(19) United States
(12) Patent Application Publication
(10) Pub. No.: US 2023/0229630 A1
(43) Pub. Date: Jul. 20, 2023

(54) PROCESSING VARIABLE-LENGTH DATA

(71) Applicant: NVIDIA Corporation, Santa Clara, CA (US)

(72) Inventors: Eyal Soha, Boulder, CO (US); Elias Stehle, Pfaeffikon SZ (CH); Nikolay Sakharnykh, East Rutherford, NJ (US)

(21) Appl. No.: 17/579,488

(22) Filed: Jan. 19, 2022

(51) Int. Cl. G06F 16/17

(52) U.S. Cl. CPC G06F 16/1724

(57) ABSTRACT

Apparatuses, systems, and techniques to decompress data in parallel. In at least one embodiment, decompressing a variable-length-coded data stream speculatively decodes overlapping portions of said data stream to determine locations to begin correctly decoding said data stream.

### FIELD

The present disclosure relates to decompression of data in parallel, and more particularly to decompression of variable-length coded data in parallel.

### BACKGROUND

Decompression of large amounts of data is often done sequentially, which uses significant amounts of time. For some decompression and, generally, decoding schemes, the nature of the schemes lend itself to sequential decoding. For example, decoding one portion of data may depend on the value of an earlier portion of data. At the same time, computer systems are limited by processor speed, bandwidth, and other resource constraints which limit the speed at which data can be decoded sequentially.

### BRIEF DESCRIPTION OF THE DRAWINGS

FIG. 1 illustrates a process for decompressing a file on a central processing unit, in accordance with at least one embodiment;

FIG. 2A illustrates a diagram of how data is compressed, in accordance with at least one embodiment;

FIG. 2B illustrates a diagram of how data is compressed, in accordance with at least one embodiment;

FIG. 3A illustrates a Huffman tree, in accordance with at least one embodiment;

FIG. 3B illustrates a Huffman tree, in accordance with at least one embodiment;

FIG. 4 illustrates a type of compressed file represented in blocks; in accordance with at least one embodiment;

FIG. 5A illustrates an addition of two large numbers using a carry lookahead adder system, in accordance with at least one embodiment;

FIG. 5B illustrates addition of two large numbers using a carry lookahead adder system after some summing operations, in accordance with at least one embodiment;

FIG. 6 illustrates addition of two large numbers using carry-ins and carry-outs, in accordance with at least one embodiment;

FIG. 7A illustrates a decoding of a bit stream using offsets, in accordance with at least one embodiment;

FIG. 7B illustrates vectors corresponding with strides of data, in accordance with at least one embodiment;

FIG. 8 illustrates an up-sweep phase of vectors performed in parallel, in accordance with at least one embodiment;

FIG. 9 illustrates a down-sweep phase of vectors, in accordance with at least one embodiment;

FIG. 10A illustrates a pruning operation, in accordance with at least one embodiment;

FIG. 10B illustrates a to-do list created from decoding offsets, in accordance with at least one embodiment;

FIG. 11 illustrates a to-do list created from decoding offsets, in accordance with at least one embodiment;

FIG. 12 illustrates an array operated upon by an algorithm using pointers, in accordance with at least one embodiment;

FIG. 13A illustrates an array and threads executing an algorithm, in accordance with at least one embodiment;

FIG. 13B illustrates an array and threads after one iteration of work, in accordance with at least one embodiment;

FIG. 14A illustrates an array after available threads have been reassigned, in accordance with at least one embodiment;

FIG. 14B illustrates an array and all threads parked, in accordance with at least one embodiment;

FIG. 15A illustrates a diagram of how data is decompressed, in accordance with at least one embodiment;

FIG. 15B illustrates an input file and ring buffer, in accordance with at least one embodiment;

FIG. 16A illustrates an input file and ring buffer, in accordance with at least one embodiment;

FIG. 16B illustrates an input file and ring buffer, in accordance with at least one embodiment;

FIG. 17 illustrates an input file and ring buffer, in accordance with at least one embodiment;

FIG. 18 illustrates a GPU writing to a buffer, in accordance with at least one embodiment;

FIG. 19 illustrates GPU actions corresponding with buffer states, in accordance with at least one embodiment;

FIG. 20 illustrates a process for decompressing a stream of data, in accordance with at least one embodiment;

FIG. 21 illustrates a framework for decompressing data streams, in accordance with at least one embodiment;

FIG. 22 illustrates an approach for decompressing data in parallel, in accordance with at least one embodiment;

FIG. 23 illustrates a diagram of an auxiliary back-reference array, in accordance with at least one embodiment;

FIG. 24 illustrates an exemplary data center, in accordance with at least one embodiment;

FIG. 25 illustrates a processing system, in accordance with at least one embodiment;

FIG. 26 illustrates a computer system, in accordance with at least one embodiment;

FIG. 27 illustrates a system, in accordance with at least one embodiment;

FIG. 28 illustrates an exemplary integrated circuit, in accordance with at least one embodiment;

FIG. 29 illustrates a computing system, in accordance with at least one embodiment;

FIG. 30 illustrates an APU, in accordance with at least one embodiment;

FIG. 31 illustrates a CPU, in accordance with at least one embodiment;

FIG. 32 illustrates an exemplary accelerator integration slice, in accordance with at least one embodiment;

FIGS. 33A-33B illustrate exemplary graphics processors, in accordance with at least one embodiment;

FIG. 34A illustrates a graphics core, in accordance with at least one embodiment;

FIG. 34B illustrates a GPGPU, in accordance with at least one embodiment;

FIG. 35A illustrates a parallel processor, in accordance with at least one embodiment;

FIG. 35B illustrates a processing cluster, in accordance with at least one embodiment;

FIG. 35C illustrates a graphics multiprocessor, in accordance with at least one embodiment;

FIG. 36 illustrates a graphics processor, in accordance with at least one embodiment;

FIG. 37 illustrates a processor, in accordance with at least one embodiment;

FIG. 38 illustrates a processor, in accordance with at least one embodiment;

FIG. 39 illustrates a graphics processor core, in accordance with at least one embodiment;

FIG. 40 illustrates a PPU, in accordance with at least one embodiment;

FIG. 41 illustrates a GPC, in accordance with at least one embodiment;

FIG. 42 illustrates a streaming multiprocessor, in accordance with at least one embodiment;

FIG. 43 illustrates a software stack of a programming platform, in accordance with at least one embodiment;

FIG. 44 illustrates a CUDA implementation of a software stack of FIG. 43, in accordance with at least one embodiment;

FIG. 45 illustrates a ROCm implementation of a software stack of FIG. 43, in accordance with at least one embodiment;

FIG. 46 illustrates an OpenCL implementation of a software stack of FIG. 43, in accordance with at least one embodiment;

FIG. 47 illustrates software that is supported by a programming platform, in accordance with at least one embodiment;

FIG. 48 illustrates compiling code to execute on programming platforms of FIGS. 43-46, in accordance with at least one embodiment;

FIG. 49 illustrates in greater detail compiling code to execute on programming platforms of FIGS. 43-46, in accordance with at least one embodiment;

FIG. 50 illustrates translating source code prior to compiling source code, in accordance with at least one embodiment;

FIG. 51A illustrates a system configured to compile and execute CUDA source code using different types of processing units, in accordance with at least one embodiment;

FIG. 51B illustrates a system configured to compile and execute CUDA source code of FIG. 51A using a CPU and a CUDA-enabled GPU, in accordance with at least one embodiment;

FIG. 51C illustrates a system configured to compile and execute CUDA source code of FIG. 51A using a CPU and a non-CUDA-enabled GPU, in accordance with at least one embodiment;

FIG. 52 illustrates an exemplary kernel translated by CUDA-to-HIP translation tool of FIG. 51C, in accordance with at least one embodiment;

FIG. 53 illustrates non-CUDA-enabled GPU of FIG. 51C in greater detail, in accordance with at least one embodiment;

FIG. 54 illustrates how threads of an exemplary CUDA grid are mapped to different compute units of FIG. 53, in accordance with at least one embodiment; and

FIG. 55 illustrates how to migrate existing CUDA code to Data Parallel C++ code, in accordance with at least one embodiment.

### DETAILED DESCRIPTION

In the following description, numerous specific details are set forth to provide a more thorough understanding of at least one embodiment. However, it will be apparent to one skilled in the art that the inventive concepts may be practiced without one or more of these specific details and that various embodiments can be combined. In at least one embodiment, hardware such as a processor, a data source, a data sink, or some combination thereof, performs or participates in one or more steps to perform operations discussed herein, such as decompressing or otherwise performing operations involving decoding of variable-length coded data in parallel. In at least one embodiment, processors include parallel processors, GPUs, field-programmable gate arrays (FPGAs), application-specific integrated circuits (ASICs), or some combination thereof. In at least one embodiment, data such as compressed data files, bit streams, binary code, or some combination thereof are located on a data sources such as a main memories, nonvolatile memory express hardware (NVMe), hard disk drives (HDDs), solid state drives (SSDs), network hardware, network interface controllers (NICs), GPU device memories, or some combination thereof. In at least one embodiment, data are found on data sinks such as main memories, NVMe, HDDs, SSDs, network hardware, NICs, GPU device memories, or some combination thereof.

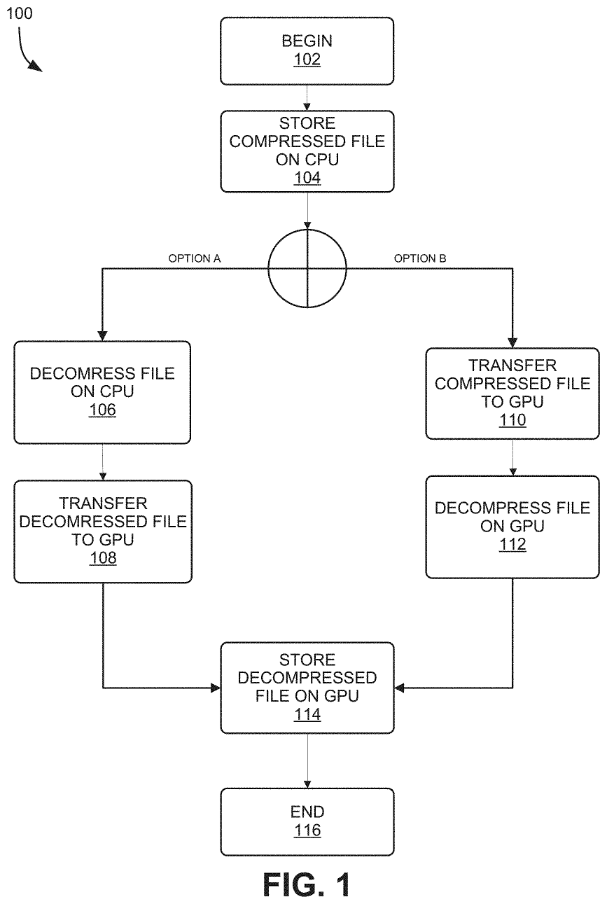

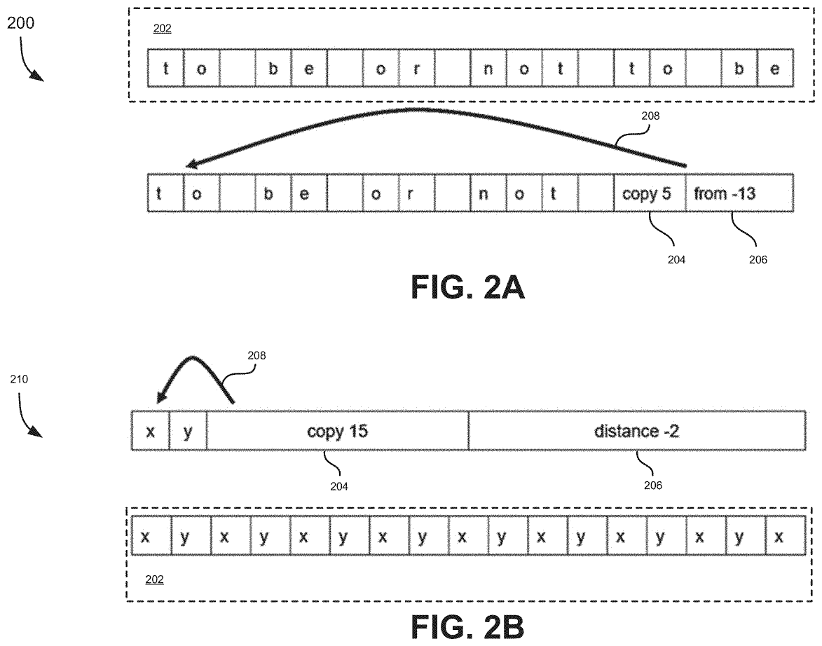

FIG. 1 illustrates a process 100 for decompressing a compressed file on a central processing unit (CPU) to be made available on a graphics processing unit (GPU), according to at least one embodiment. In at least one embodiment, FIG. 1 illustrates two possible processing paths of many processing paths for decompressing a compressed file. In at least one embodiment, decompressing large files in parallel occurs, at least in part, on a GPU. In at least one embodiment, decompressing large files in parallel includes decoding variable-length coded data in parallel as further discussed in conjunction with at least FIGS. 2-23 of this disclosure. In at least one embodiment, variable-length codes include coding systems such as Huffman coding, Lempel-Ziv coding, arithmetic coding, and context-adaptive variable-length coding.

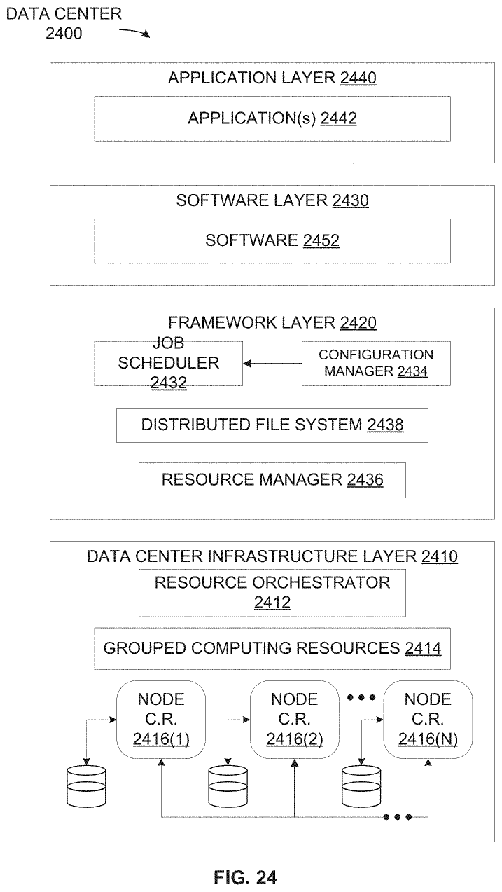

In at least one embodiment, steps to decompressing a compressed file begin 102 with storing a compressed file (e.g., data, bit stream, database file, spreadsheet file) on a CPU 104, then, with one option, Option A, decompresses said compressed file on said CPU 106, transfers said decompressed file to a GPU 108, and stores said decompressed file on said GPU 114 to end 116 said process. In at least one embodiment, instead of decompressing a compressed file on a CPU 106, steps include transferring said compressed file to a GPU 110, decompressing said compressed file on said GPU 112, and storing said decompressed file on said GPU 114 to end 116 said process. In at least one embodiment, a decompressed file is stored in a memory of a GPU. In at least one embodiment, transferring a compressed file from a CPU to a GPU 100 and then decompressing a compressed file on said GPU 112 results in faster performance and throughput than decompressing a compressed file on a CPU 106 and then transferring said decompressed file to a GPU 108. In at least one embodiment, decompression of a compressed file on either a CPU or GPU 106, 112 includes one or more embodiments described in conjunction with FIGS. 2A-23 below. In at least one embodiment, process 100 is implemented in connection with one or any combination of embodiments described further in conjunction with FIGS. 24-55.

In at least one embodiment, a compressed file stored in step 104 is a computer file which has undergone data compression (e.g., a reduction in size of an original file by encoding data of said original file using fewer bits), using an LZ77 data compression method. In at least one embodiment, a compressed file stored in step 104 is one or more computer files which have undergone data compression, using a data compression method (e.g., DEFLATE, GZIP, LZ77, LZW, LZSS, Zstandard (zstd)) resulting in a compressed file format (e.g., GZIP, ZIP, 7Zip, PNG, zlib, pkzip, gunzip, rar, zst). In at least one embodiment, a compressed file stored in step 104 is lossy. In at least one embodiment, a compressed file stored in step 104 is lossless. In at least one embodiment, DEFLATE, sometimes referenced to as Deflate, is an algorithm that is some combination of an LZ77 algorithm (e.g., an algorithm related to LZSS, a compression and decompression algorithm) and Huffman coding (e.g., variable-length coding, prefix-free coding). In at least one embodiment, GZIP is a file format and a software application used for file compression and decompression based on DEFLATE.

In at least one embodiment, decompression of a compressed file, as with steps 106 and 112 and discussed further in conjunction with FIGS. 2-14, includes methods related to those involved in data compression using DEFLATE, which includes Huffman coding and algorithms of LZ77, wherein Huffman coding uses a prefix-free code (e.g., encoded values, variable-length encoded values), which is a system of code (e.g., code words, encoded values) with a prefix property (e.g., no whole code words in a code system is a prefix for any other code word in said code system). In at least one embodiment, a prefix-free code is confusingly referred to as a “prefix code” in the art. In at least one embodiment, a prefix-free codebook contains codes representing symbols (e.g., literals).

In at least one embodiment, a data path (e.g., a path data follows through hardware in a computing system) includes a file transferred from a CPU to a GPU as with steps 108 and 110, and comprises connections between one or more CPUs and one or more GPUs, wherein said connections use some computer network communications standard (e.g., PCIe, Ethernet, InfiniBand). In at least one embodiment, connections between one or more CPUs and one or more GPUs further comprise other computing components such as other processors (including accelerators, field programmable gate arrays (“FPGAs”), memory devices (e.g., dynamic read-only memory), storage devices (e.g., solid state or disk drives), or some combination thereof). In at least one embodiment, a data path to a GPU does not include a CPU, as with direct memory access (DMA) (e.g., a method of transferring data from one part of a computing system to another part of said computing system without processing said data using a CPU). In at least one embodiment, a data path to a GPU does not include a CPU, as with NVIDIA's GPUDirect Storage, which is a driver that enables direct memory access between GPU and storage.

In at least one embodiment, a decompressed file is stored on device memory (e.g., memory where data being processed is stored). In at least one embodiment, device memory is only accessible by other means of storage such as main memory, SSDs, NVMe, NIC, or some combination thereof. In at least one embodiment, storing a decompressed file on a GPU 114 includes storing said decompressed file in GPU memory (e.g., device memory, caches, shared memory, register file) allowing said GPU to perform operations on said decompressed file. In at least one embodiment GPU memory is device memory.

FIG. 2A illustrates a diagram 200 of how an LZ77 compression converts an original file of data into a data stream including literals (e.g., a notation for representing a fixed value in source code, a letter, a number, a symbol) and LZ77 copy instructions, according to at least one embodiment. In at least one embodiment, a portion of an original file 202 contains data representing text stating “to be or not to be,” and using an LZ77 copy instruction, which comprises copy instruction 204 and distance instruction 206, a processor compresses said data by pointing to and replacing said previous statement of “to be” with a copy instruction. In at least one embodiment, said operation of compressing said data by pointing to and replacing said previous statement of “to be” with a copy instruction is referred to, at least in part, as copying. In at least one embodiment, an LZ77 copy instruction comprises an instruction 204, 206 that specifies how many bytes to copy 204 from a previous location in file 202, wherein each block in file 202 represents a byte, and an instruction that specifies how far back to look 206 in file 202. In at least one embodiment, each block in file 202 represents more than one byte, such as 2 bytes, 4 bytes, or more. In at least one embodiment, each block in file 202 represents 4 bytes of LZ77 processing buffer per 1 byte of decompressed output. In FIG. 2A, according to at least one embodiment, instruction 204 requires a copy size of 5 bytes and instruction 206 requires a copy to go back a distance of 13 bytes 208 earlier in file 202.

FIG. 2B illustrates another representation 210 of how an LZ77 compression converts an original file of data into a data stream including literals (e.g., symbols) and LZ77 copy instructions, according to at least one embodiment. In at least one embodiment, LZ77 copy instructions 204, 206 specify a copy size greater than a distance required to go back and look in file 202, for example, as shown in FIG. 2B, original file 202 contains repeating text “x y x y . . . ” and instruction 204 requires a copy size of 15 bytes and instruction 206 requires a copy to go back a distance of 2 bytes 208 earlier in file 202. In at least one embodiment, LZ77 compression may restrict copy length to between 3 and 285 bytes and restrict distances to points not beyond a file's beginning. In at least one embodiment, LZ77 compression using copies is one method of compressing an original file 202. In at least one embodiment, the principles, techniques, methods, and systems disclosed in conjunction with FIGS. 2A-B can be used in connection with one or any combination of embodiments described further in conjunction with at least FIGS. 1, and 3A-23.

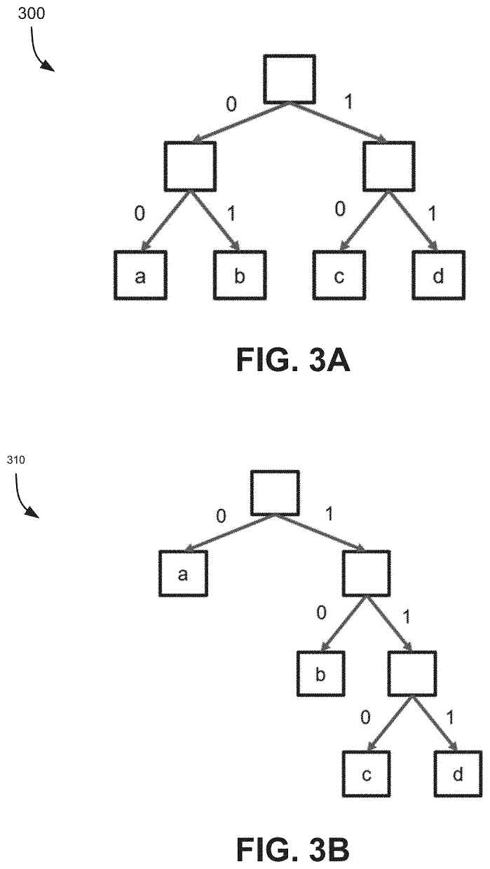

FIG. 3A illustrates a Huffman tree 300, which is a binary tree wherein each end point (e.g., end node, end point, end box) represents a letter or literal, where Huffman tree 300 represents a system for Huffman encoding during compression of files according to at least one embodiment. In at least one embodiment, a Huffman tree 300 helps visualize an encoding and decoding of a bit stream, with each branch of said tree indicating which bits to output to a bit stream, for example, letter “a” is coded “00” and “b” is coded “01,” and therefore, a string of letters “aabaabcd” would be encoded as a bit stream of “0000010000011011,” or in reverse, “0000010000011011” would be decoded as “aabaabcd.” In at least one embodiment, a Huffman tree 300 may be called a balanced tree as illustrated in FIG. 3A, with each letter encoded by two bits.

FIG. 3B illustrates a Huffman tree 310 where each literal is assigned a code length depending on how frequently said literal appears in an original file to optimize computing resources such as memory bandwidth, for example, if an original file contains a string of text “aabaabcd,” letter “a” appears most frequently and therefore is assigned a code comprising one bit, “0,” while letters “c” and “c” appear least frequently and are assigned a code comprising three bits—“110” and “111” respectively. In at least one embodiment, a Huffman tree is considered to be, at least partly, a type of code book. In at least one embodiment, if an original file contains a string of text “aabaabcd,” and Huffman tree 310 represents a system for encoding said string of text, a bit stream of “00100010110111” would represent an encoding of said string of text, which is two bits shorter than in said example discussed in connection with FIG. 3A.

In at least one embodiment, Huffman trees 300, 310 include encodings for more than just letters, for example, encodings represent statements or symbols such as “copy,” “distance,” and “end,” which indicates an end to Huffman-encoded data. In at least one embodiment, one or more Huffman trees are used in connection with each other, for example, a second Huffman tree is used to encode a distance instruction representing a number (e.g., a number from 1 to 32768). In at least one embodiment, a Huffman tree is represented by one or more Huffman trees (e.g., a Huffman tree is encoded by another Huffman tree), wherein code of said one or more Huffman trees is further specified in a compressed code as well. In at least one embodiment, the principles, techniques, methods, and systems disclosed in conjunction with FIG. 3A-B can be used in connection with one or any combination of embodiments described further in conjunction with at least FIGS. 1-2B, and 4-23.

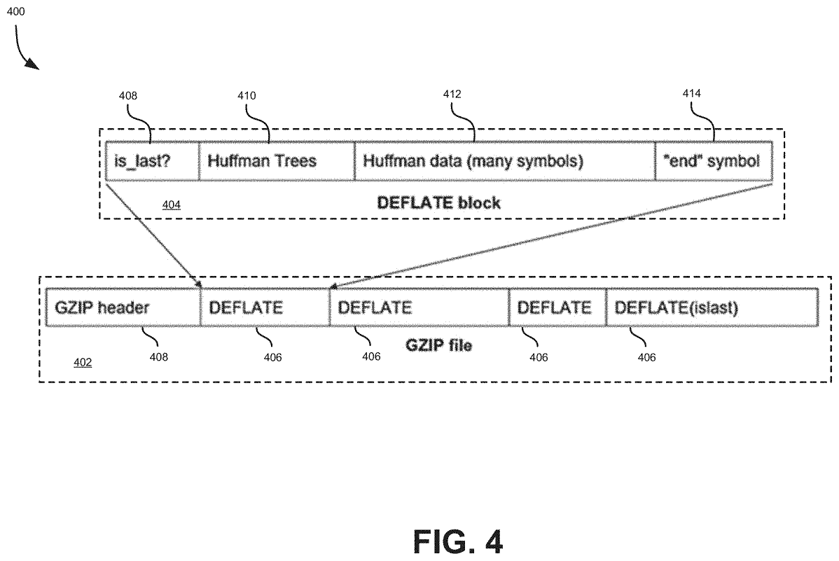

FIG. 4 illustrates a GZIP file format, at least in part, according to at least one embodiment. FIG. 4 includes a GZIP file (e.g., a compressed file using GZIP compression) 402 in blocks (e.g., a representation of chunks of data as sequences of bytes or bits), according to at least one embodiment. In at least one embodiment, GZIP file 402 comprises DEFLATE blocks 406 following GZIP header 408 until one of DEFLATE blocks 406 is marked as last (e.g., marked as “islast”). In at least one embodiment, GZIP header 408 comprises information on the size of original (e.g., uncompressed) input data (e.g., marked as “islast”). In at least one embodiment, GZIP file 402 follows a file format specification such as GZIP file format specification version 4.3 (RFC 1952). In at least one embodiment, GZIP header 408 comprises data regarding a file's name and modification time and date, but GZIP header 408 does not comprise data regarding said file's uncompressed length or number of DEFLATE blocks 406 contained in said file. In at least one embodiment, GZIP header 408 does contain an original, uncompressed input data's number of DEFLATE blocks 406 contained in said file.

In at least one embodiment, one or more DEFLATE blocks 406 comprise a DEFLATE block header 404, which comprises a bit 408 to indicate if one of DEFLATE blocks 406 is GZIP file's 402 last DEFLATE block. In at least one embodiment DEFLATE block header 404 comprises encoding of Huffman trees 410, Huffman data 412 decoded by Huffman trees 410, and an end symbol 414, which indicates a DEFLATE block's 404 end. In at least one embodiment, the principles, techniques, methods, and systems disclosed in conjunction with FIG. 4 can be used in connection with one or any combination of embodiments described further in conjunction with at least FIGS. 1-3B, and 5-23.

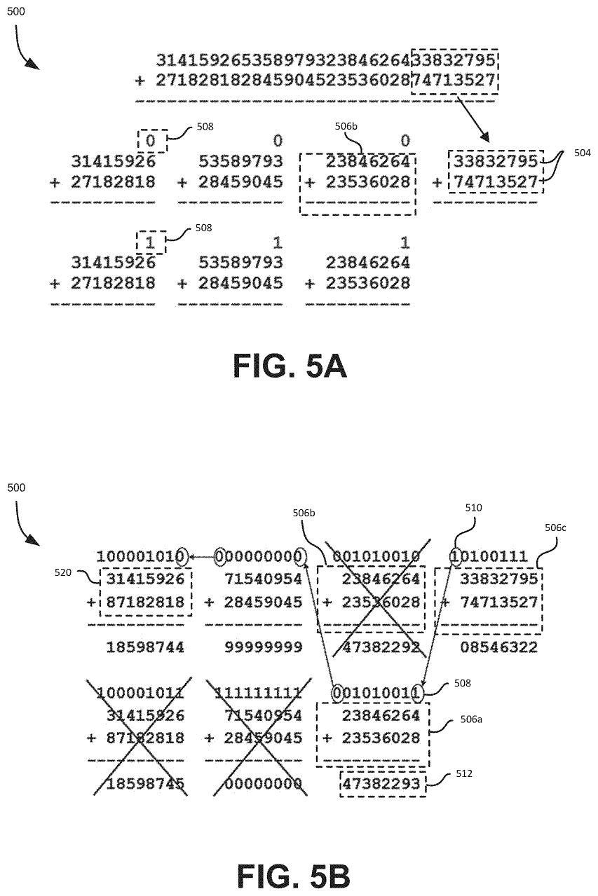

FIG. 5A illustrates addition 500 of two large numbers using a carry lookahead adder system performed by one or more processors, according to at least one embodiment. In at least one embodiment, two large strings of numbers can be added (e.g., summed) together by breaking up said two numbers into smaller chunks 504, adding said smaller chunks together in pairs 506 under two conditions, one where said addition assumes a carry-in 508 of 1 from an addition of two prior mathematically relevant chunks and another where said addition assumes a carry-in 508 zero from said addition of two prior chunks, for example, in adding two 32-digit numbers, 31415926535897932384626433832795 and 27182818284590452353602874713527, each of said numbers are divided into chunks 504 of 8 digits each and adding each pair of chunks 506, except for said numbers' right-most pair, twice—once with a carry-in 508 of 0 and once with a carry-in 508 of 1. In at least one embodiment, numbers are divided into chunks of some length other than 8 digits each, with said division based, at least in part, on optimizing computational resource concerns (e.g., maximizing use of available threads while minimizing calculation times). In at least one embodiment, a thread is a sequence of programmed instructions.

FIG. 5B illustrates addition of two large numbers using a carry lookahead adder system 500 after summing together each pair of chunks 506 twice, once with a carry-in of 1 and once with a carry-out of 0, and determining a carry-out of 0 or 1 for each pair of chunks 506 based on said summation operation according to at least one embodiment. In at least one embodiment, one or more processors match carry-out 510 from one summed pair of chunks with carry-in 508 used to perform a summation for pair of chunks 506a, resulting in summed pair 506b going unmatched (e.g., unused, wasted). In at least one embodiment, when a carry-out 510 from a sum of right-most pair of chunks 506c results in a value of 1, one or more processors uses a sum 512 from a next mathematically relevant pair that has been summed using a carry-in 508 of 1, and when a carry-out 510 from a sum of right-most pair of chunks 506c results in a value of 0, one or more processors uses a sum 512 from a next mathematically relevant pair that has been summed using a carry-in 508 of 0. In at least one embodiment, when one or more processors uses a sum based on a carry-in, said one or more processors use said sum's carry-out to determine which sum to use next by matching said sum's carry-out with a carry-in used to sum a pair of chunks, repeating such steps until using a sum from an addition of left-most pair of chunks 520. In at least one embodiment, adding more than two numbers together results in more possible values for a carry-out, for example, if adding 20 numbers together, then a carry-out could be any integer value between 0 and 19, resulting in 20 additions for each pair, resulting in 19 unmatched summations.

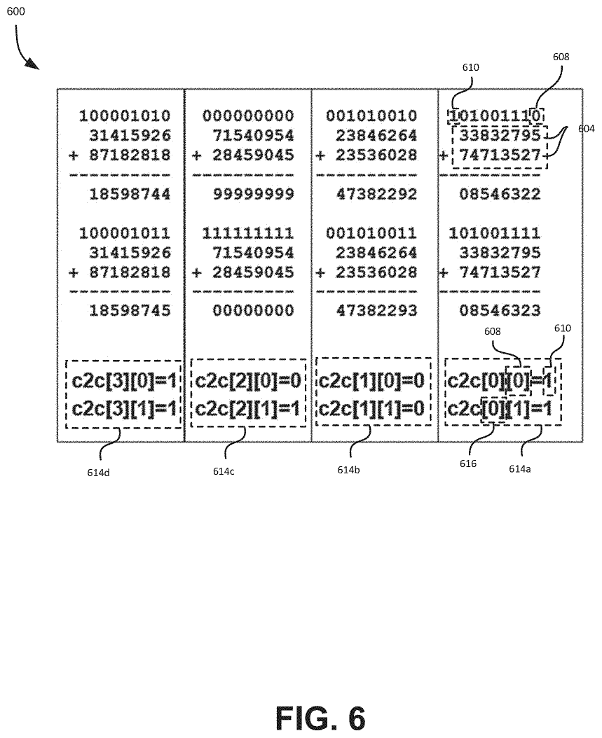

FIG. 6 illustrates addition 600 of two large numbers comprising smaller chunks 604 of said two large numbers, carry-ins 608, and carry-outs 610 according to at least one embodiment and as further discussed in conjunction with FIGS. 5A-B. In at least one embodiment, speculative addition 600 further comprise arrays of c2c vectors 614, which indicate, at least in part, how a carry-in leads to a carry-out during speculative addition 600, for example, from right to left, c2c vector 614a maps carry-in 618 of 0 to carry-out 610 of 1 and carry-in of 1 to carry-out of 1; c2c vector 614b maps 0 (carry-in) to 0 (carry-out) and 1 (carry-in) to 0 (carry-out); c2c vector 614c maps 0 (carry-in) to 0 (carry-out) and 1 (carry-in) to 1 (carry-out); c2c vector 614d maps 0 (carry-in) to 1 (carry-out) and 1 (carry-in) to 1 (carry-out). In at least one embodiment arrays of c2c vectors 614 are conceptualized and/or treated as functions that map an input to an output so that given an input that is 0 or 1, said functions output a 0 or 1, which, for example, can be represented as:

uint c2c(uint carry_in){return c2c[carry_in];}.

In at least one embodiment, each column of addition illustrated in FIG. 6 is called a stride and the first or left-most index of each c2c vector 614 comprises a stride number 616, with 0 representing the right-most stride and 3 representing the left-most stride, and where the second index includes carry-in 608 as discussed above. In at least one embodiment, array of c2c vectors 614 can be represented as:

uint c2c(uint stride,uint carry_in){return c2c[stride][carry_in];}.

In at least one embodiment, arrays of c2c vectors 614 are represented with a subscript of a stride, for example, arrays of c2c vectors for four strides are represented as c2c₀, c2c₁, c2c₂, c2c₃, and a function could be defined as:

c²c_{stride}(carry_in)=c2c(stride,carry_in).

In at least one embodiment, arrays of c2c vectors 614 from sequential strides create a chain that maps carry-ins to carry-outs to carry-ins to carry-outs and so on, with representation of such a chain being a repetition of function compositions, for example, as represented by:

c2c₂(c2c₁(c2c₀(0))),

or equivalently with alternative notation as:

c2c₀·c2c₁·c2c₂,

wherein stride 0's carry-in is 0 in this example. In at least one embodiment, a chain that maps carry-ins to carry-outs is a function composition of all preceding functions and such mapping is called a scan or multithread scan. In at least one embodiment, c2c vectors for each stride are produced by performing, at least partly in parallel, summations on each stride for all possible carry-in values, and then a scan is performed on said c2c vectors with results (e.g., output) of said scan being recorded to a GPU memory. In at least one embodiment, a scan operation on c2c vectors (e.g., functions) requires a mathematical operation that is associative and values in said c2c vectors' domain (e.g., carry-in values) that are identical to values in said c2c vectors' range (e.g., carry-out values), for example, requirements are met when a scan comprising function composition, which is associative, is performed by a logarithmic GPU algorithm further comprising a combination operator, wherein values for both domain and range are each 0 and 1. In at least one embodiment, a scan operation begins with a first c2c vector (e.g., function) using an identity function. In at least one embodiment, the principles, techniques, methods, and systems disclosed in conjunction with FIGS. 5A-6 can be used in connection with one or any combination of embodiments described further in conjunction with at least FIGS. 1-4, and 7A-23.

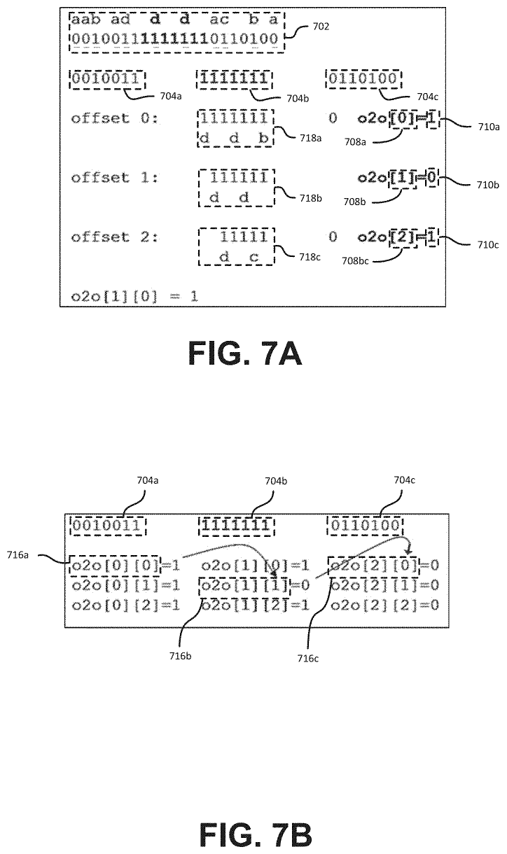

FIG. 7A illustrates how a bit stream made up of Huffman codes is decoded, at least in part, using offsets according to at least one embodiment. In at least one embodiment, Huffman codes are decoded according to a code book, which is discussed, at least in part, in conjunction with FIG. 3B. In at least one embodiment, principles, techniques, and methods used in a carryout lookahead adder algorithm, as discussed further in conjunction with FIGS. 5A-6, are applied directly or abstractly to decompressing data in parallel as discussed throughout this disclosure. In at least one embodiment, principles, techniques, and methods used to decompress data in parallel are used to otherwise process large amounts of data, such as extracting coherent blocks of data. In at least one embodiment, principles, techniques, and methods used to encode and/or decode data in parallel are used in other applications not limited to decryption, encryption, cryptography, and encoding and decoding wireless communication signals. In at least one embodiment, decompressing data in parallel uses aspects of speculative decoding.

In at least one embodiment, an offset value determines (e.g., sets) and/or describes where a segment of data begins (e.g., an offset of 2 creates a subsegment of data beginning at the second bit of a data segment such as a section of a bit stream, a stride, a chunk of data, a block of data). In at least one embodiment, an offset provides information as to where to begin decoding a segment of data and/or an offset provides information as to where to stop decoding a segment of data. In at least one embodiment, an offset providing information as to where to begin decoding a segment of data is called a start offset. In at least one embodiment, an offset providing information as to where to stop decoding a segment of data is called an end offset. In at least one embodiment, an end offset of one segment of data is the start offset of the next segment of data. In at least one embodiment, an offset refers to a subsegment of data (e.g., offset 2 refers to a subsegment beginning with bit 2 of a data segment or data chunk). In at least one embodiment, an offset refers to an overlapping portion of data. In at least one embodiment, multiple offsets are created, which provide information, at least in part, as to locations where a subsegment begins. In at least one embodiment, multiple offsets are created, which provide information, at least in part, as to locations where a subsegment ends. In at least one embodiment, locations where a subsegment ends) in a data segment, wherein said created offsets can be conceptualized as overlapping portions of data, as illustrated with an arrangement of offsets 718. Offsets 718 are illustrated to show how offset 718c partially overlaps offset 718b, which partially overlaps 718a. In at least one embodiment, literal overlapping is not required, but rather a conceptual aid in explaining offsets created from data segments. In at least one embodiment, offsets are created for every offset (e.g., 48 offsets are created for a 48-bit data segment). In FIG. 7A, bit stream 702 contains Huffman codes for literals a, b, c, and d, according to at least one embodiment, and further in FIG. 7A, each bit that is a beginning of a Huffman code is marked with a line underneath and with a literal represented by said code above each said bit. In at least one embodiment, a processor tasked to decode bit stream 702 has no instructions, markers, or flags to follow to determine each beginning to each Huffman code. In at least one embodiment, bit stream 702 is broken into 3 chunks 704 (e.g., strides) of equal length—7 bits. In at least one embodiment, using chunk 704b “1111111” as an example, decoding by a processor using an offset 0 (e.g., decoding beginning with bit one (left-most bit) of a chunk) results in decoding chunk 704b as an array of literals “ddb,” wherein decoding of said literal “b” requires borrowing one bit, “0,” from right-most chunk 704c, resulting in an overlap 710a of 1; decoding by a processor with an offset of 1 (e.g., beginning with bit two) results in decoding chunk 704b as an array of literals “dd,” wherein said decoding does not require borrowing bits from chunk 704c to properly decode and, therefore, results in an overlap 710b of 0; decoding by a processor with an offset of 2 (e.g., beginning with bit three) results in decoding chunk as an array of literals “dc,” wherein said decoding requires borrowing one bit, “0” from chunk 704c, resulting in an overlap 710c of 1. In at least one embodiment, an offset is a value of n−1, wherein n equals a data segment's bit length and an overlap can be 0 or an integer equal to or greater than 1.

In at least one embodiment, offset and overlap 710 information of FIG. 7A is used by a processor to create, at least in part, a vector, an o2o (e.g., offset to overlap) vector, for example, for a Huffman decoding of bit stream 702 with offset 0, an o2o vector (e.g., a function) is represented as o2o[0]=1, wherein “[0]” is an offset index 708a, in this case 0, and “1” represents overlap 710, and for Huffman decodings with offset 1 and offset 2, o2o vectors would read o2o[1]=0 and o2o[2]=1 respectively, with “[1]” representing an offset index 708b of 1 and “[2]” representing an offset index 708c of 2.

FIG. 7B illustrates o2o vectors for each stride 704 according to at least one embodiment and as further discussed in conjunction with FIG. 7A. In at least one embodiment, once all o2o vectors have been calculated (e.g., by a processor) for each stride, information about a carry-in used for an o2o vector for a left-most stride is used to determine which o2o vector to use in a subsequent stride, for example, beginning with o2o vector 716a with an offset index 0 for left-most (e.g., first) stride 704a, an overlap of 1 results, therefore a processor points to o2o vector 716b for stride 704b that has an offset index of 1 and uses resulting overlap 0 from o2o vector 716b to point to an o2o vector 716c for stride 704c with an offset index of 0 and so forth. In at least one embodiment, pointing from one o2o vector to another continues until no more strides are left, resulting in a single overlap value for an entire data segment. In at least one embodiment, a single overlap value for an entire data segment other than 0 indicates that whatever offset value was used to begin decoding said entire data segment is incorrect, and if said single overlap value for said entire data segment is 0, then whatever offset value was used to begin decoding said entire data segment is possibly correct.

In at least one embodiment, decoding of Huffman codes contained in a bit stream, as discussed further in conjunction with FIGS. 7A-B, is represented with code as follows:

```
// Function composition
void add(const uint a[OFFSETS],
      const uint b[OFFSETS],
      uint out[OFFSETS]) {
  for (uint i = 0; i < OFFSETS; i++) {
    out[i] = b[a[i]];
  }
}
uint o2o[STRIDES][OFFSETS];
uint out[OFFSETS];
add(o2o[0], o2o[l], &out);
```

wherein said code is a loop going through each element in each o2o vector and performs a composition of vector a and vector b into vector out.

In at least one embodiment, decoding of Huffman codes contained in a bit stream, as discussed further in conjunction with FIGS. 7A-B, is represented with code as follows:

```
// Function composition
void add(const uint index,
    const uint a[OFFSETS],
    const uint b[OFFSETS],
    uint out[OFFSETS]) {
  out[index] = b[a[index]];
}
uint o2o[STRIDES][OFFSETS];
uint out[STRIDES][OFFSETS];
uint stride_id = threadIdx.x / OFFSETS;
uint write_id = threadIdx.x % OFFSETS;
add(write_id, o2o[stride_id*2], o2o[stride_id*2+1], out[stride_id]);
```

wherein each thread works on one offset of said composition, requiring multiple threads per operation and using division and modulo to stride across a data segment. In at least one embodiment, decoding Huffman codes use division and modulo to stripe across a data segment. In at least one embodiment, uint stride_id (e.g., unsigned integer for variable stride_id) uses modulo and uint write_id uses division, or uint stride_id uses division and uint write_id uses modulo. In at least one embodiment, the principles, techniques, methods, and systems disclosed in conjunction with FIGS. 7A-B can be used in connection with one or any combination of embodiments described further in conjunction with at least FIGS. 1-6, and 8-23.

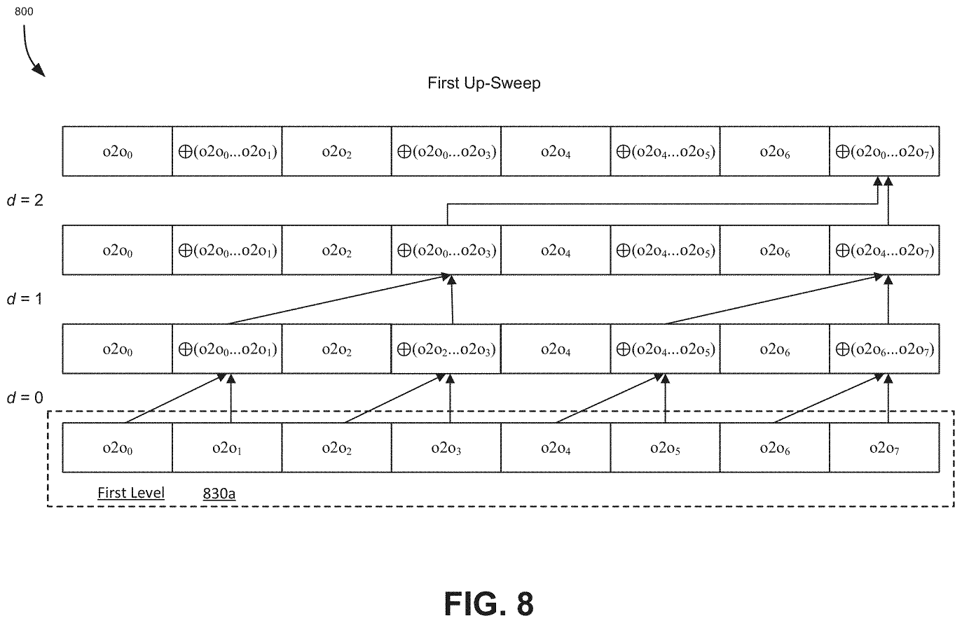

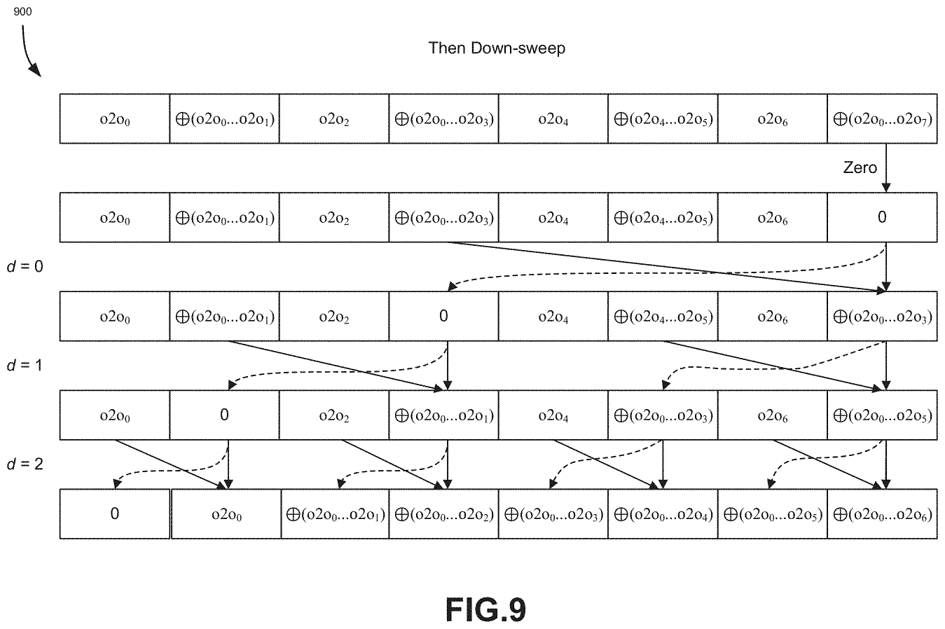

FIG. 8 illustrates a representation of up-sweep 800 performed in parallel, using combination operations on o2o vectors to produce information (e.g., carryout information for a specific offset) with logarithmic complexity, according to at least one embodiment and as further discussed in conjunction with FIGS. 6 and 7A-B. In at least one embodiment, up-sweep 800 is referred to as an upscan. In at least one embodiment, up-sweep 800 is referred to as one aspect of an o2o vector scan. In at least one embodiment, use of an exclusive-or (XOR) symbol, ⊕, is a novel use of said symbol representing operations performed during sweeps, such as up-sweep 800 and down-sweep 900, discussed further in conjunction with FIG. 9, wherein use of an XOR symbol is used merely due to a lack of existing symbols that describe said operations performed during said sweeps. In at least one embodiment, use of an XOR symbol does not signify an XOR operation. In at least one embodiment, a symbol other than an XOR symbol is used to represent operations performed during sweeps as described herein. In at least one embodiment, use of an XOR symbol represents, at least in part, an operation on a series of o2o vectors. In at least one embodiment, up-sweep 800 represented by FIG. 8 is not an actual data structure and helps visualize what one or more processors do as it progresses through an algorithm. In at least one embodiment, first level set of blocks (e.g., nodes) 830a represent an array of o2o vectors stored in memory (e.g., shared memory) that is operated on by one or more processors performing a combination function on pairs of o2o vectors, wherein one o2o vector of each pair is overwritten in memory with each step of processing (e.g., a round of combination operations performed on o2o vectors), wherein processing step 1 is represented as d=0 and two arrows pointing to one block in a subsequent level 830 represents a combination performed on a pair of o2o vectors and a rewriting of one o2o vector of said pair. In at least one embodiment, determining how many processing steps d are required to operate on an even number, x, of vectors (e.g., elements, inputs) in an array is based on solving log₂ x=d, for example, 8 o2o vectors in an array requires 3 steps of processing as shown in FIG. 8. In at least one embodiment, up-sweep 800 operates on a non-power-of-two-sized input array. In at least one embodiment, up-sweep 800 operates on an input array with unnecessary input elements removed. In at least one embodiment, if up-sweep 800 outputs results into data-dependent operands of inputs, computer code for processing up-sweep 800 requires synchronization, with said code represented by:

```
  // Function composition
void add(const uint index,
    const uint a[OFFSETS],
    const uint b[OFFSETS],
    uint out[OFFSETS]) {
  out[index] = b[a[index]];
}
uint o2o[STRIDES][OFFSETS];
add(write_id, a, b, a); // Okay.
add(write_id, a, b, b); // Not okay, data-race.
// Okay:
add(write_id, a, b, temp);
_{——}syncthreads( );
copy(write_id, temp, b).
```

In at least one embodiment, said syncthreads( ) command relates to a synchronization of a group of threads participating in a computation. In at least one embodiment, synchtreads( ) is a block-level synchronization barrier. In at least one embodiment, if a GPU executes groups of threads known as warps or other groups of threads, including cooperative groups of threads, another synchronization primitive is used such as cg.sync( ). In at least one embodiment, the principles, techniques, methods, and systems disclosed in conjunction with FIG. 8 can be used in connection with one or any combination of embodiments described further in conjunction with at least FIGS. 1-7, and 9-23.

FIG. 9 illustrates a representation of down-sweep 900 performed in parallel, after an up-sweep comprising combination operations on o2o vectors, according to at least one embodiment and as discussed further in conjunction with FIG. 8. In at least one embodiment, down-sweep 900 is referred to as a downscan. In at least one embodiment, down-sweep 900 is referred to as one aspect of an o2o vector scan. In at least one embodiment, decompression of a compressed data stream comprises down-sweep 900 that determines information (e.g., overflows) for composition of o2o vectors not determined during up-sweep 800 (e.g., up-sweep), wherein down-sweep 900 determines compositions for vectors or a range of vectors, such as operations as follows: ⊕(o2o₀ . . . o2o₂), ⊕(o2o₀ . . . o2o₄), and ⊕(o2o₀ . . . o2o₆). In at least one embodiment, a number of operations O(n) is equal to a number of operations for doing a scan natively in a loop. In at least one embodiment, up-sweep 800 creates partial sums and an aggregate value for o20 vector array in first level set of blocks 830a. In at least one embodiment, during decompression, once up-sweep 800 is complete, decoding (e.g., computing) a Huffman tree for a next set of blocks begins. In at least one embodiment, a scanned array of vectors is considered to be split by two functions with identical arguments because of an up-sweep and a down-sweep, wherein an up-sweep returns an aggregate of said array of vectors. In at least one embodiment, a scan algorithm is also modified to work on a non-power-of-two-sized input array, which is important because o2o vector sizes are large and being able to remove unnecessary elements saves a lot of shared memory. In at least one embodiment, the principles, techniques, methods, and systems disclosed in conjunction with FIG. 9 can be used in connection with one or any combination of embodiments described further in conjunction with at least FIGS. 1-8, and 10A-23.

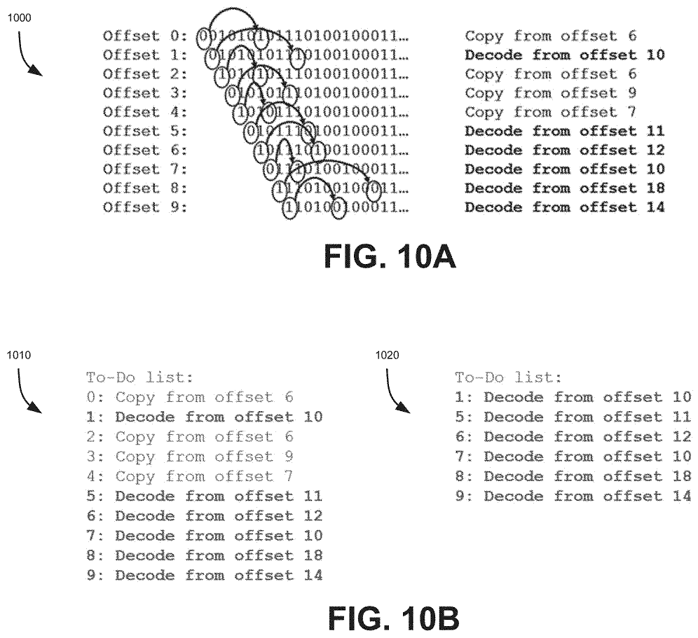

FIG. 10A illustrates a representation of a pruning operation 1000 according to at least one embodiment. In at least one embodiment, a pruning operation 1000 reduces wasteful tasks (e.g., processing tasks, computing tasks) such as unnecessarily decoding an entire data segment for each offset and by focusing tasks on offsets correctly correlated with a code. Without pruning, in some situations, there are 48 offsets per o2o vector to be considered, which results in 98% of tasks being wasted. In at least one embodiment, pruning operation 1000 begins with decoding a first subportion (e.g., portion of an offset, a portion of a subsegment, a portion of an overlapping portion) of data for each overlapping portion of data (e.g., each offset). In at least one embodiment, pruning operation 1000 begins with decoding a first possible code for offsets 1-9 due to computing constraints and determining that decoding a next code for offsets 1-9 may be a decoding task that will be handled by decoding for another offset. In at least one embodiment, decoding offsets generates and/or outputs results (e.g., elements, literals) of said decoding. In at least one embodiment, decoding a first possible code reveals said first possible code's end point (e.g., indicates where subsequent decoding would begin). According to at least one embodiment in FIG. 10A, decoding first possible codes for a data segment at offset 0 and offset 2 results in a code that ends on said data segment's fifth bit; therefore, without pruning operation 1000, decoding with offsets 0 and 2 would continue with said data segment's sixth bit; with pruning operation 1000, however, decoding with offsets 0 and 2 does not continue and decoding of said data segment for offsets 0 and 2 is based on results from decoding with offset 6 (e.g., decoding for offsets 0 and 2 are copied from offset 6, decoding for offsets 0 and 2 are skipped).

In at least one embodiment, decoding with an offset would continue with an offset not yet decoded, pruning operation 1000 determines what future decoding operation can be used for said offset. According to at least one embodiment illustrated in FIG. 8, after decoding a first code of a data segment with offset 1, decoding would continue with said data segment's tenth bit without pruning operation 1000, but with pruning operation 1000, decoding would be based on a future decoding with offset 10. In at least one embodiment, decoding from one offset landing in another offset that is going to be decoded anyway is known as convergence. In at least one embodiment, lower offsets are more likely to converge because larger offsets often decode past a number of possible offsets. In at least one embodiment, pruning operation 1000 reduces wasted tasks by about half.

FIG. 10B illustrates a representation of a to-do list 1010 created from decoding one code from each offset during pruning operation 1000. In at least one embodiment, pruning operation 1000 includes to-do list 1010 represented in FIG. 10B. Bold-lettered tasks of to-do list 1010 represent work required for decoding remaining bits of a data segment, and non-bold-lettered tasks of to-do list 1010 represent copy entries to be copied into an offset. In at least one embodiment, for distributing work, to-do list 1010 is filtered (e.g., pared down) to only include decode entries (e.g., copy entries are removed) to create filtered to-do list 1020. In at least one embodiment, creating filtered to-do list 1020 uses an operation, which, in a library (e.g., NVIDIA Thrust library), is called copy if. In at least one embodiment, to-do list 1010 is conceptualized as a radix of one bit, where each bit is 1 or 0, and is processed with a scan such as a prefix sum, which includes use of a sum operator for addition. In at least one embodiment, to-do list 1010 is processed with a prefix sum. In at least one embodiment, processing to-do list 1010 is done with an atomic operation (e.g., operations that run completely independently of any other processes; completing a single step relative to other threads; steps or variables do not appear incomplete, a step performed in an indivisible way) looping over elements of to-do list 1010, of which some require work and others are just copies. In at least one embodiment, threads that were assigned an element with no work to do increment an atomic variable to find a new element that no other thread has processed, and once each thread has a work item or is off an array's end, then all said threads start to decode. In at least one embodiment, atomics are fast at block level and modern CUDA has special optimizations for warp-level atomic operations. In at least one embodiment, the principles, techniques, methods, and systems disclosed in conjunction with FIGS. 10A-B can be used in connection with one or any combination of embodiments described further in conjunction with at least FIGS. 1-9, and 11-23.

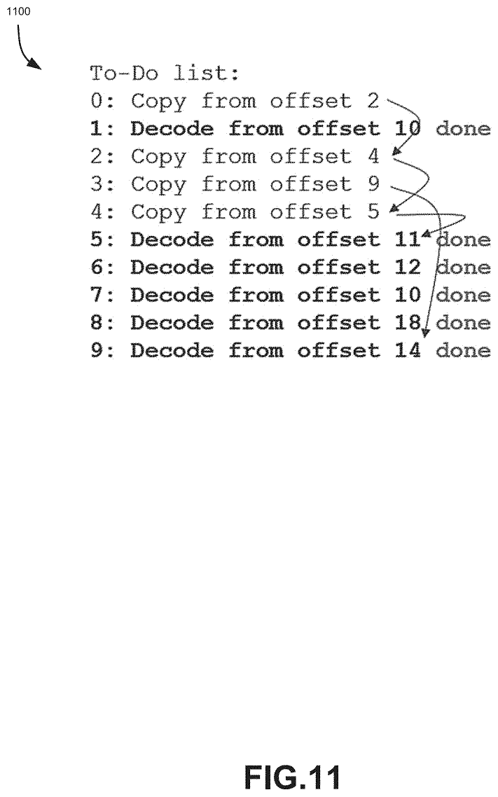

FIG. 11 illustrates a to-do list 1100 after decoding is complete, according to at least one embodiment. In at least one embodiment, to-do list 1100 is a part of pruning operation 1000. In at least one embodiment, when decoding is complete, as with rows 1 and 5-9 in to-do list 1100, copying steps are now required, but such copying steps may sometimes point to other copies, such as row 0, which needs to copy from row 2, which needs to copy from row 4, which is a copy of row 5. In at least one embodiment, rows (e.g., lines) of a to-do list are based on offsets within a data segment. In at least one embodiment, each copy will resolve to a decode, and there should be no loops because each copy must point to an element that is greater than itself, wherein such a structure (e.g., rules) for copying can be seen as a tree structure. In at least one embodiment, a structure for copying is similar to a disjoint set algorithm (e.g., union-find algorithm), wherein each element is in one of three states: 1) already decoded, in which case said element requires no processing, such as with row 7 of to-do list 1100; 2) a copy pointing to a decoded element, in which case a result may be copied, such as with row 3 pointing to row 9 of to-do list 1100; 3) a copy pointing to a copy, in which case both elements are merged, such as rewriting row 0 to point to row 4 because row 0 points to row 2, which points to row 4 in to-do list 1100. In at least one embodiment, minimum copy distance is 1, (e.g., row 4 pointing to row 5 in to-do list 1100), wherein merging two elements adds copy distances together so if said minimum copy distance was originally 1, then after processing each element once, a new minimum copy distance is 2; after the next iteration, the new minimum will be 4, then 8, then 16, and so on. In at least one embodiment, the maximum copy distance equals a data segment's maximum number of possible offsets, and therefore, an algorithm for copying will terminate in no more than log base 2 of said maximum number of possible offsets. In at least one embodiment, the principles, techniques, methods, and systems disclosed in conjunction with FIG. 11 can be used in connection with one or any combination of embodiments described further in conjunction with at least FIGS. 1-10B, and 12-23.

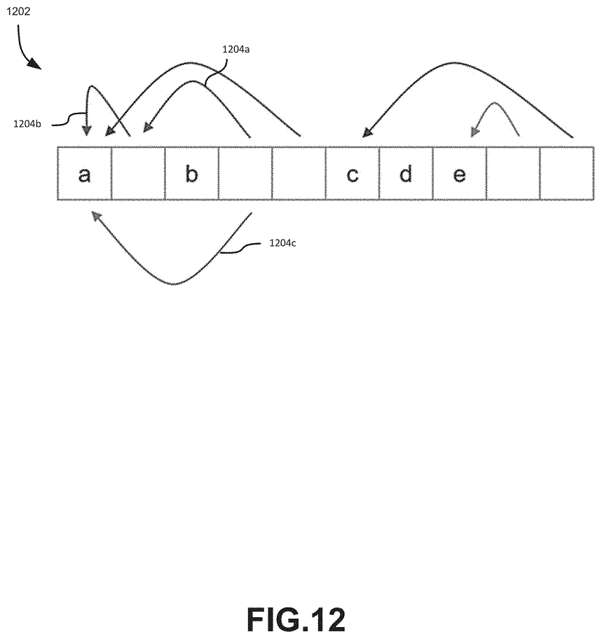

FIG. 12 illustrates array 1202 (e.g., array of elements) operated upon by a lookback algorithm using pointers, according to at least one embodiment. Array 1202 contains elements (e.g., memory block for a literal, space for a literal, an empty space, a pointer, or a literal) that are complete (e.g., contains a decoded literal) and elements that are not complete (e.g., empty). In at least one embodiment, completing all elements of array 1202 requires pointers (arrows of FIG. 12) that transitively resolve to complete elements. In at least one embodiment, a lookback algorithm is used to resolve all back references in an LZ77 stream (e.g., a set of data segments compressed by an LZ77 algorithm). In at least one embodiment, a lookback algorithm includes rules as follows: 1) if an element is already a literal character, no work is done, as with left-most element (literal “a”) of array 1202; 2) if an element points to a literal, copy said literal pointed to, as with right-most element (pointer directed at literal “c”) of array 1202; 3) if an element points to a pointer, coalesce said pointers, such as pointer 1204a and pointer 1204b being combined to become pointer 1204c. In at least one embodiment, repeating a process of lookback algorithm allows for processing an entire LZ77 stream into an output stream. In at least one embodiment, the principles, techniques, methods, and systems disclosed in conjunction with FIG. 12 can be used in connection with one or any combination of embodiments described further in conjunction with at least FIGS. 1-11, and 13A-23.

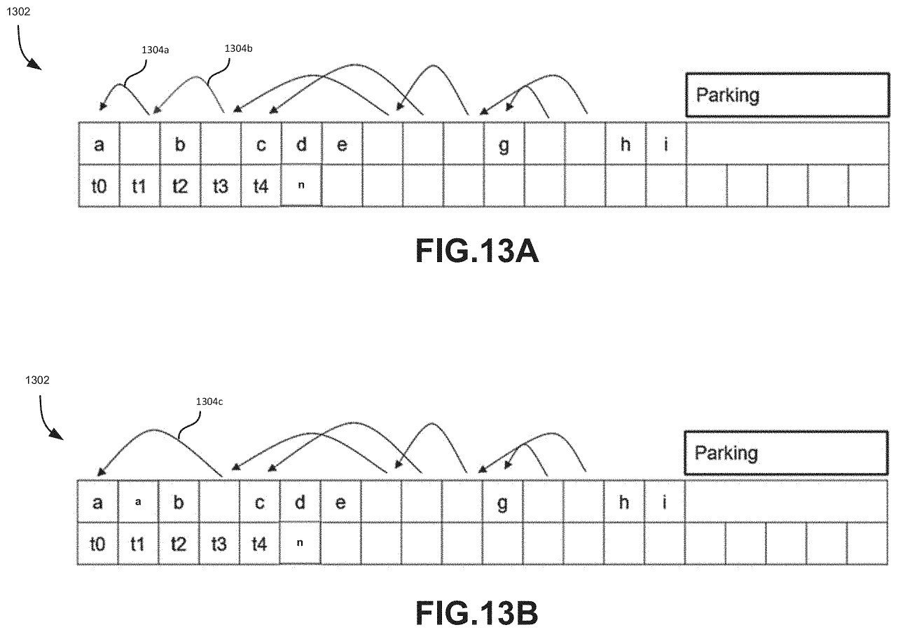

FIG. 13A illustrates an array 1302 and assigned threads executing a lookback algorithm, according to at least one embodiment. In at least one embodiment, a distribution of work among threads uses atomics. Often, said distribution is necessary because a DEFLATE block can contain about 160 kilobytes, which often exceed available threads. For FIG. 13A, five threads (t0 through t4) are assigned to a single element, and a global atomic variable n indicates an element to be processed next. Each of said five threads executes one step of a lookback algorithm according to at least one embodiment. In at least one embodiment, if a thread finds that it has no work to do because said thread is already pointing at a literal, said thread will do nothing, such as in organization 1302 with thread to, whose assigned element already contains a literal “a,” and therefore, thread t0 will look for a new work item. If a thread has work to do, it remains with its assigned element, such as with thread t3 of organization 1302.

FIG. 13B illustrates array 1302 after one iteration of work, according to at least one embodiment. In FIG. 13B, thread t1's operation 1304b (e.g., pointer, arrow) of copying from left-most element of array 1302 has been completed as shown with a second literal “a” in FIG. 13B. Thread t3 has coalesced pointers 1304a and 1304b into single pointer 1304c, but did not copy t1's literal because both work items of coalescing pointers and copying from t1 attempted to happen simultaneously, so only one work item executed. If thread t3 were used, t3 would be reading and writing to one memory location simultaneously, which would lead to undefined behavior. For threads assigned to array 1302 of FIG. 13B, only thread t3 needs to remain (e.g., stay put) and do more work. In at least one embodiment, the principles, techniques, methods, and systems disclosed in conjunction with FIGS. 13A-B can be used in connection with one or any combination of embodiments described further in conjunction with at least FIGS. 1-12, and 14A-23.

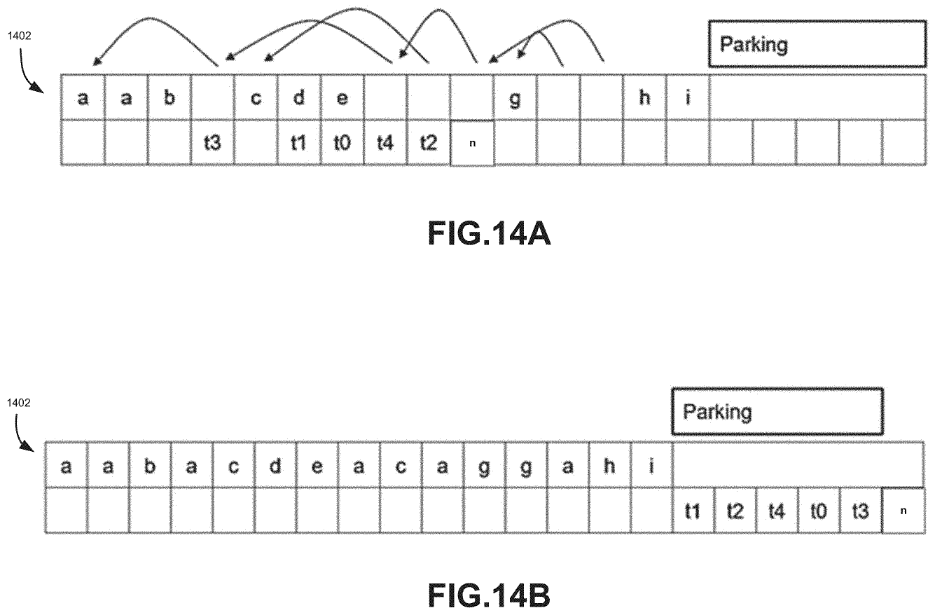

FIG. 14A illustrates an array 1402 after available threads have been reassigned, according to at least one embodiment. In at least one embodiment, threads are assigned by an atomic in any order so predicting said thread assignments is not possible, but using atomics ensures each thread gets a unique work item and that no work item gets skipped. In at least one embodiment, threads assigned to array 1402 of FIG. 14A progress from left to right (e.g., forward progress) until said threads reach a parking area, which is beyond array 1402 (e.g., bytes to be worked on, data segment to be worked on). In at least one embodiment, a parking area is an abstracted representation of organizing threads and their execution. In at least one embodiment, when a thread is in said parking area, said thread does not work but also does not progress—said thread stays in its location in said parking area, waiting for other threads to complete their work.

FIG. 14B illustrates an array 1402 with all threads (t0, t1, t2, t3, t4) parked during operation of a lookback algorithm, according to at least one embodiment. With all threads in a parking area (e.g., parked, waiting), global atomic variable n must be one beyond said parking area, wherein n is observable by all threads so all workers can simultaneously return, and a simultaneous return is important to maintain synchronization of said lookback algorithm. In at least one embodiment, said global atomic variable is incremented as many times as there are elements in an array. In at least one embodiment, said global atomic variable is incremented a number of times fewer than an array's number of elements because of warp-level atomic aggregation (e.g., combining atomic operations from multiple threads in a warp, a basic unit of execution, into a single atomic), a feature that is present and used automatically by at least some GPU compliers and architectures. In at least one embodiment, a lookback algorithm works at grid level in global memory and/or at block level in shared memory. In at least one embodiment, block-level LZ77 resolution (e.g., decompression of a coded data segment) cannot be complete because some pointers (e.g., arrows) will point into a previous block (e.g., data segment). In at least one embodiment, block-level atomics and memory operations are faster than in global memory and, therefore, a lookback algorithm is performed on an LZ77 stream generated per-block, and then results from said performing said lookback algorithm are copied into global memory LZ77. In at least one embodiment, performing said lookback algorithm at block-level and global level is faster (e.g., three times) over performing said lookback algorithm at said global level alone. In at least one embodiment, the principles, techniques, methods, and systems disclosed in conjunction with FIGS. 14A-B can be used in connection with one or any combination of embodiments described further in conjunction with at least FIGS. 1-13B, and 16A-23.

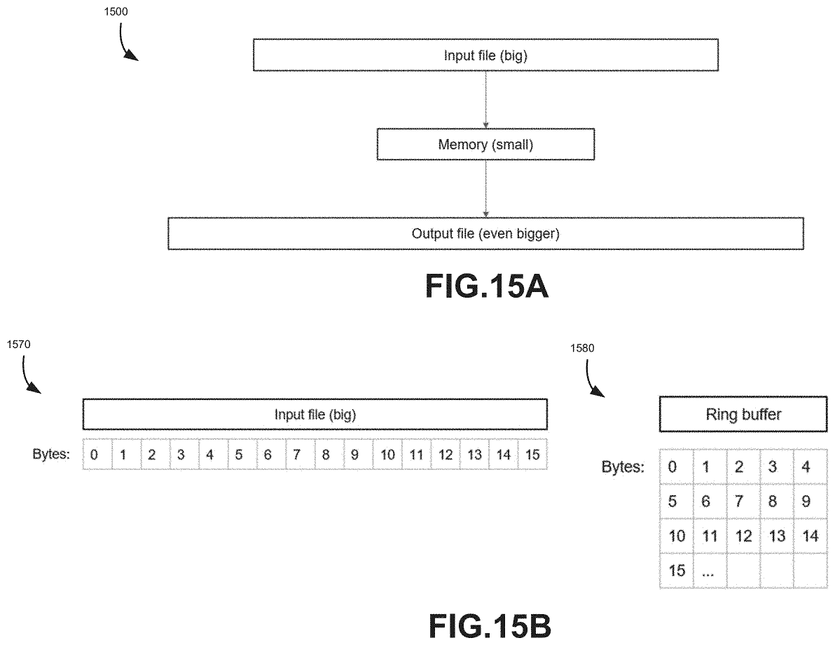

FIG. 15A illustrates a representation 1500 of how data is decompressed, according to at least one embodiment. In at least one embodiment, representation 1500 illustrates relative sizes between an input file, a memory where decompression is performed on said input file, and an output file, which is said input file decompressed. In at least one embodiment, data is decompressed using a streaming algorithm, (e.g., DEFLATE, GZIP) discussed further in conjunction with at least FIGS. 1, 4, and 21, which means that said algorithm can start outputting results of compression or decompression of a file before it reaches said file's end, which also means that a file (e.g., input file) could be as large as what a disk (e.g., an external hard drive) can hold, even if it is much larger than a GPU's memory, which poses a problem for a GPU algorithm, wherein decompression of a file often copies all of a file's data into GPU memory where said file is decompressed and output to a CPU. Therefore, in at least one embodiment, a method for processing more data than can fit into GPU memory that is efficient and streaming (e.g., able to send first byte of decompressed data without waiting for last bytes to be decompressed) uses a ring buffer (e.g., a circular buffer, circular queue, cyclic buffer) to optimize communication (e.g., data transfers) between a CPU and GPU. In at least one embodiment, a ring buffer may be located in a memory found on a CPU, GPU, a processor other than a CPU or GPU, or some combination thereof.

FIG. 15B illustrates an input file 1570 and ring buffer 1580, according to at least one embodiment. In at least one embodiment, FIG. 15B illustrates, at least in part, communication from a CPU to a GPU. In at least one embodiment, a CPU can write (e.g., copy) data from input file 1570 into ring buffer 1580. In at least one embodiment, a GPU can write (e.g., copy) data from input file 1570 into ring buffer 1580. In at least one embodiment, input file 1570 is a very big file on a disk of a CPU, wherein input file 1570 is more than can be allocated on a GPU and a CPU. In at least one embodiment, a buffer is allocated in memory (e.g., GPU memory, CPU memory) that is large enough to hold a chunk of data to be processed. In at least one embodiment, bytes of input file 1570 are copied into ring buffer 1580 in a circular fashion, wherein when said copying reaches ring buffer's 1580 end, copying starts again at the beginning of ring buffer 1580. In at least one embodiment, blocks 0-15 of input file 1570 each represent a position of a byte of data within said file. In at least one embodiment, blocks 0-17 of ring buffer 1580 represent positions (e.g., elements, sections, blocks) of where a byte is stored. In at least one embodiment, so long as ring buffer 1580 holds enough bytes to be worked on (e.g., decompressed), said bytes will be processed. In at least one embodiment, the principles, techniques, methods, and systems disclosed in conjunction with FIGS. 15A-B can be used in connection with one or any combination of embodiments described further in conjunction with at least FIGS. 1-14B, and 16A-23.

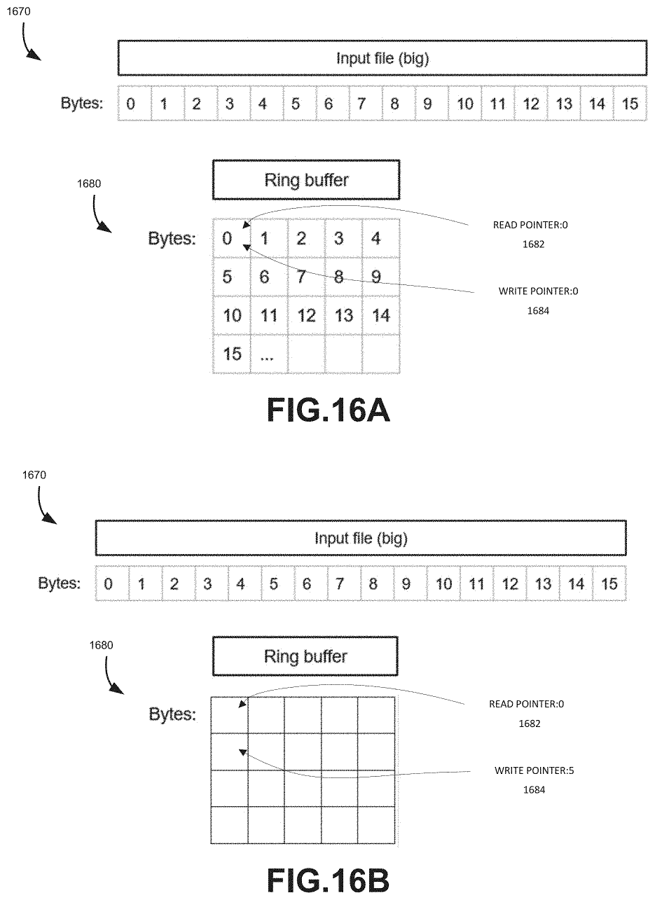

FIG. 16A illustrates an input file 1670 and ring buffer 1680, according to at least one embodiment. In at least one embodiment, to keep track of organizing ring buffer 1680, read pointer 1682 and write pointer 1684 are used. In at least one embodiment, read pointer 1682 points to a byte from input file. In at least one embodiment, if ring buffer 1680 is empty, a GPU has no data to process and must wait for a CPU to send data over to ring buffer 1680. In at least one embodiment, a CPU looks at read pointer 1682 and write pointer 1684 to determine if there is space in ring buffer 1680, and if so, said CPU will fill ring buffer 1680.

FIG. 16B illustrates an input file 1670 and ring buffer 1680 after a processor has copied bytes from input file 1670 to ring buffer 1680, according to at least one embodiment. In at least one embodiment, a CPU fills ring buffer 1680 by copying (e.g., writing) input file's 1670 first 5 bytes (from blocks 0, 1, 2, 3, and 4) and into first 5 elements (e.g., sections) of ring buffer 1680, which is ring buffer's 1680 top row. In at least one embodiment, write pointer 1684 is updated to write to ring buffer's 1680 fifth element. In at least one embodiment, a GPU is monitoring read pointer 1682 and write pointer 1684, and when said GPU determines that write pointer 1684 is five positions ahead of read pointer 1682, GPU determines that there are 5 bytes available for processing. In at least one embodiment, the principles, techniques, methods, and systems disclosed in conjunction with FIGS. 16A-B can be used in connection with one or any combination of embodiments described further in conjunction with at least FIGS. 1-15B, and 17-23.

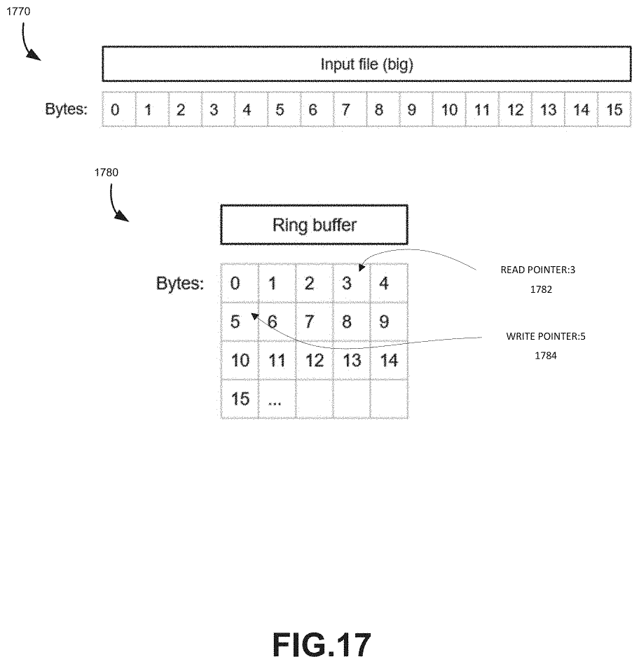

FIG. 17 illustrates an input file 1770 and ring buffer 1780 after a processor has processed some bytes in ring buffer 1780, according to at least one embodiment. In FIG. 17, a GPU has processed three bytes stored in ring buffer 1780 so now read pointer 1782 can be increased by 3, which signals to a CPU that said bytes are no longer necessary. Read pointer 1782 and write pointer 1784 now have a distance of 2 between them, which means that all but two bytes still need to be processed by said GPU. Said CPU can now copy another 3 bytes into positions 5, 6, and 7 of ring buffer 1780. In at least one embodiment, said CPU can now overwrite old bytes in positions 0, 1, and 2 with another 3 bytes because of overlap. In at least one embodiment, a GPU's processing of bytes in a ring buffer is not sequential and can be performed on bytes in various combinations of positions. In at least one embodiment, an entire input file is processed using techniques discussed further at least in conjunction with FIGS. 15A-B, 16A-B, and FIG. 17.

In at least one embodiment, ring buffers 1580, 1680, 1780 and pointers 1682, 1684, 1782, 1784 are located in memory accessible to both a GPU and CPU, and therefore, shared memory in said GPU is not an option. In at least one embodiment, lots of data is transferred from a CPU to a GPU, and said data is transferred to a local memory of some type. In at least one embodiment, for pointers 1682, 1684, 1782, 1784, one processor (e.g., either a GPU or CPU) is only writing and another processor is only reading; a GPU and CPU cannot both read and write simultaneously or otherwise. If both a GPU and CPU were writing simultaneously, a race condition may occur, which is why storing start and length data is a not a good option; storing start and end information is a better option. In at least one embodiment, each pointer has only one writer to said pointer. In at least one embodiment, only a CPU writes to a ring buffer and only a GPU reads a ring buffer. In at least one embodiment, only a CPU writes a write pointer and only a GPU reads said write pointer. In at least one embodiment, only a GPU writes a read pointer and only a CPU reads a read pointer. In at least one embodiment, a pointer's very top bit indicates that there is no more data (e.g., a bit value of 1 means no more data). In at least one embodiment, when a CPU writes data into a GPU's memory, said GPU cache has been monitored to be invalidated properly. In at least one embodiment, pointers are updated only after a ring buffer is updated. In at least one embodiment, a memory fence is used (e.g., a memory barrier, a fence instruction, an instruction that guarantees for all observers that one memory update has occurred before a subsequent memory update, an instruction causing a CPU to place a constraint on memory operations issued before and after said instruction).

In at least one embodiment, ring buffers 1580, 1680, 1780 includes managed memory, wherein an application programming interface (API) (e.g., CUDA (NVIDIA), one API (Intel), Open GL, Vulkan) allows both a CPU and GPU to read and write from it. In at least one embodiment, an API managing a ring buffer is a driver API or a runtime API. In at least one embodiment an API will copy memory over from CPU to GPU and vice-versa so all reads and writes are local. In at least one embodiment, to address a penalty of copying memory to local storage, a prefetch is used—when a CPU needs to write data to local memory, it can issue a prefetch with an address and length of memory to write to. Then said CPU can start writing while a memory controller works to get said data into CPU memory. When complete, a GPU will be a processor that next accesses said memory so said data can be prefetched back into GPU memory. In at least one embodiment, because a GPU is a bottleneck in processing data, a CPU performs preparatory work to said data so said data is ready to be processed by said GPU. In at least one embodiment, managed memory properly invalidates a cache when a CPU writes into a GPU's memory.

In at least one embodiment, instructions (e.g., an API call, an API function) for managed memory with prefetch is executed to manage ring buffers 1580, 1680, 1780, according to at least one embodiment. In at least one embodiment, managed memory with prefetch for a ring buffer includes the steps of: prefetching memory from GPU to CPU; writing data to CPU memory; prefetching memory from CPU to GPU; waiting for more space in a ring buffer; and repeating said steps. In at least one embodiment, said steps are performed in a different order.

In at least one embodiment, a pointer is stored in memory that is closest to said memory's reader (e.g., GPU or CPU). In at least one embodiment, a CPU writes write pointer 1684, 1784 and a GPU reads said write pointer, wherein said write pointer is stored on said GPU. In at least one embodiment, a GPU writes read pointer 1682, 1782 and a CPU reads said read pointer, wherein said read pointer is stored on said CPU.

In at least one embodiment, both a CPU and GPU determine read pointers' 1682, 1782 and write pointers' 1684, 1784 values (e.g., statuses, details on what they are pointing to) to in turn determine how full or empty a ring buffer is. In at least one embodiment, only a CPU writes to write pointer 1684, 1784, and therefore said CPU does not need to read write pointer 1684, 1784 as said CPU already has values on what said CPU wrote regarding write pointer 1684, 1784. In at least one embodiment, a CPU or GPU does not read a pointer value that said CPU or GPU just wrote, wherein said pointer value is cached. In at least one embodiment, both a CPU and GPU maintain an internal copy of what said CPU and GPU wrote to their respective pointers, and therefore, each pointer is capable of having only one writer and one reader. In at least one embodiment, the principles, techniques, methods, and systems disclosed in conjunction with FIG. 17 can be used in connection with one or any combination of embodiments described further in conjunction with at least FIGS. 1-16B, and 18-23.

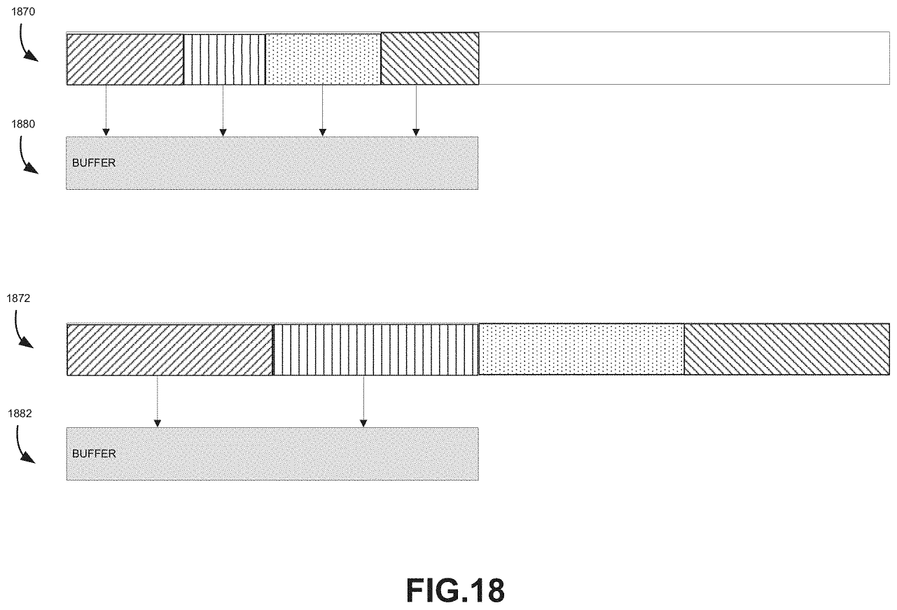

FIG. 18 illustrates how a GPU writes to a buffer, according to at least one embodiment. In at least one embodiment, a buffer (e.g., ring buffer) is being freed up a little at a time, and as soon as a data segment (with each data segment represented by a block filled in with a pattern) from an input file 1802 can fit in said buffer, then said data segment and its bytes are written into said buffer. With input file 1870, all data segments can eventually be written by a GPU into buffer 1880 one at a time or in combined chunks. With input file 1872, only two data segments can be written into buffer 1882, with remaining data segments forced to wait for buffer 1882 to have free space before a GPU can write another data segment into buffer 1882. Each time a GPU performs a write operation into a buffer, a write pointer is updated. In at least one embodiment, each time a GPU writes one or more data segments into a buffer, a prefetch and update to a write pointer is required, which adds to computational overhead. In at least one embodiment, a GPU waits for a buffer to free up enough space for multiple data segments to be written into said buffer to minimize prefetching operations and updates to write pointers. In at least one embodiment, a GPU writes to a buffer only when said buffer is about half-empty, and said writing only fills one half of said buffer on either its left side or right side, wherein a buffer's left or right sides are an abstracted representation of how a buffer's memory is organized. In at least one embodiment, a GPU writes to a buffer only when said buffer is exactly half-empty. In at least one embodiment, a GPU writes to a buffer only when said buffer is exactly half-empty, and said writing only fills one half of said buffer on either its left side or right side. In at least one embodiment, having a GPU write to a buffer only when said buffer is half-empty aligns prefetch operations with cache pages, resulting in more efficient prefetching. In at least one embodiment, one-half of a buffer is for data transferred from CPU to GPU and said buffer's other half is for transferring data GPU to CPU (e.g., double-buffering), wherein said halves of said buffer may switch roles (e.g., one-half of a buffer is for data transferred from CPU to GPU and then said half gets used for data transferred from GPU to CPU). In at least one embodiment, the principles, techniques, methods, and systems disclosed in conjunction with FIG. 18 can be used in connection with one or any combination of embodiments described further in conjunction with at least FIGS. 1-17, and 19-23.

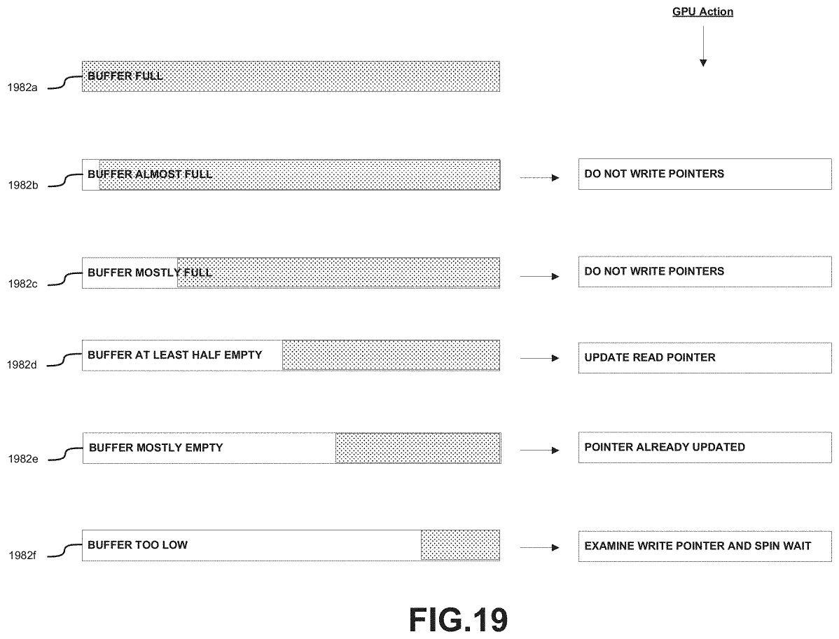

FIG. 19 illustrates GPU actions corresponding with buffer states, according to one embodiment. In at least one embodiment, a CPU will only write data and update pointer values if buffer 1982 (e.g., a ring buffer) is at least half-empty, wherein a GPU will not update said CPU regarding pointers (e.g., no pointer will be updated) until said buffer is at least half-empty. In at least one embodiment, a GPU does not update any pointers while a buffer 1982 is more than half-full. In at least one embodiment, a CPU will fill (e.g., write to) buffer 1982 once a GPU reports that said buffer is at least half-empty. In at least one embodiment, enough data in buffer 1982 will have been processed that there is not enough data left for decoding, which causes a GPU to examine a write pointer. In at least one embodiment, between updating a read pointer and examining a write pointer, enough time has elapsed for a CPU to fill up one-half of buffer 1982. In at least one embodiment, memory operations keep up with GPU decompression operations so that examination of a write pointer never leads to spin waiting. In at least one embodiment, an optimal condition occurs when a GPU never examines a write pointer more than once per half-buffer. In at least one embodiment, time spent on all data transfers is entirely latency hidden and processing to adjust pointers accounts for around 1% of all processing, and small files and endless files decompress at identical or similar performance rates. In at least one embodiment, methods and techniques described in conjunction with FIG. 19 can be used for GPU to CPU communications or CPU to GPU communications.

Buffer 1982 is illustrated in different states 1982a-f of fullness (e.g., capacity), according to at least one embodiment. Buffer 1982a is a buffer full of data (indicated by a dotted background filling said buffer), so a GPU takes no action with respect to pointers. Buffer 1982b is a buffer that is almost full, but because it is not at least half-empty, it does not write pointers, according to at least one embodiment. Buffer 1982c is more than half-full, but because it is not at least half-empty, it does not write pointers, according to at least one embodiment. Buffer 1982d is at least half-empty so a GPU updates a read pointer, according to at least one embodiment. Buffer 1982e is mostly empty, but because of that, a GPU would have already updated a read pointer, so said GPU takes no action, according to at least one embodiment. Buffer 1982f is mostly empty but does not contain enough data for a decoding (e.g., decompression) operation, so a GPU examines a write pointer and spin waits (e.g., busy-waiting, busy-looping, spinning, repeatedly checks if a condition is true). In at least one embodiment, the principles, techniques, methods, and systems disclosed in conjunction with FIG. 19 can be used in connection with one or any combination of embodiments described further in conjunction with at least FIGS. 1-18, and 20-23.

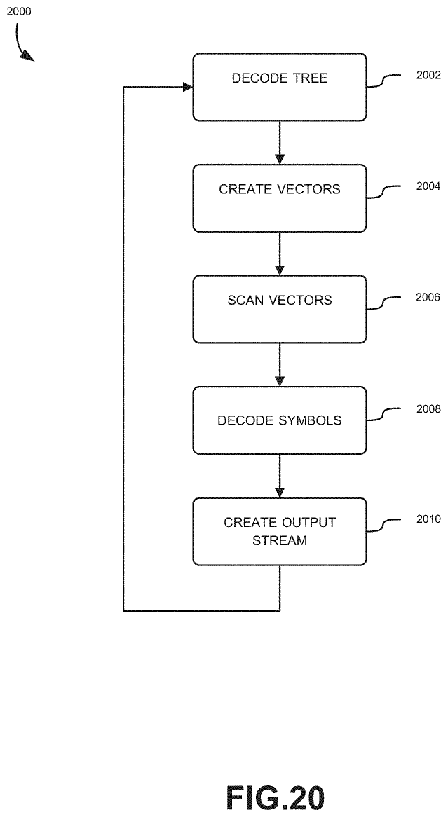

FIG. 20 illustrates a process 2000 for decompressing a stream (e.g., a series) of blocks (e.g., bit strings), according to at least one embodiment. In at least one embodiment, the principles, techniques, methods, and systems disclosed in conjunction with FIG. 20 can be used in connection with one or any combination of embodiments described further in conjunction with at least FIGS. 1-19, and 21-23. In at least one embodiment, process 2000 decodes a DEFLATE stream, which includes a series of DEFLATE blocks, wherein each block is preceded by a header. Process 2000 includes decoding (e.g., computing) a tree (e.g., a Huffman tree, a binary tree) from a DEFLATE block at step 2002. In at least one embodiment, computing a Huffman tree includes decoding bits of a DEFLATE block's header (e.g., at a file's beginning). In at least one embodiment, process 2000 includes storing a value representing starting positions for overlapping portions of the data, which is further discussed in conjunction with at least FIGS. 7A-B. In at least one embodiment, process 2000 includes decoding overlapping portions of the data, wherein each portion begins with a different bit of the data and ends with the last bit of the data, which is discussed further in conjunction with at least FIGS. 7A-B. In at least one embodiment process 2000 includes calculating a number of extra bits required from data next in sequence to complete decoding any incomplete codes in overlapping portions of the data, which is discussed further in conjunction with at least FIGS. 7A-B. In at least one embodiment, process 2000 includes creating one or more vectors based, at least in part on decoding overlapping portions of the data, which is discussed further in conjunction with at least FIGS. 7A-B. In at least one embodiment, process 2000 includes sweeping the vectors using composition operations to determine, at least in part, starting locations for decoding the data, which is discussed further at least in conjunction with FIGS. 8-9.

In at least one embodiment, process 2000 includes outputting an element of decoded data in parallel, wherein the processor includes threads, and at least one thread outputs one element by copying another element.

In at least one embodiment, creating vectors 2004 includes using a Huffman tree decoded at step 2002 to process all offsets in all strides to make one o2o vector per stride.

In at least one embodiment, scanning vectors 2006 includes scanning o2o vectors created at step 2004 to find each stride's correct offset. In at least one embodiment, scanning vectors 2006 reveals a next DEFLATE block's starting location (e.g., starting position) and process 2000 includes sending said starting location to a different kernel dedicated to said next DEFLATE block without waiting for steps 2008 or 2010 to be complete.

In at least one embodiment, decoding symbols (e.g., literals) 2008 includes decoding symbols in all strides into an LZ77 stream that includes literals and back references.

In at least one embodiment, creating an output stream 2010 includes resolving all back references of an LZ77 stream created in step 2008 to create an output stream of literals. After creating output stream 2010, process 2000 is repeated on a following DEFLATE block, beginning with step 2002.

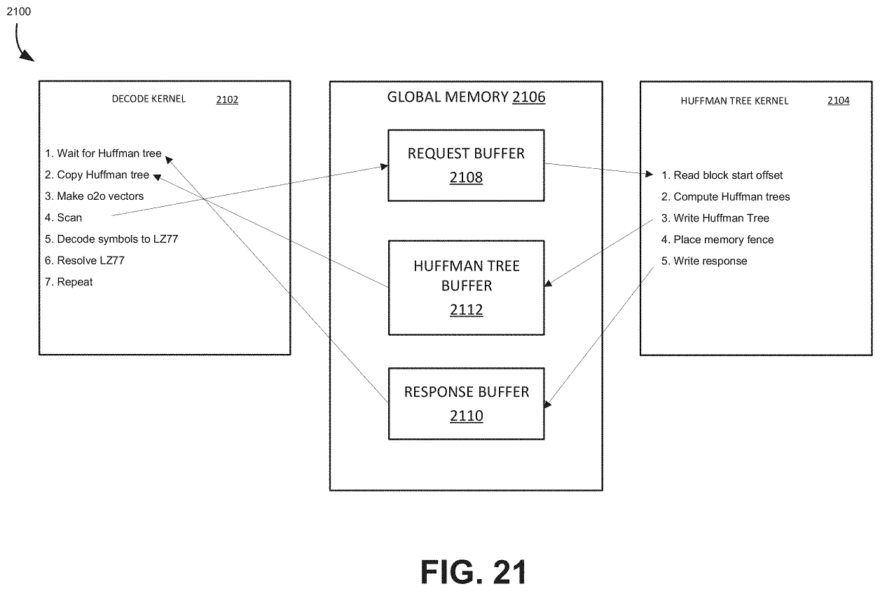

FIG. 21 illustrates a framework 2100 for decompressing data streams, according to at least one embodiment. In at least one embodiment, framework 2100 includes at least one or more kernels, which area functions executed on a GPU). In at least one embodiment, two or more kernels are fused into one kernel. In at least one embodiment, framework 2100 includes a decode kernel 2102 programmed to execute steps 1-7 as illustrated in FIG. 21, wherein said steps include: waiting for a Huffman tree; copying said Huffman tree; make o2o vectors; perform a scan; decode symbols to LZ77; resolve said LZ77; and repeat.

In at least one embodiment, framework 2100 includes a Huffman tree kernel 2104 programmed to execute steps 1-5 as illustrated in FIG. 21, wherein said steps include: reading a block start offset; computing Huffman trees; writing a Huffman tree; executing a memory fence; and writing a response.

In at least one embodiment, framework 2100 includes at least three buffers in global memory 2106. In at least one embodiment, said at least three buffers are in a level 2 cache (L2 cache) if data is small enough to fit in said cache. In at least one embodiment, framework 2100 includes two pointers, wherein said pointers are offsets into an input stream of bytes. In at least one embodiment, each pointer has a starting condition of 0 because a GZIP file has a header so no decoding begins at 0. In at least one embodiment, when decode kernel 2102 wants Huffman tree kernel 2104 to begin decoding a Huffman tree in a block, decode kernel 2102 indicates that by writing an offset into request buffer 2108, wherein Huffman tree kernel 2104 detects request buffer 2108 is no longer equal to response buffer 2110 and then begins working on decoding a next block's header.

In at least one embodiment, latency hiding (e.g., optimizing) of Huffman tree decoding includes Huffman tree creation beginning when a request is made at scan operation (step 4) in decode kernel 2102, wherein a result is not required until decode kernel 2012 gets back to step 1 and waiting for a Huffman tree so that creating a Huffman tree for a next block can be done while decoding and LZ77 decompression is running. In at least one embodiment, Huffman tree decoding is faster than Huffman tree creation and resolution of an LZ77 stream, eliminating any wait in decode kernel 2102. In at least one embodiment, Huffman tree kernel only requires one threadblock, wherein other threadblocks are allocated to decode kernel 2102.

In at least one embodiment, a memory fence is placed between writing of a Huffman tree (step 3) of Huffman tree kernel 2104 and writing a response (step 5) of Huffman tree kernel 2104. In at least one embodiment, Huffman tree buffer 2112 is only large enough for Huffman trees of a single block. In at least one embodiment, each kernel 2102, 2014 is operating on its own copy of Huffman trees in their own shared memory, wherein said shared memory copy and a global memory copy make two buffers, which results in double-buffering without using extra global memory.

In at least one embodiment, Huffman tree kernel 2104 exits when decode kernel 2102 finds an end to a file and writes a request value of negative one (−1), which synchronizes quitting by both kernels.

In at least one embodiment, a scan (step 4) performed by decode kernel 2102 includes a calculation of one or more offsets, which are then written to request buffer 2108, as illustrated with an arrow pointing from step 4 of decode kernel 2102 to request buffer 2018 in FIG. 21. In at least one embodiment, Huffman tree kernel 2104 reads one or more offsets stored in request buffer 2108 as illustrated with an arrow pointing from request buffer 2108 to step 1 of Huffman tree kernel 2104 in FIG. 21. In at least one embodiment, Huffman tree buffer 2112 writes (step 3) a computed Huffman tree to Huffman tree buffer 2112, as illustrated by an arrow pointing from step 3 of Huffman tree kernel 2014 to Huffman tree buffer 2112. In at least one embodiment, decode kernel 2102 copies a Huffman tree stored (e.g., written to) Huffman tree buffer 2112, as illustrated by an arrow pointing from Huffman tree buffer 2112 to step 2 of decode kernel 2102 in FIG. 21.

In at least one embodiment, Huffman tree kernel 2104 uses a memory fence (step 4) and writes a response (step 5) to response buffer 2110, as illustrated by an arrow pointing from step 5 of Huffman tree kernel 2104 to response buffer 2110 in FIG. 21.

In at least one embodiment, decode kernel 2102 waits (step 1) for an indication that a Huffman tree has been written to Huffman tree buffer 2112, as illustrated with an arrow pointing from response buffer 2110 to step 1 of decode kernel 2102 in FIG. 21. In at least one embodiment, the principles, techniques, methods, and systems disclosed in conjunction with FIG. 21 can be used in connection with one or any combination of embodiments described further in conjunction with at least FIGS. 1-20, and 22-23.

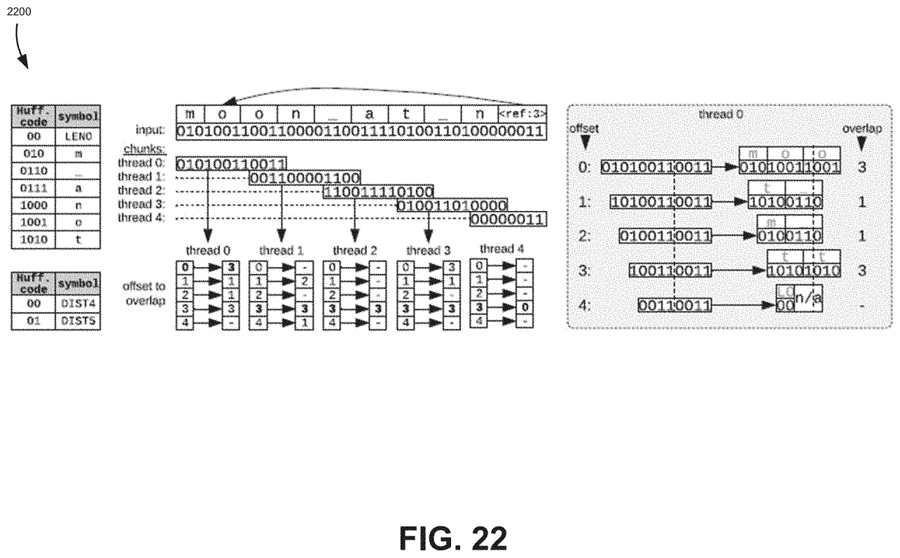

FIG. 22 illustrates an approach 2200 (e.g., algorithm), at least in part, for decompressing data in parallel, according to at least one embodiment. Codebooks are illustrated as tables on FIG. 22's left side. In at least one embodiment, each thread decodes a chunk of eight bits. In at least one embodiment, the longest combination of a length code followed by the length's extra bits, the distance code, and the distance's extra bits is five bits wide. That is, 0b00 for LENO with zero extra bits (as specified with RFC 1951: DEFLATE Compressed Data Format Specification version 1.3(“RFC 1951”)), followed by 0b01 for DIST5 with one extra bit (as specified with RFC 1951). In at least one embodiment, a combination's maximum length is five bits long so an overlap of a thread's last code combination into the subsequent chunk is at most four bits. Since said overlap is at most four bits, each thread will decode its chunk for every possible offset, i.e., [0; 4], and note a number of bits a last code would extend into a subsequent chunk in an array. In at least one embodiment, mapping from a given offset to its overlap is illustrated by sets of boxes and arrows labeled threads 0-4 and offset to overlap at the bottom of FIG. 21. Said mapping can be represented using a vector of length L, where L corresponds to the maximum number of bits a combination of length code and distance code along with their extra bits may be comprised of. Said vector may be referenced as an o2o vector. In at least one embodiment, an i-th element of an o2o-vector corresponds to an overlap into a subsequent chunk if a thread started parsing at offset i. In at least one embodiment, a process of computing an o2o-vector, i.e., decoding a chunk for all possible offsets, is illustrated for thread 0 (box outlined in dotted line) in FIG. 22. In at least one embodiment, for an offset of four bits, a thread would decode 0b00 for LENO. Since LENO is supposed to be followed by a distance code, said thread cannot properly decode a chunk for an offset of four bits, since there is no distance code beginning with 0b1 in a distance codebook as illustrated in FIG. 22. For all other offsets, said thread successfully decodes its chunk and notes a number of overlapping bits.

In at least one embodiment, approach 2200 computes (e.g., executes, performs) a prefix scan (e.g., exclusive prefix scan) over o2o-vectors using composition as an operator. In at least one embodiment, for a given binary reduction operator (e.g., addition), an exclusive prefix scan takes an array of input elements and returns an array, where the i-th output element is computed by applying a reduction operator to all input elements up to (but excluding) the i-th element, which is represented as follows:

$${y}_{i} = {⊕}_{k = 0}^{i - 1} {x}_{k}$$

In at least one embodiment, a composition operation over two o2o vectors a and b is represented as follows:

c[i]=b[a[i]],i∈[0,|L|)

In at least one embodiment, |L|, corresponds to an o2o vector's size, for example, |L| represents how many offsets or items an o2o vector holds. In at least one embodiment, a code boundary of a first Huffman code of a thread's chunk is determined by an i-th element of said thread's o2o vector that results from a prefix scan computed using a composition operator as discussed, at least in part, in conjunction with approach 2200, where i corresponds to a bit-offset of an input's first code word boundary, for example, if thread 0 was beginning at a compressed block's compressed data segment, which means if said block's first code boundary is at offset zero, each thread begins decoding from an offset that corresponds to a value found at index zero of its o2o vector. Hence, if thread 0 was beginning at a compressed block's compressed data segment, which means, its first code is at offset zero, all threads begin decoding from an offset said threads at index zero of their offset vector.

In at least one embodiment, when all threads are aware of the first code boundary within their chunk, said threads can correctly decode their chunks. However, each chunk varies with its number of bytes, so where to write decoded data to is unclear. In at least one embodiment, writing decoded data includes, at least in part, writing a stream of literals and back-references. Hence, prior to writing decoded data to an output stream, threads first count a number of bytes that each thread's chunk is contributing to said output. In at least one embodiment, a number of bytes being generated by each chunk is defined by a number of literals being decoded plus a sum over a length of all a chunk's back-references. Once said number of bytes of uncompressed data for each chunk is known, an exclusive sum (e.g., an exclusive prefix scan using the addition operator) is computed. As said exclusive sum yields offsets into an output stream for all threads, said threads can now decode their chunk and write decoded data according to the position determined using said prefix sum in said output stream.

While literals can simply be written to the output stream, back-references from LZ77 pose two challenges. Firstly, a race condition might appear when a thread decodes a back-reference while the data being referenced is not yet available. Secondly, a back-reference might point to a data segment, which itself contains a back-reference to a different data segment. In at least one embodiment, said back-references may form a chain with serial dependence. In at least one embodiment, a resolution of back-references is deferred until after all literals have been written to an output stream in order to circumvent race conditions. In at least one embodiment, the principles, techniques, methods, and systems disclosed in conjunction with FIG. 22 can be used in connection with one or any combination of embodiments described further in conjunction with at least FIGS. 1-21, and 23.

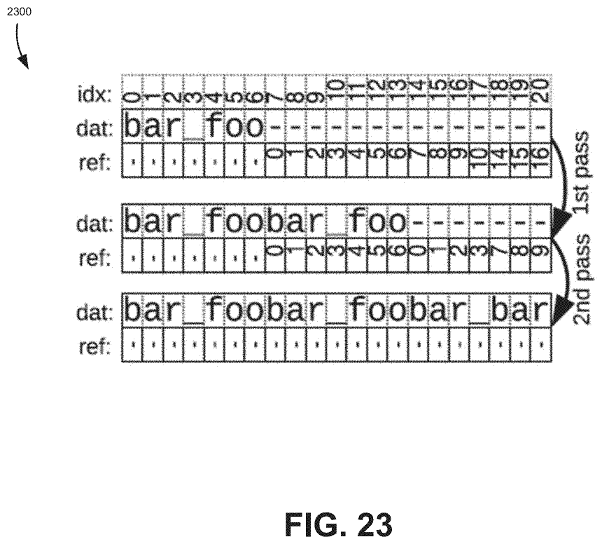

FIG. 23 illustrates an auxiliary back-reference array 2300, according to at least one embodiment. In at least one embodiment, back-reference array 2300, for every byte that is part of a back-reference, indicates an absolute offset of a byte being referenced. In at least one embodiment, to resolve back-references in parallel without degrading to a serial approach, back-references are resolved in multiple passes. With each said pass, each thread is responsible for resolving one byte of a first number P of unresolved back-references, where P equals a number of threads being launched to fully occupy all streaming multiprocessors of the GPU. Said threads check if a byte referenced by their back-reference is a literal or is another back-reference by looking at a referenced index in a ref array. In at least one embodiment, if said back-reference is a literal, said thread copies said literal and updates said ref array to indicate that said thread has resolved its back-reference. In at least one embodiment, if said back-reference is another back-reference, said thread updates its item from the ref array to point at the back-reference it just discovered. In at least one embodiment, back-reference dependencies represent a directed acyclic graph (DAG), where each node has one outgoing and possibly multiple incoming edges, and so an upper bound on a maximum number of passes required for resolving a back-reference can be determined. In at least one embodiment, after k-th pass is completed, a back-reference will have advanced by 2^{k-1} hops, and, at least, first back-references as defined by a summation shown below will have been resolved.

Σᵢ₌₀^{k-1}2ⁱ=2^{k}−1

In at least one embodiment, even in a worst case scenario where there is only serial dependence, for P=30000, only 15 passes are needed to resolve back-references for all threads. In at least one embodiment, the principles, techniques, methods, and systems disclosed in conjunction with FIG. 23 can be used in connection with one or any combination of embodiments described further in conjunction with at least FIGS. 1-22.

### Data Center

FIG. 24 illustrates an exemplary data center 2400, in accordance with at least one embodiment. In at least one embodiment, data center 2400 includes, without limitation, a data center infrastructure layer 2410, a framework layer 2420, a software layer 2430 and an application layer 2440.

In at least one embodiment, as shown in FIG. 24, data center infrastructure layer 2410 may include a resource orchestrator 2412, grouped computing resources 2414, and node computing resources (“node C.R.s”) 2416(1)-2416(N), where “N” represents any whole, positive integer. In at least one embodiment, node C.R.s 2416(1)-2416(N) may include, but are not limited to, any number of central processing units (“CPUs”) or other processors (including accelerators, field programmable gate arrays (“FPGAs”), data processing units (“DPUs”) in network devices, graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 2416(1)-2416(N) may be a server having one or more of above-mentioned computing resources.

In at least one embodiment, grouped computing resources 2414 may include separate groupings of node C.R.s housed within one or more racks (not shown), or many racks housed in data centers at various geographical locations (also not shown). Separate groupings of node C.R.s within grouped computing resources 2414 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 2412 may configure or otherwise control one or more node C.R.s 2416(1)-2416(N) and/or grouped computing resources 2414. In at least one embodiment, resource orchestrator 2412 may include a software design infrastructure (“SDI”) management entity for data center 2400. In at least one embodiment, resource orchestrator 2412 may include hardware, software or some combination thereof.

In at least one embodiment, as shown in FIG. 24, framework layer 2420 includes, without limitation, a job scheduler 2432, a configuration manager 2434, a resource manager 2436 and a distributed file system 2438. In at least one embodiment, framework layer 2420 may include a framework to support software 2452 of software layer 2430 and/or one or more application(s) 2442 of application layer 2440. In at least one embodiment, software 2452 or application(s) 2442 may respectively include web-based service software or applications, such as those provided by Amazon Web Services, Google Cloud and Microsoft Azure. In at least one embodiment, framework layer 2420 may be, but is not limited to, a type of free and open-source software web application framework such as Apache Spark™ (hereinafter “Spark”) that may utilize distributed file system 2438 for large-scale data processing (e.g., “big data”). In at least one embodiment, job scheduler 2432 may include a Spark driver to facilitate scheduling of workloads supported by various layers of data center 2400. In at least one embodiment, configuration manager 2434 may be capable of configuring different layers such as software layer 2430 and framework layer 2420, including Spark and distributed file system 2438 for supporting large-scale data processing. In at least one embodiment, resource manager 2436 may be capable of managing clustered or grouped computing resources mapped to or allocated for support of distributed file system 2438 and job scheduler 2432. In at least one embodiment, clustered or grouped computing resources may include grouped computing resource 2414 at data center infrastructure layer 2410. In at least one embodiment, resource manager 2436 may coordinate with resource orchestrator 2412 to manage these mapped or allocated computing resources.

In at least one embodiment, software 2452 included in software layer 2430 may include software used by at least portions of node C.R.s 2416(1)-2416(N), grouped computing resources 2414, and/or distributed file system 2438 of framework layer 2420. One or more types of software may include, but are not limited to, Internet web page search software, e-mail virus scan software, database software, and streaming video content software.

In at least one embodiment, application(s) 2442 included in application layer 2440 may include one or more types of applications used by at least portions of node C.R.s 2416(1)-2416(N), grouped computing resources 2414, and/or distributed file system 2438 of framework layer 2420. In at least one or more types of applications may include, without limitation, CUDA applications. In at least one embodiment, application(s) 2442 performs one or more steps of process 2000 of FIG. 20 to decompress variable-length coded data in parallel.

In at least one embodiment, any of configuration manager 2434, resource manager 2436, and resource orchestrator 2412 may implement any number and type of self-modifying actions based on any amount and type of data acquired in any technically feasible fashion. In at least one embodiment, self-modifying actions may relieve a data center operator of data center 2400 from making possibly bad configuration decisions and possibly avoiding underutilized and/or poor performing portions of a data center.

### Computer-Based Systems

The following figures set forth, without limitation, exemplary computer-based systems that can be used to implement at least one embodiment.

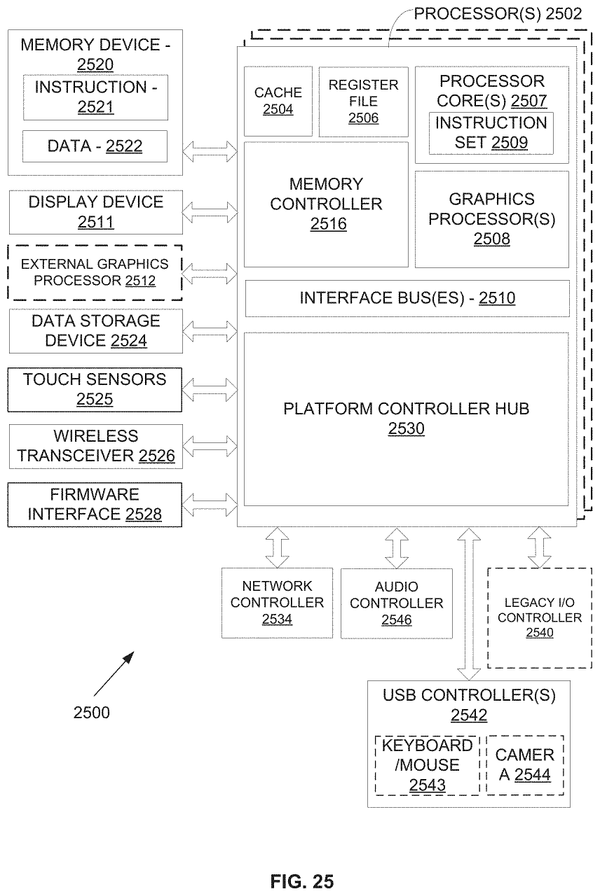

FIG. 25 illustrates a processing system 2500, in accordance with at least one embodiment. In at least one embodiment, processing system 2500 includes one or more processors 2502 and one or more graphics processors 2508, and may be a single processor desktop system, a multiprocessor workstation system, or a server system having a large number of processors 2502 or processor cores 2507. In at least one embodiment, processing system 2500 is a processing platform incorporated within a system-on-a-chip (“SoC”) integrated circuit for use in mobile, handheld, or embedded devices. In at least one embodiment, processing system 2500 performs one or more steps to perform operations discussed herein, such as decompressing or otherwise performing operations involving decoding of variable-length coded data in parallel.

In at least one embodiment, processing system 2500 can include, or be incorporated within a server-based gaming platform, a game console, a media console, a mobile gaming console, a handheld game console, or an online game console. In at least one embodiment, processing system 2500 is a mobile phone, smart phone, tablet computing device or mobile Internet device. In at least one embodiment, processing system 2500 can also include, couple with, or be integrated within a wearable device, such as a smart watch wearable device, smart eyewear device, augmented reality device, or virtual reality device. In at least one embodiment, processing system 2500 is a television or set top box device having one or more processors 2502 and a graphical interface generated by one or more graphics processors 2508.

In at least one embodiment, one or more processors 2502 each include one or more processor cores 2507 to process instructions which, when executed, perform operations for system and user software. In at least one embodiment, each of one or more processor cores 2507 is configured to process a specific instruction set 2509. In at least one embodiment, instruction set 2509 may facilitate Complex Instruction Set Computing (“CISC”), Reduced Instruction Set Computing (“RISC”), or computing via a Very Long Instruction Word (“VLIW”). In at least one embodiment, processor cores 2507 may each process a different instruction set 2509, which may include instructions to facilitate emulation of other instruction sets. In at least one embodiment, processor core 2507 may also include other processing devices, such as a digital signal processor (“DSP”).

In at least one embodiment, processor 2502 includes cache memory (“cache”) 2504. In at least one embodiment, processor 2502 can have a single internal cache or multiple levels of internal cache. In at least one embodiment, cache memory is shared among various components of processor 2502. In at least one embodiment, processor 2502 also uses an external cache (e.g., a Level 3 (“L3”) cache or Last Level Cache (“LLC”)) (not shown), which may be shared among processor cores 2507 using known cache coherency techniques. In at least one embodiment, register file 2506 is additionally included in processor 2502 which may include different types of registers for storing different types of data (e.g., integer registers, floating point registers, status registers, and an instruction pointer register). In at least one embodiment, register file 2506 may include general-purpose registers or other registers.

In at least one embodiment, one or more processor(s) 2502 are coupled with one or more interface bus(es) 2510 to transmit communication signals such as address, data, or control signals between processor 2502 and other components in processing system 2500. In at least one embodiment interface bus 2510, in one embodiment, can be a processor bus, such as a version of a Direct Media Interface (“DMI”) bus. In at least one embodiment, interface bus 2510 is not limited to a DMI bus, and may include one or more Peripheral Component Interconnect buses (e.g., “PCI,” PCI Express (“PCIe”)), memory buses, or other types of interface buses. In at least one embodiment processor(s) 2502 include an integrated memory controller 2516 and a platform controller hub 2530. In at least one embodiment, memory controller 2516 facilitates communication between a memory device and other components of processing system 2500, while platform controller hub (“PCH”) 2530 provides connections to Input/Output (“I/O”) devices via a local I/O bus.

In at least one embodiment, memory device 2520 can be a dynamic random access memory (“DRAM”) device, a static random access memory (“SRAM”) device, flash memory device, phase-change memory device, or some other memory device having suitable performance to serve as processor memory. In at least one embodiment memory device 2520 can operate as system memory for processing system 2500, to store data 2522 and instructions 2521 for use when one or more processors 2502 executes an application or process. In at least one embodiment, memory controller 2516 also couples with an optional external graphics processor 2512, which may communicate with one or more graphics processors 2508 in processors 2502 to perform graphics and media operations. In at least one embodiment, a display device 2511 can connect to processor(s) 2502. In at least one embodiment display device 2511 can include one or more of an internal display device, as in a mobile electronic device or a laptop device or an external display device attached via a display interface (e.g., DisplayPort, etc.). In at least one embodiment, display device 2511 can include a head mounted display (“HMD”) such as a stereoscopic display device for use in virtual reality (“VR”) applications or augmented reality (“AR”) applications.

In at least one embodiment, platform controller hub 2530 enables peripherals to connect to memory device 2520 and processor 2502 via a high-speed I/O bus. In at least one embodiment, I/O peripherals include, but are not limited to, an audio controller 2546, a network controller 2534, a firmware interface 2528, a wireless transceiver 2526, touch sensors 2525, a data storage device 2524 (e.g., hard disk drive, flash memory, etc.). In at least one embodiment, data storage device 2524 can connect via a storage interface (e.g., SATA) or via a peripheral bus, such as PCI, or PCIe. In at least one embodiment, touch sensors 2525 can include touch screen sensors, pressure sensors, or fingerprint sensors. In at least one embodiment, wireless transceiver 2526 can be a Wi-Fi transceiver, a Bluetooth transceiver, or a mobile network transceiver such as a 3G, 4G, or Long Term Evolution (“LTE”) transceiver. In at least one embodiment, firmware interface 2528 enables communication with system firmware, and can be, for example, a unified extensible firmware interface (“UEFI”). In at least one embodiment, network controller 2534 can enable a network connection to a wired network. In at least one embodiment, a high-performance network controller (not shown) couples with interface bus 2510. In at least one embodiment, audio controller 2546 is a multi-channel high definition audio controller. In at least one embodiment, processing system 2500 includes an optional legacy I/O controller 2540 for coupling legacy (e.g., Personal System 2 (“PS/2”)) devices to processing system 2500. In at least one embodiment, platform controller hub 2530 can also connect to one or more Universal Serial Bus (“USB”) controllers 2542 connect input devices, such as keyboard and mouse 2543 combinations, a camera 2544, or other USB input devices.

In at least one embodiment, an instance of memory controller 2516 and platform controller hub 2530 may be integrated into a discreet external graphics processor, such as external graphics processor 2512. In at least one embodiment, platform controller hub 2530 and/or memory controller 2516 may be external to one or more processor(s) 2502. For example, in at least one embodiment, processing system 2500 can include an external memory controller 2516 and platform controller hub 2530, which may be configured as a memory controller hub and peripheral controller hub within a system chipset that is in communication with processor(s) 2502.

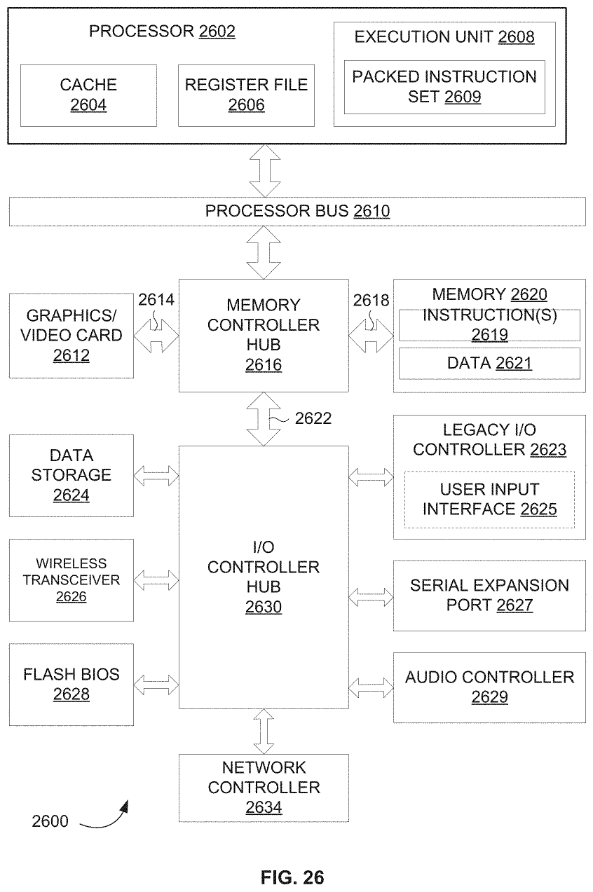

FIG. 26 illustrates a computer system 2600, in accordance with at least one embodiment. In at least one embodiment, computer system 2600 may be a system with interconnected devices and components, an SOC, or some combination. In at least on embodiment, computer system 2600 is formed with a processor 2602 that may include execution units to execute an instruction. In at least one embodiment, computer system 2600 may include, without limitation, a component, such as processor 2602 to employ execution units including logic to perform algorithms for processing data. In at least one embodiment, computer system 2600 may include processors, such as PENTIUM® Processor family, Xeon™, Itanium®, XScale™ and/or StrongARM™, Intel® Core™, or Intel® Nervana™ microprocessors available from Intel Corporation of Santa Clara, Calif., although other systems (including PCs having other microprocessors, engineering workstations, set-top boxes and like) may also be used. In at least one embodiment, computer system 2600 may execute a version of WINDOWS' operating system available from Microsoft Corporation of Redmond, Wash., although other operating systems (UNIX and Linux for example), embedded software, and/or graphical user interfaces, may also be used. In at least one embodiment, computer system 2600 performs one or more steps to perform operations discussed herein, such as decompressing or otherwise performing operations involving decoding of variable-length coded data in parallel.

In at least one embodiment, computer system 2600 may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (DSP), an SoC, network computers (“NetPCs”), set-top boxes, network hubs, wide area network (“WAN”) switches, or any other system that may perform one or more instructions.

In at least one embodiment, computer system 2600 may include, without limitation, processor 2602 that may include, without limitation, one or more execution units 2608 that may be configured to execute a Compute Unified Device Architecture (“CUDA”) (CUDA® is developed by NVIDIA Corporation of Santa Clara, Calif.) program. In at least one embodiment, a CUDA program is at least a portion of a software application written in a CUDA programming language. In at least one embodiment, computer system 2600 is a single processor desktop or server system. In at least one embodiment, computer system 2600 may be a multiprocessor system. In at least one embodiment, processor 2602 may include, without limitation, a CISC microprocessor, a RISC microprocessor, a VLIW microprocessor, a processor implementing a combination of instruction sets, or any other processor device, such as a digital signal processor, for example. In at least one embodiment, processor 2602 may be coupled to a processor bus 2610 that may transmit data signals between processor 2602 and other components in computer system 2600.

In at least one embodiment, processor 2602 may include, without limitation, a Level 1 (“L1”) internal cache memory (“cache”) 2604. In at least one embodiment, processor 2602 may have a single internal cache or multiple levels of internal cache. In at least one embodiment, cache memory may reside external to processor 2602. In at least one embodiment, processor 2602 may also include a combination of both internal and external caches. In at least one embodiment, a register file 2606 may store different types of data in various registers including, without limitation, integer registers, floating point registers, status registers, and instruction pointer register.

In at least one embodiment, execution unit 2608, including, without limitation, logic to perform integer and floating point operations, also resides in processor 2602. Processor 2602 may also include a microcode (“ucode”) read only memory (“ROM”) that stores microcode for certain macro instructions. In at least one embodiment, execution unit 2608 may include logic to handle a packed instruction set 2609. In at least one embodiment, by including packed instruction set 2609 in an instruction set of a general-purpose processor 2602, along with associated circuitry to execute instructions, operations used by many multimedia applications may be performed using packed data in a general-purpose processor 2602. In at least one embodiment, many multimedia applications may be accelerated and executed more efficiently by using full width of a processor's data bus for performing operations on packed data, which may eliminate a need to transfer smaller units of data across a processor's data bus to perform one or more operations one data element at a time.

In at least one embodiment, execution unit 2608 may also be used in microcontrollers, embedded processors, graphics devices, DSPs, and other types of logic circuits. In at least one embodiment, computer system 2600 may include, without limitation, a memory 2620. In at least one embodiment, memory 2620 may be implemented as a DRAM device, an SRAM device, flash memory device, or other memory device. Memory 2620 may store instruction(s) 2619 and/or data 2621 represented by data signals that may be executed by processor 2602.

In at least one embodiment, a system logic chip may be coupled to processor bus 2610 and memory 2620. In at least one embodiment, the system logic chip may include, without limitation, a memory controller hub (“MCH”) 2616, and processor 2602 may communicate with MCH 2616 via processor bus 2610. In at least one embodiment, MCH 2616 may provide a high bandwidth memory path 2618 to memory 2620 for instruction and data storage and for storage of graphics commands, data and textures. In at least one embodiment, MCH 2616 may direct data signals between processor 2602, memory 2620, and other components in computer system 2600 and to bridge data signals between processor bus 2610, memory 2620, and a system I/O 2622. In at least one embodiment, system logic chip may provide a graphics port for coupling to a graphics controller. In at least one embodiment, MCH 2616 may be coupled to memory 2620 through high bandwidth memory path 2618 and graphics/video card 2612 may be coupled to MCH 2616 through an Accelerated Graphics Port (“AGP”) interconnect 2614.

In at least one embodiment, computer system 2600 may use system I/O 2622 that is a proprietary hub interface bus to couple MCH 2616 to I/O controller hub (“ICH”) 2630. In at least one embodiment, ICH 2630 may provide direct connections to some I/O devices via a local I/O bus. In at least one embodiment, local I/O bus may include, without limitation, a high-speed I/O bus for connecting peripherals to memory 2620, a chipset, and processor 2602. Examples may include, without limitation, an audio controller 2629, a firmware hub (“flash BIOS”) 2628, a wireless transceiver 2626, a data storage 2624, a legacy I/O controller 2623 containing a user input interface 2625 and a keyboard interface, a serial expansion port 2627, such as a USB, and a network controller 2634. Data storage 2624 may comprise a hard disk drive, a floppy disk drive, a CD-ROM device, a flash memory device, or other mass storage device.

In at least one embodiment, FIG. 26 illustrates a system, which includes interconnected hardware devices or “chips.” In at least one embodiment, FIG. 26 may illustrate an exemplary SoC. In at least one embodiment, devices illustrated in FIG. 26 may be interconnected with proprietary interconnects, standardized interconnects (e.g., PCIe), or some combination thereof. In at least one embodiment, one or more components of system 2600 are interconnected using compute express link (“CXL”) interconnects.

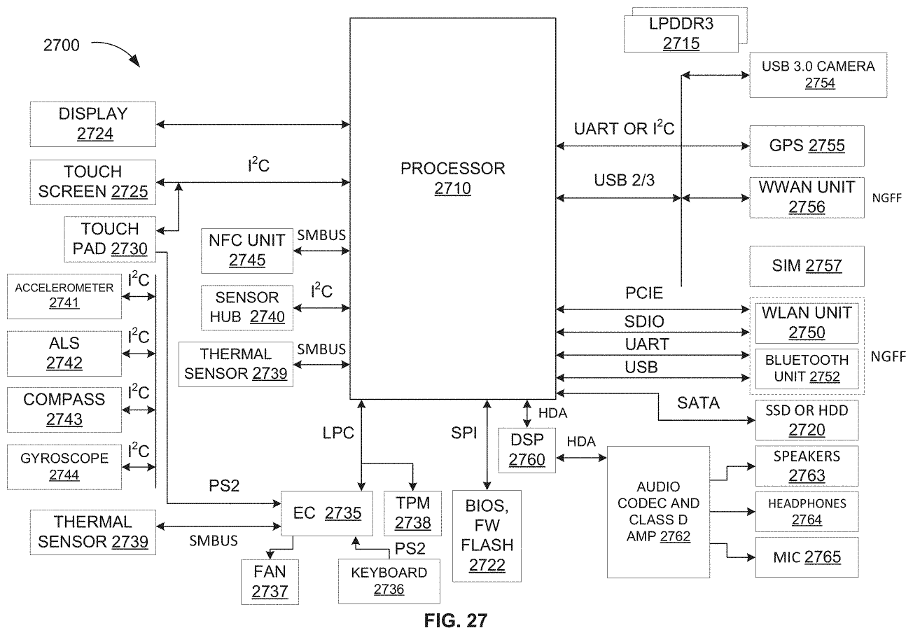

FIG. 27 illustrates a system 2700, in accordance with at least one embodiment. In at least one embodiment, system 2700 is an electronic device that utilizes a processor 2710. In at least one embodiment, system 2700 may be, for example and without limitation, a notebook, a tower server, a rack server, a blade server, an edge device communicatively coupled to one or more on-premise or cloud service providers, a laptop, a desktop, a tablet, a mobile device, a phone, an embedded computer, or any other suitable electronic device.

In at least one embodiment, system 2700 may include, without limitation, processor 2710 communicatively coupled to any suitable number or kind of components, peripherals, modules, or devices. In at least one embodiment, processor 2710 is coupled using a bus or interface, such as an I²C bus, a System Management Bus (“SMBus”), a Low Pin Count (“LPC”) bus, a Serial Peripheral Interface (“SPI”), a High Definition Audio (“HDA”) bus, a Serial Advance Technology Attachment (“SATA”) bus, a USB (versions 1, 2, 3), or a Universal Asynchronous Receiver/Transmitter (“UART”) bus. In at least one embodiment, FIG. 27 illustrates a system which includes interconnected hardware devices or “chips.” In at least one embodiment, FIG. 27 may illustrate an exemplary SoC. In at least one embodiment, devices illustrated in FIG. 27 may be interconnected with proprietary interconnects, standardized interconnects (e.g., PCIe) or some combination thereof. In at least one embodiment, one or more components of FIG. 27 are interconnected using CXL interconnects. In at least one embodiment, system 2700 performs one or more steps to perform operations discussed herein, such as decompressing or otherwise performing operations involving decoding of variable-length coded data in parallel.

In at least one embodiment, FIG. 27 may include a display 2724, a touch screen 2725, a touch pad 2730, a Near Field Communications unit (“NFC”) 2745, a sensor hub 2740, a thermal sensor 2746, an Express Chipset (“EC”) 2735, a Trusted Platform Module (“TPM”) 2738, BIOS/firmware/flash memory (“BIOS, FW Flash”) 2722, a DSP 2760, a Solid State Disk (“SSD”) or Hard Disk Drive (“HDD”) 2720, a wireless local area network unit (“WLAN”) 2750, a Bluetooth unit 2752, a Wireless Wide Area Network unit (“WWAN”) 2756, a Global Positioning System (“GPS”) 2755, a camera (“USB 3.0 camera”) 2754 such as a USB 3.0 camera, or a Low Power Double Data Rate (“LPDDR”) memory unit (“LPDDR3”) 2715 implemented in, for example, LPDDR3 standard. These components may each be implemented in any suitable manner.

In at least one embodiment, other components may be communicatively coupled to processor 2710 through components discussed above. In at least one embodiment, an accelerometer 2741, an Ambient Light Sensor (“ALS”) 2742, a compass 2743, and a gyroscope 2744 may be communicatively coupled to sensor hub 2740. In at least one embodiment, a thermal sensor 2739, a fan 2737, a keyboard 2736, and a touch pad 2730 may be communicatively coupled to EC 2735. In at least one embodiment, a speaker 2763, a headphones 2764, and a microphone (“mic”) 2765 may be communicatively coupled to an audio unit (“audio codec and class d amp”) 2762, which may in turn be communicatively coupled to DSP 2760. In at least one embodiment, audio unit 2762 may include, for example and without limitation, an audio coder/decoder (“codec”) and a class D amplifier. In at least one embodiment, a SIM card (“SIM”) 2757 may be communicatively coupled to WWAN unit 2756. In at least one embodiment, components such as WLAN unit 2750 and Bluetooth unit 2752, as well as WWAN unit 2756 may be implemented in a Next Generation Form Factor (“NGFF”).

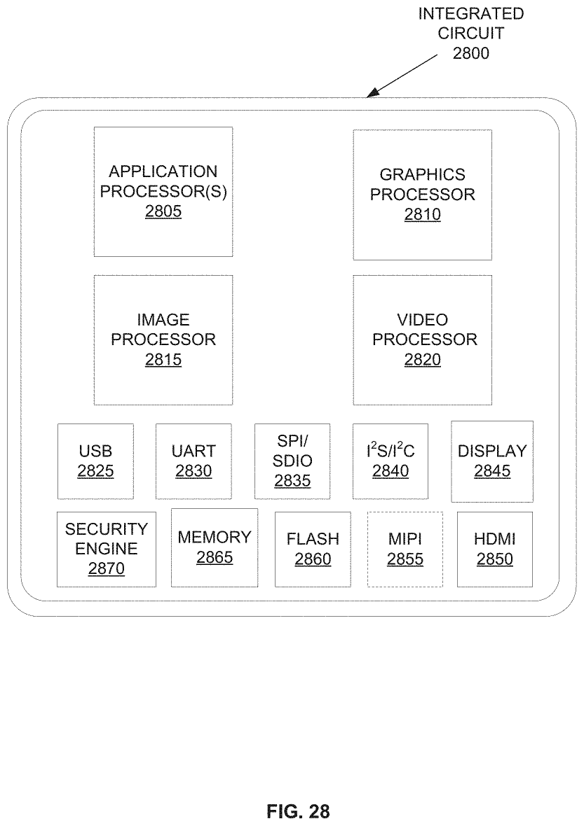

FIG. 28 illustrates an exemplary integrated circuit 2800, in accordance with at least one embodiment. In at least one embodiment, exemplary integrated circuit 2800 is an SoC that may be fabricated using one or more IP cores. In at least one embodiment, integrated circuit 2800 includes one or more application processor(s) 2805 (e.g., CPUs, DPUs), at least one graphics processor 2810, and may additionally include an image processor 2815 and/or a video processor 2820, any of which may be a modular IP core. In at least one embodiment, integrated circuit 2800 includes peripheral or bus logic including a USB controller 2825, a UART controller 2830, an SPI/SDIO controller 2835, and an I²S/I²C controller 2840. In at least one embodiment, integrated circuit 2800 can include a display device 2845 coupled to one or more of a high-definition multimedia interface (“HDMI”) controller 2850 and a mobile industry processor interface (“MIPI”) display interface 2855. In at least one embodiment, storage may be provided by a flash memory subsystem 2860 including flash memory and a flash memory controller. In at least one embodiment, a memory interface may be provided via a memory controller 2865 for access to SDRAM or SRAM memory devices. In at least one embodiment, some integrated circuits additionally include an embedded security engine 2870. In at least one embodiment, integrated circuit 2800 performs one or more steps to perform operations discussed herein, such as decompressing or otherwise performing operations involving decoding of variable-length coded data in parallel.

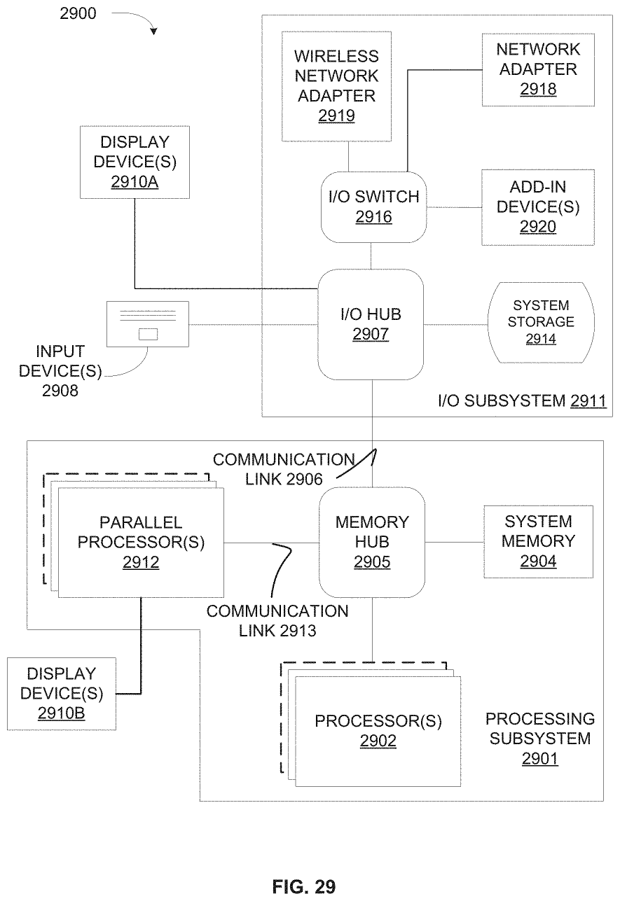

FIG. 29 illustrates a computing system 2900, according to at least one embodiment; In at least one embodiment, computing system 2900 includes a processing subsystem 2901 having one or more processor(s) 2902 and a system memory 2904 communicating via an interconnection path that may include a memory hub 2905. In at least one embodiment, memory hub 2905 may be a separate component within a chipset component or may be integrated within one or more processor(s) 2902. In at least one embodiment, memory hub 2905 couples with an I/O subsystem 2911 via a communication link 2906. In at least one embodiment, I/O subsystem 2911 includes an I/O hub 2907 that can enable computing system 2900 to receive input from one or more input device(s) 2908. In at least one embodiment, I/O hub 2907 can enable a display controller, which may be included in one or more processor(s) 2902, to provide outputs to one or more display device(s) 2910A. In at least one embodiment, one or more display device(s) 2910A coupled with I/O hub 2907 can include a local, internal, or embedded display device. In at least one embodiment, system 2900 performs one or more steps to perform operations discussed herein, such as decompressing or otherwise performing operations involving decoding of variable-length coded data in parallel.

In at least one embodiment, processing subsystem 2901 includes one or more parallel processor(s) 2912 coupled to memory hub 2905 via a bus or other communication link 2913. In at least one embodiment, communication link 2913 may be one of any number of standards based communication link technologies or protocols, such as, but not limited to PCIe, or may be a vendor specific communications interface or communications fabric. In at least one embodiment, one or more parallel processor(s) 2912 form a computationally focused parallel or vector processing system that can include a large number of processing cores and/or processing clusters, such as a many integrated core processor. In at least one embodiment, one or more parallel processor(s) 2912 form a graphics processing subsystem that can output pixels to one of one or more display device(s) 2910A coupled via I/O Hub 2907. In at least one embodiment, one or more parallel processor(s) 2912 can also include a display controller and display interface (not shown) to enable a direct connection to one or more display device(s) 2910B.

In at least one embodiment, a system storage unit 2914 can connect to I/O hub 2907 to provide a storage mechanism for computing system 2900. In at least one embodiment, an I/O switch 2916 can be used to provide an interface mechanism to enable connections between I/O hub 2907 and other components, such as a network adapter 2918 and/or wireless network adapter 2919 that may be integrated into a platform, and various other devices that can be added via one or more add-in device(s) 2920. In at least one embodiment, network adapter 2918 can be an Ethernet adapter or another wired network adapter. In at least one embodiment, wireless network adapter 2919 can include one or more of a Wi-Fi, Bluetooth, NFC, or other network device that includes one or more wireless radios.

In at least one embodiment, computing system 2900 can include other components not explicitly shown, including USB or other port connections, optical storage drives, video capture devices, and the like, that may also be connected to I/O hub 2907. In at least one embodiment, communication paths interconnecting various components in FIG. 29 may be implemented using any suitable protocols, such as PCI based protocols (e.g., PCIe), or other bus or point-to-point communication interfaces and/or protocol(s), such as NVLink high-speed interconnect, or interconnect protocols.

In at least one embodiment, one or more parallel processor(s) 2912 incorporate circuitry optimized for graphics and video processing, including, for example, video output circuitry, and constitutes a graphics processing unit (“GPU”). In at least one embodiment, one or more parallel processor(s) 2912 incorporate circuitry optimized for general purpose processing. In at least embodiment, components of computing system 2900 may be integrated with one or more other system elements on a single integrated circuit. For example, in at least one embodiment, one or more parallel processor(s) 2912, memory hub 2905, processor(s) 2902, and I/O hub 2907 can be integrated into an SoC integrated circuit. In at least one embodiment, components of computing system 2900 can be integrated into a single package to form a system in package (“SIP”) configuration. In at least one embodiment, at least a portion of the components of computing system 2900 can be integrated into a multi-chip module (“MCM”), which can be interconnected with other multi-chip modules into a modular computing system. In at least one embodiment, I/O subsystem 2911 and display devices 2910B are omitted from computing system 2900.

### Processing Systems

The following figures set forth, without limitation, exemplary processing systems that can be used to implement at least one embodiment.

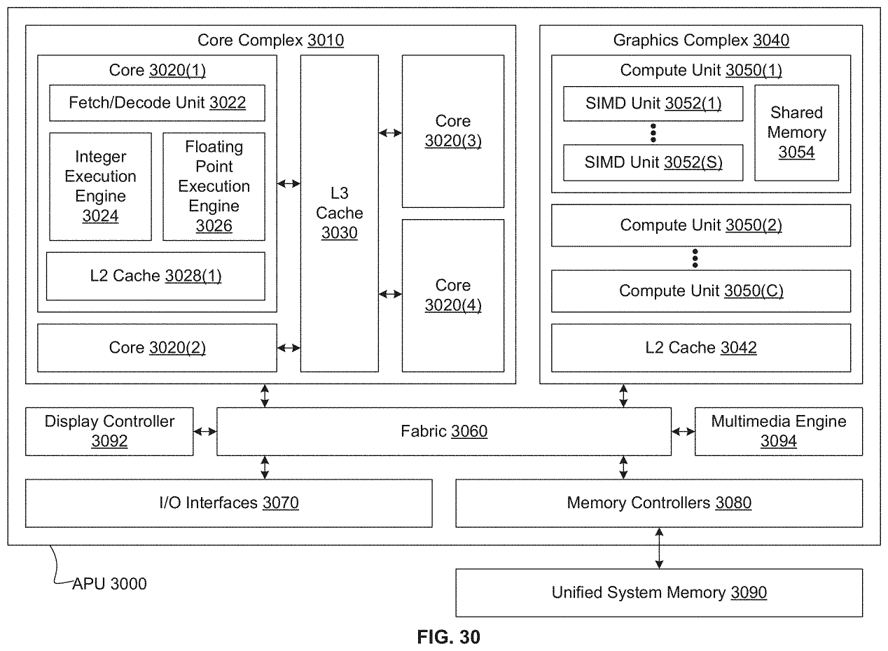

FIG. 30 illustrates an accelerated processing unit (“APU”) 3000, in accordance with at least one embodiment. In at least one embodiment, APU 3000 is developed by AMD Corporation of Santa Clara, Calif. In at least one embodiment, APU 3000 can be configured to execute an application program, such as a CUDA program. In at least one embodiment, APU 3000 includes, without limitation, a core complex 3010, a graphics complex 3040, fabric 3060, I/O interfaces 3070, memory controllers 3080, a display controller 3092, and a multimedia engine 3094. In at least one embodiment, APU 3000 may include, without limitation, any number of core complexes 3010, any number of graphics complexes 3050, any number of display controllers 3092, and any number of multimedia engines 3094 in any combination. For explanatory purposes, multiple instances of like objects are denoted herein with reference numbers identifying the object and parenthetical numbers identifying the instance where needed. In at least one embodiment, APU 3000 performs one or more steps to perform operations discussed herein, such as decompressing or otherwise performing operations involving decoding of variable-length coded data in parallel.

In at least one embodiment, core complex 3010 is a CPU, graphics complex 3040 is a GPU, and APU 3000 is a processing unit that integrates, without limitation, 3010 and 3040 onto a single chip. In at least one embodiment, some tasks may be assigned to core complex 3010 and other tasks may be assigned to graphics complex 3040. In at least one embodiment, core complex 3010 is configured to execute main control software associated with APU 3000, such as an operating system. In at least one embodiment, core complex 3010 is the master processor of APU 3000, controlling and coordinating operations of other processors. In at least one embodiment, core complex 3010 issues commands that control the operation of graphics complex 3040. In at least one embodiment, core complex 3010 can be configured to execute host executable code derived from CUDA source code, and graphics complex 3040 can be configured to execute device executable code derived from CUDA source code.

In at least one embodiment, core complex 3010 includes, without limitation, cores 3020(1)-3020(4) and an L3 cache 3030. In at least one embodiment, core complex 3010 may include, without limitation, any number of cores 3020 and any number and type of caches in any combination. In at least one embodiment, cores 3020 are configured to execute instructions of a particular instruction set architecture (“ISA”). In at least one embodiment, each core 3020 is a CPU core.

In at least one embodiment, each core 3020 includes, without limitation, a fetch/decode unit 3022, an integer execution engine 3024, a floating point execution engine 3026, and an L2 cache 3028. In at least one embodiment, fetch/decode unit 3022 fetches instructions, decodes such instructions, generates micro-operations, and dispatches separate micro-instructions to integer execution engine 3024 and floating point execution engine 3026. In at least one embodiment, fetch/decode unit 3022 can concurrently dispatch one micro-instruction to integer execution engine 3024 and another micro-instruction to floating point execution engine 3026. In at least one embodiment, integer execution engine 3024 executes, without limitation, integer and memory operations. In at least one embodiment, floating point engine 3026 executes, without limitation, floating point and vector operations. In at least one embodiment, fetch-decode unit 3022 dispatches micro-instructions to a single execution engine that replaces both integer execution engine 3024 and floating point execution engine 3026.

In at least one embodiment, each core 3020(i), where i is an integer representing a particular instance of core 3020, may access L2 cache 3028(i) included in core 3020(i). In at least one embodiment, each core 3020 included in core complex 3010(j), where j is an integer representing a particular instance of core complex 3010, is connected to other cores 3020 included in core complex 3010(j) via L3 cache 3030(j) included in core complex 3010(j). In at least one embodiment, cores 3020 included in core complex 3010(j), where j is an integer representing a particular instance of core complex 3010, can access all of L3 cache 3030(j) included in core complex 3010(j). In at least one embodiment, L3 cache 3030 may include, without limitation, any number of slices.

In at least one embodiment, graphics complex 3040 can be configured to perform compute operations in a highly-parallel fashion. In at least one embodiment, graphics complex 3040 is configured to execute graphics pipeline operations such as draw commands, pixel operations, geometric computations, and other operations associated with rendering an image to a display. In at least one embodiment, graphics complex 3040 is configured to execute operations unrelated to graphics. In at least one embodiment, graphics complex 3040 is configured to execute both operations related to graphics and operations unrelated to graphics.

In at least one embodiment, graphics complex 3040 includes, without limitation, any number of compute units 3050 and an L2 cache 3042. In at least one embodiment, compute units 3050 share L2 cache 3042. In at least one embodiment, L2 cache 3042 is partitioned. In at least one embodiment, graphics complex 3040 includes, without limitation, any number of compute units 3050 and any number (including zero) and type of caches. In at least one embodiment, graphics complex 3040 includes, without limitation, any amount of dedicated graphics hardware.

In at least one embodiment, each compute unit 3050 includes, without limitation, any number of SIMD units 3052 and a shared memory 3054. In at least one embodiment, each SIMD unit 3052 implements a SIMD architecture and is configured to perform operations in parallel. In at least one embodiment, each compute unit 3050 may execute any number of thread blocks, but each thread block executes on a single compute unit 3050. In at least one embodiment, a thread block includes, without limitation, any number of threads of execution. In at least one embodiment, a workgroup is a thread block. In at least one embodiment, each SIMD unit 3052 executes a different warp. In at least one embodiment, a warp is a group of threads (e.g., 16 threads), where each thread in the warp belongs to a single thread block and is configured to process a different set of data based on a single set of instructions. In at least one embodiment, predication can be used to disable one or more threads in a warp. In at least one embodiment, a lane is a thread. In at least one embodiment, a work item is a thread. In at least one embodiment, a wavefront is a warp. In at least one embodiment, different wavefronts in a thread block may synchronize together and communicate via shared memory 3054.

In at least one embodiment, fabric 3060 is a system interconnect that facilitates data and control transmissions across core complex 3010, graphics complex 3040, I/O interfaces 3070, memory controllers 3080, display controller 3092, and multimedia engine 3094. In at least one embodiment, APU 3000 may include, without limitation, any amount and type of system interconnect in addition to or instead of fabric 3060 that facilitates data and control transmissions across any number and type of directly or indirectly linked components that may be internal or external to APU 3000. In at least one embodiment, I/O interfaces 3070 are representative of any number and type of I/O interfaces (e.g., PCI, PCI-Extended (“PCI-X”), PCIe, gigabit Ethernet (“GBE”), USB, etc.). In at least one embodiment, various types of peripheral devices are coupled to I/O interfaces 3070 In at least one embodiment, peripheral devices that are coupled to I/O interfaces 3070 may include, without limitation, keyboards, mice, printers, scanners, joysticks or other types of game controllers, media recording devices, external storage devices, network interface cards, and so forth.

In at least one embodiment, display controller AMD92 displays images on one or more display device(s), such as a liquid crystal display (“LCD”) device. In at least one embodiment, multimedia engine 3094 includes, without limitation, any amount and type of circuitry that is related to multimedia, such as a video decoder, a video encoder, an image signal processor, etc. In at least one embodiment, memory controllers 3080 facilitate data transfers between APU 3000 and a unified system memory 3090. In at least one embodiment, core complex 3010 and graphics complex 3040 share unified system memory 3090.

In at least one embodiment, APU 3000 implements a memory subsystem that includes, without limitation, any amount and type of memory controllers 3080 and memory devices (e.g., shared memory 3054) that may be dedicated to one component or shared among multiple components. In at least one embodiment, APU 3000 implements a cache subsystem that includes, without limitation, one or more cache memories (e.g., L2 caches 3128, L3 cache 3030, and L2 cache 3042) that may each be private to or shared between any number of components (e.g., cores 3020, core complex 3010, SIMD units 3052, compute units 3050, and graphics complex 3040).

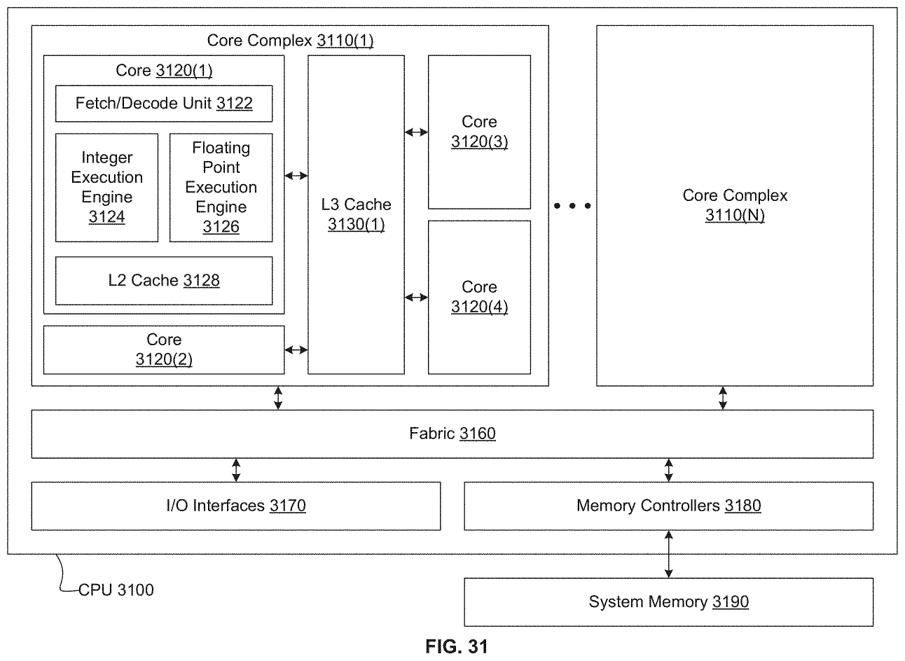

FIG. 31 illustrates a CPU 3100, in accordance with at least one embodiment. In at least one embodiment, CPU 3100 is developed by AMD Corporation of Santa Clara, Calif. In at least one embodiment, CPU 3100 can be configured to execute an application program. In at least one embodiment, CPU 3100 is configured to execute main control software, such as an operating system. In at least one embodiment, CPU 3100 issues commands that control the operation of an external GPU (not shown). In at least one embodiment, CPU 3100 can be configured to execute host executable code derived from CUDA source code, and an external GPU can be configured to execute device executable code derived from such CUDA source code. In at least one embodiment, CPU 3100 includes, without limitation, any number of core complexes 3110, fabric 3160, I/O interfaces 3170, and memory controllers 3180. In at least one embodiment, CPU 3100 performs one or more steps to perform operations discussed herein, such as decompressing or otherwise performing operations involving decoding of variable-length coded data in parallel.

In at least one embodiment, core complex 3110 includes, without limitation, cores 3120(1)-3120(4) and an L3 cache 3130. In at least one embodiment, core complex 3110 may include, without limitation, any number of cores 3120 and any number and type of caches in any combination. In at least one embodiment, cores 3120 are configured to execute instructions of a particular ISA. In at least one embodiment, each core 3120 is a CPU core.

In at least one embodiment, each core 3120 includes, without limitation, a fetch/decode unit 3122, an integer execution engine 3124, a floating point execution engine 3126, and an L2 cache 3128. In at least one embodiment, fetch/decode unit 3122 fetches instructions, decodes such instructions, generates micro-operations, and dispatches separate micro-instructions to integer execution engine 3124 and floating point execution engine 3126. In at least one embodiment, fetch/decode unit 3122 can concurrently dispatch one micro-instruction to integer execution engine 3124 and another micro-instruction to floating point execution engine 3126. In at least one embodiment, integer execution engine 3124 executes, without limitation, integer and memory operations. In at least one embodiment, floating point engine 3126 executes, without limitation, floating point and vector operations. In at least one embodiment, fetch-decode unit 3122 dispatches micro-instructions to a single execution engine that replaces both integer execution engine 3124 and floating point execution engine 3126.

In at least one embodiment, each core 3120(i), where i is an integer representing a particular instance of core 3120, may access L2 cache 3128(i) included in core 3120(i). In at least one embodiment, each core 3120 included in core complex 3110(j), where j is an integer representing a particular instance of core complex 3110, is connected to other cores 3120 in core complex 3110(j) via L3 cache 3130(j) included in core complex 3110(j). In at least one embodiment, cores 3120 included in core complex 3110(j), where j is an integer representing a particular instance of core complex 3110, can access all of L3 cache 3130(j) included in core complex 3110(j). In at least one embodiment, L3 cache 3130 may include, without limitation, any number of slices.

In at least one embodiment, fabric 3160 is a system interconnect that facilitates data and control transmissions across core complexes 3110(1)-3110(N) (where N is an integer greater than zero), I/O interfaces 3170, and memory controllers 3180. In at least one embodiment, CPU 3100 may include, without limitation, any amount and type of system interconnect in addition to or instead of fabric 3160 that facilitates data and control transmissions across any number and type of directly or indirectly linked components that may be internal or external to CPU 3100. In at least one embodiment, I/O interfaces 3170 are representative of any number and type of I/O interfaces (e.g., PCI, PCI-X, PCIe, GBE, USB, etc.). In at least one embodiment, various types of peripheral devices are coupled to I/O interfaces 3170 In at least one embodiment, peripheral devices that are coupled to I/O interfaces 3170 may include, without limitation, displays, keyboards, mice, printers, scanners, joysticks or other types of game controllers, media recording devices, external storage devices, network interface cards, and so forth.

In at least one embodiment, memory controllers 3180 facilitate data transfers between CPU 3100 and a system memory 3190. In at least one embodiment, core complex 3110 and graphics complex 3140 share system memory 3190. In at least one embodiment, CPU 3100 implements a memory subsystem that includes, without limitation, any amount and type of memory controllers 3180 and memory devices that may be dedicated to one component or shared among multiple components. In at least one embodiment, CPU 3100 implements a cache subsystem that includes, without limitation, one or more cache memories (e.g., L2 caches 3128 and L3 caches 3130) that may each be private to or shared between any number of components (e.g., cores 3120 and core complexes 3110).

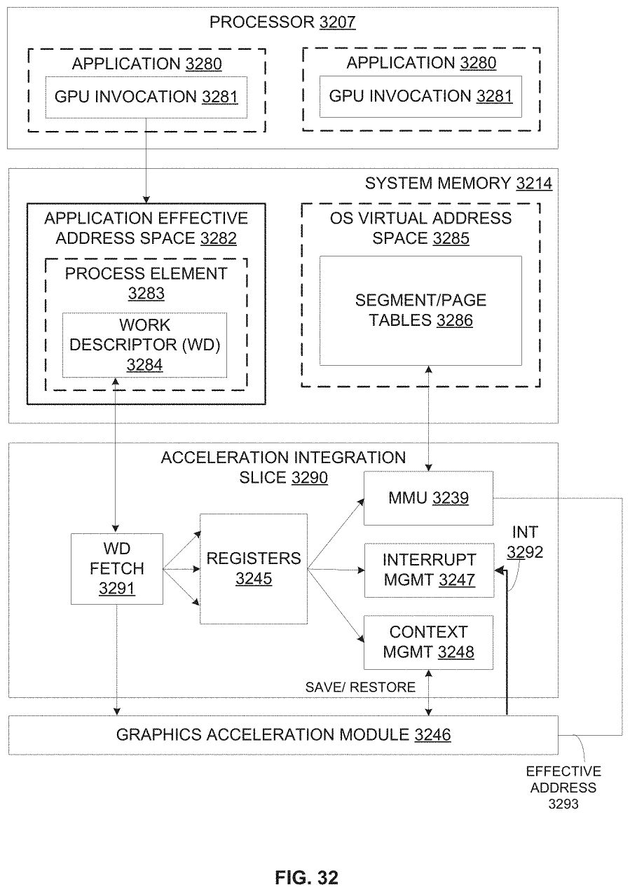

FIG. 32 illustrates an exemplary accelerator integration slice 3290, in accordance with at least one embodiment. As used herein, a “slice” comprises a specified portion of processing resources of an accelerator integration circuit. In at least one embodiment, the accelerator integration circuit provides cache management, memory access, context management, and interrupt management services on behalf of multiple graphics processing engines included in a graphics acceleration module. The graphics processing engines may each comprise a separate GPU. Alternatively, the graphics processing engines may comprise different types of graphics processing engines within a GPU such as graphics execution units, media processing engines (e.g., video encoders/decoders), samplers, and blit engines. In at least one embodiment, the graphics acceleration module may be a GPU with multiple graphics processing engines. In at least one embodiment, the graphics processing engines may be individual GPUs integrated on a common package, line card, or chip.

An application effective address space 3282 within system memory 3214 stores process elements 3283. In one embodiment, process elements 3283 are stored in response to GPU invocations 3281 from applications 3280 executed on processor 3207. A process element 3283 contains process state for corresponding application 3280. A work descriptor (“WD”) 3284 contained in process element 3283 can be a single job requested by an application or may contain a pointer to a queue of jobs. In at least one embodiment, WD 3284 is a pointer to a job request queue in application effective address space 3282. In at least one embodiment, application(s) 2442 performs one or more steps to perform operations discussed herein, such as decompressing or otherwise performing operations involving decoding of variable-length coded data in parallel.

Graphics acceleration module 3246 and/or individual graphics processing engines can be shared by all or a subset of processes in a system. In at least one embodiment, an infrastructure for setting up process state and sending WD 3284 to graphics acceleration module 3246 to start a job in a virtualized environment may be included. In at least one embodiment, processor 3237 performs one or more steps to perform operations discussed herein, such as decompressing or otherwise performing operations involving decoding of variable-length coded data in parallel.

In at least one embodiment, a dedicated-process programming model is implementation-specific. In this model, a single process owns graphics acceleration module 3246 or an individual graphics processing engine. Because graphics acceleration module 3246 is owned by a single process, a hypervisor initializes an accelerator integration circuit for an owning partition and an operating system initializes accelerator integration circuit for an owning process when graphics acceleration module 3246 is assigned.

In operation, a WD fetch unit 3291 in accelerator integration slice 3290 fetches next WD 3284 which includes an indication of work to be done by one or more graphics processing engines of graphics acceleration module 3246. Data from WD 3284 may be stored in registers 3245 and used by a memory management unit (“MMU”) 3239, interrupt management circuit 3247 and/or context management circuit 3248 as illustrated. For example, one embodiment of MMU 3239 includes segment/page walk circuitry for accessing segment/page tables 3286 within OS virtual address space 3285. Interrupt management circuit 3247 may process interrupt events (“INT”) 3292 received from graphics acceleration module 3246. When performing graphics operations, an effective address 3293 generated by a graphics processing engine is translated to a real address by MMIU 3239.

In one embodiment, a same set of registers 3245 are duplicated for each graphics processing engine and/or graphics acceleration module 3246 and may be initialized by a hypervisor or operating system. Each of these duplicated registers may be included in accelerator integration slice 3290. Exemplary registers that may be initialized by a hypervisor are shown in Table 1.

TABLE 1
Hypervisor Initialized Registers

| | |
|---|---|
| 1 | Slice Control Register |
| 2 | Real Address (RA) Scheduled Processes Area Pointer |
| 3 | Authority Mask Override Register |
| 4 | Interrupt Vector Table Entry Offset |
| 5 | Interrupt Vector Table Entry Limit |
| 6 | State Register |
| 7 | Logical Partition ID |
| 8 | Real address (RA) Hypervisor Accelerator Utilization Record Pointer |
| 9 | Storage Description Register |

Exemplary registers that may be initialized by an operating system are shown in Table 2.

TABLE 2
Operating System Initialized Registers

| | |
|---|---|
| 1 | Process and Thread Identification |
| 2 | Effective Address (EA) Context Save/Restore Pointer |
| 3 | Virtual Address (VA) Accelerator Utilization Record Pointer |
| 4 | Virtual Address (VA) Storage Segment Table Pointer |
| 5 | Authority Mask |
| 6 | Work descriptor |

In one embodiment, each WD 3284 is specific to a particular graphics acceleration module 3246 and/or a particular graphics processing engine. It contains all information required by a graphics processing engine to do work or it can be a pointer to a memory location where an application has set up a command queue of work to be completed.

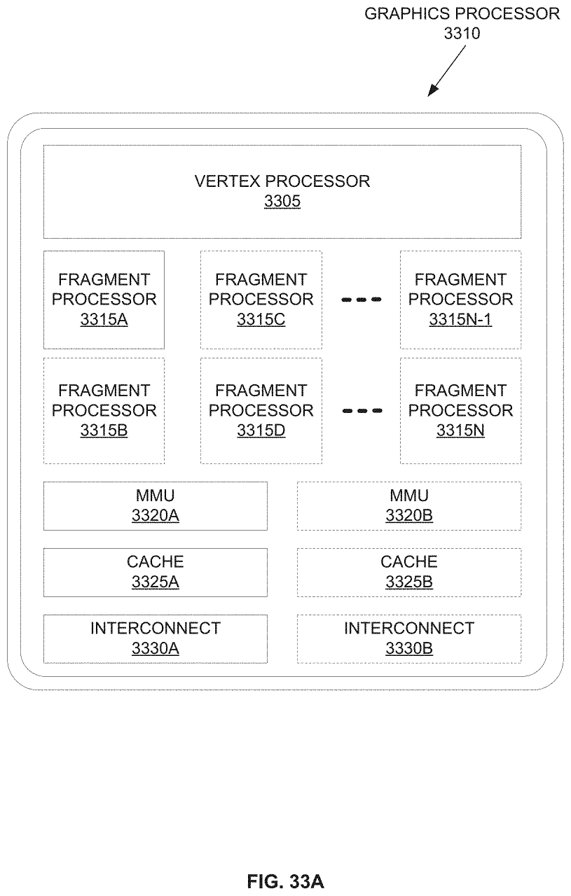

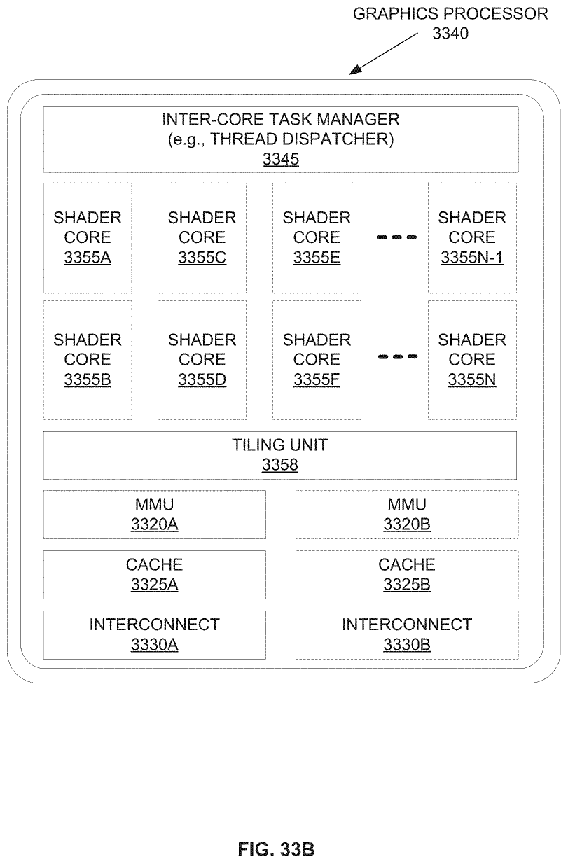

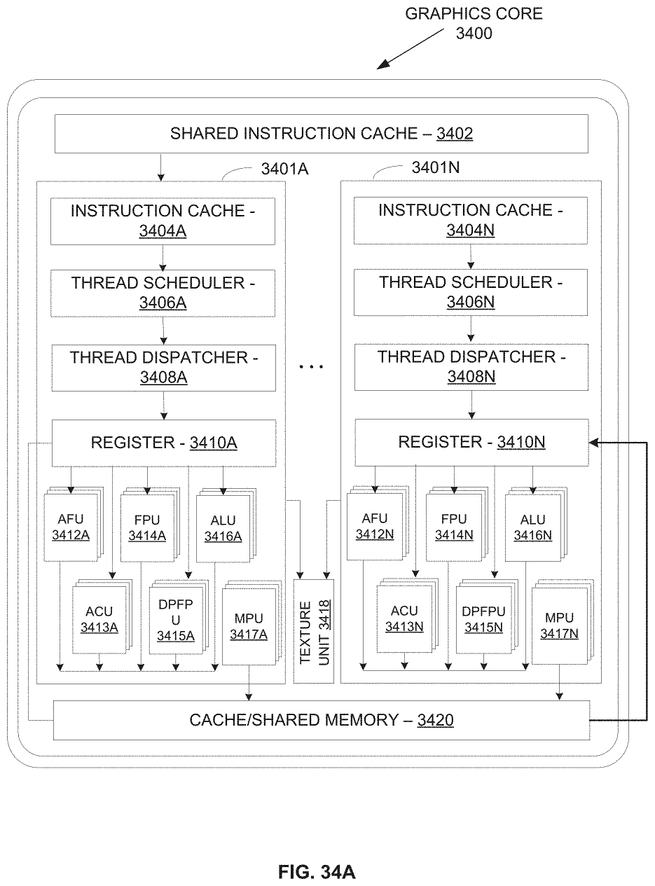

FIGS. 33A-33B illustrate exemplary graphics processors, in accordance with at least one embodiment. In at least one embodiment, any of the exemplary graphics processors may be fabricated using one or more IP cores. In addition to what is illustrated, other logic and circuits may be included in at least one embodiment, including additional graphics processors/cores, peripheral interface controllers, or general-purpose processor cores. In at least one embodiment, the exemplary graphics processors are for use within an SoC.

FIG. 33A illustrates an exemplary graphics processor 3310 of an SoC integrated circuit that may be fabricated using one or more IP cores, in accordance with at least one embodiment. FIG. 33B illustrates an additional exemplary graphics processor 3340 of an SoC integrated circuit that may be fabricated using one or more IP cores, in accordance with at least one embodiment. In at least one embodiment, graphics processor 3310 of FIG. 33A is a low power graphics processor core. In at least one embodiment, graphics processor 3340 of FIG. 33B is a higher performance graphics processor core. In at least one embodiment, each of graphics processors 3310, 3340 can be variants of graphics processor 2810 of FIG. 28. In at least one embodiment, graphics processor 3310 performs one or more steps to perform operations discussed herein, such as decompressing or otherwise performing operations involving decoding of variable-length coded data in parallel.

In at least one embodiment, graphics processor 3310 includes a vertex processor 3305 and one or more fragment processor(s) 3315A-3315N (e.g., 3315A, 3315B, 3315C, 3315D, through 3315N-1, and 3315N). In at least one embodiment, graphics processor 3310 can execute different shader programs via separate logic, such that vertex processor 3305 is optimized to execute operations for vertex shader programs, while one or more fragment processor(s) 3315A-3315N execute fragment (e.g., pixel) shading operations for fragment or pixel shader programs. In at least one embodiment, vertex processor 3305 performs a vertex processing stage of a 3D graphics pipeline and generates primitives and vertex data. In at least one embodiment, fragment processor(s) 3315A-3315N use primitive and vertex data generated by vertex processor 3305 to produce a framebuffer that is displayed on a display device. In at least one embodiment, fragment processor(s) 3315A-3315N are optimized to execute fragment shader programs as provided for in an OpenGL API, which may be used to perform similar operations as a pixel shader program as provided for in a Direct 3D API.

In at least one embodiment, graphics processor 3310 additionally includes one or more MMU(s) 3320A-3320B, cache(s) 3325A-3325B, and circuit interconnect(s) 3330A-3330B. In at least one embodiment, one or more MMU(s) 3320A-3320B provide for virtual to physical address mapping for graphics processor 3310, including for vertex processor 3305 and/or fragment processor(s) 3315A-3315N, which may reference vertex or image/texture data stored in memory, in addition to vertex or image/texture data stored in one or more cache(s) 3325A-3325B. In at least one embodiment, one or more MMU(s) 3320A-3320B may be synchronized with other MMUs within a system, including one or more MMUs associated with one or more application processor(s) 2805, image processors 2815, and/or video processors 2820 of FIG. 28, such that each processor 2805-2820 can participate in a shared or unified virtual memory system. In at least one embodiment, one or more circuit interconnect(s) 3330A-3330B enable graphics processor 3310 to interface with other IP cores within an SoC, either via an internal bus of the SoC or via a direct connection.

In at least one embodiment, graphics processor 3340 includes one or more MMU(s) 3320A-3320B, caches 3325A-3325B, and circuit interconnects 3330A-3330B of graphics processor 3310 of FIG. 33A. In at least one embodiment, graphics processor 3340 includes one or more shader core(s) 3355A-3355N (e.g., 3355A, 3355B, 3355C, 3355D, 3355E, 3355F, through 3355N-1, and 3355N), which provides for a unified shader core architecture in which a single core or type or core can execute all types of programmable shader code, including shader program code to implement vertex shaders, fragment shaders, and/or compute shaders. In at least one embodiment, a number of shader cores can vary. In at least one embodiment, graphics processor 3340 includes an inter-core task manager 3345, which acts as a thread dispatcher to dispatch execution threads to one or more shader cores 3355A-3355N and a tiling unit 3358 to accelerate tiling operations for tile-based rendering, in which rendering operations for a scene are subdivided in image space, for example to exploit local spatial coherence within a scene or to optimize use of internal caches. In at least one embodiment, graphics processor 3340 performs one or more steps to perform operations discussed herein, such as decompressing or otherwise performing operations involving decoding of variable-length coded data in parallel.

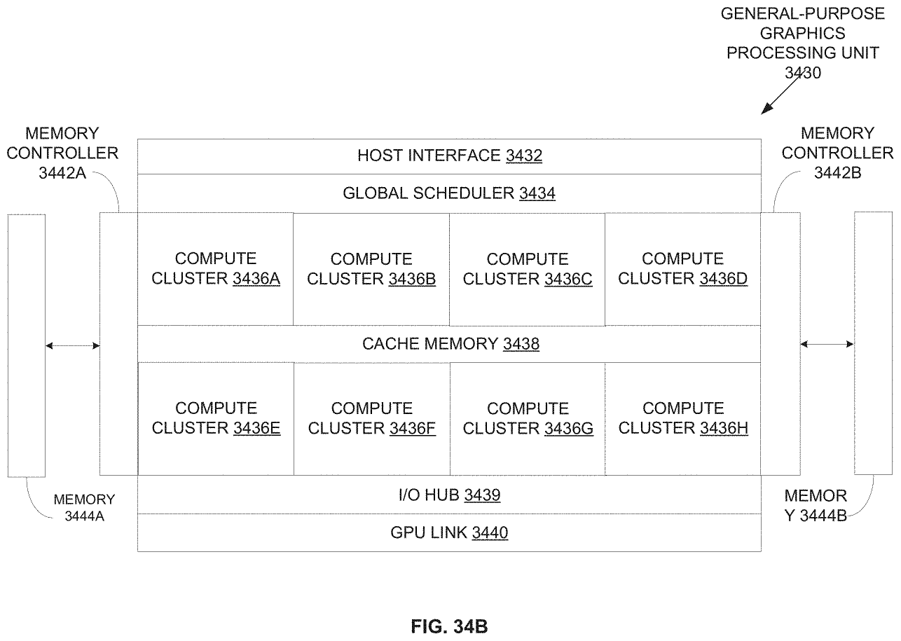

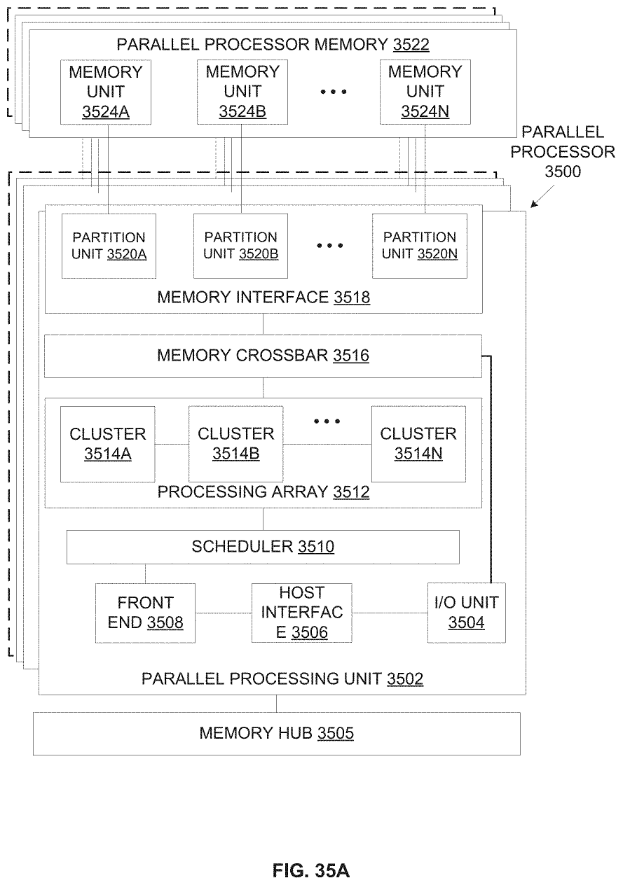

FIG. 34A illustrates a graphics core 3400, in accordance with at least one embodiment. In at least one embodiment, graphics core 3400 may be included within graphics processor 2810 of FIG. 28. In at least one embodiment, graphics core 3400 may be a unified shader core 3355A-3355N as in FIG. 33B. In at least one embodiment, graphics core 3400 includes a shared instruction cache 3402, a texture unit 3418, and a cache/shared memory 3420 that are common to execution resources within graphics core 3400. In at least one embodiment, graphics core 3400 can include multiple slices 3401A-3401N or partition for each core, and a graphics processor can include multiple instances of graphics core 3400. Slices 3401A-3401N can include support logic including a local instruction cache 3404A-3404N, a thread scheduler 3406A-3406N, a thread dispatcher 3408A-3408N, and a set of registers 3410A-3410N. In at least one embodiment, slices 3401A-3401N can include a set of additional function units (“AFUs”) 3412A-3412N, floating-point units (“FPUs”) 3414A-3414N, integer arithmetic logic units (“ALUs”) 3416-3416N, address computational units (“ACUs”) 3413A-3413N, double-precision floating-point units (“DPFPUs”) 3415A-3415N, and matrix processing units (“MPUs”) 3417A-3417N. In at least one embodiment, graphics core 3400 performs one or more steps to perform operations discussed herein, such as decompressing or otherwise performing operations involving decoding of variable-length coded data in parallel.

In at least one embodiment, FPUs 3414A-3414N can perform single-precision (32-bit) and half-precision (16-bit) floating point operations, while DPFPUs 3415A-3415N perform double precision (64-bit) floating point operations. In at least one embodiment, ALUs 3416A-3416N can perform variable precision integer operations at 8-bit, 16-bit, and 32-bit precision, and can be configured for mixed precision operations. In at least one embodiment, MPUs 3417A-3417N can also be configured for mixed precision matrix operations, including half-precision floating point and 8-bit integer operations. In at least one embodiment, MPUs 3417-3417N can perform a variety of matrix operations to accelerate CUDA programs, including enabling support for accelerated general matrix to matrix multiplication (“GEMM”). In at least one embodiment, AFUs 3412A-3412N can perform additional logic operations not supported by floating-point or integer units, including trigonometric operations (e.g., Sine, Cosine, etc.).

FIG. 34B illustrates a general-purpose graphics processing unit (“GPGPU”) 3430, in accordance with at least one embodiment. In at least one embodiment, GPGPU 3430 is highly-parallel and suitable for deployment on a multi-chip module. In at least one embodiment, GPGPU 3430 can be configured to enable highly-parallel compute operations to be performed by an array of GPUs. In at least one embodiment, GPGPU 3430 can be linked directly to other instances of GPGPU 3430 to create a multi-GPU cluster to improve execution time for CUDA programs. In at least one embodiment, GPGPU 3430 includes a host interface 3432 to enable a connection with a host processor. In at least one embodiment, host interface 3432 is a PCIe interface. In at least one embodiment, host interface 3432 can be a vendor specific communications interface or communications fabric. In at least one embodiment, GPGPU 3430 receives commands from a host processor and uses a global scheduler 3434 to distribute execution threads associated with those commands to a set of compute clusters 3436A-3436H. In at least one embodiment, compute clusters 3436A-3436H share a cache memory 3438. In at least one embodiment, cache memory 3438 can serve as a higher-level cache for cache memories within compute clusters 3436A-3436H. In at least one embodiment, GPGPU 3430 performs one or more steps to perform operations discussed herein, such as decompressing or otherwise performing operations involving decoding of variable-length coded data in parallel.

In at least one embodiment, GPGPU 3430 includes memory 3444A-3444B coupled with compute clusters 3436A-3436H via a set of memory controllers 3442A-3442B. In at least one embodiment, memory 3444A-3444B can include various types of memory devices including DRAM or graphics random access memory, such as synchronous graphics random access memory (“SGRAM”), including graphics double data rate (“GDDR”) memory.

In at least one embodiment, compute clusters 3436A-3436H each include a set of graphics cores, such as graphics core 3400 of FIG. 34A, which can include multiple types of integer and floating point logic units that can perform computational operations at a range of precisions including suited for computations associated with CUDA programs. For example, in at least one embodiment, at least a subset of floating point units in each of compute clusters 3436A-3436H can be configured to perform 16-bit or 32-bit floating point operations, while a different subset of floating point units can be configured to perform 64-bit floating point operations.

In at least one embodiment, multiple instances of GPGPU 3430 can be configured to operate as a compute cluster. Compute clusters 3436A-3436H may implement any technically feasible communication techniques for synchronization and data exchange. In at least one embodiment, multiple instances of GPGPU 3430 communicate over host interface 3432. In at least one embodiment, GPGPU 3430 includes an I/O hub 3439 that couples GPGPU 3430 with a GPU link 3440 that enables a direct connection to other instances of GPGPU 3430. In at least one embodiment, GPU link 3440 is coupled to a dedicated GPU-to-GPU bridge that enables communication and synchronization between multiple instances of GPGPU 3430. In at least one embodiment GPU link 3440 couples with a high speed interconnect to transmit and receive data to other GPGPUs 3430 or parallel processors. In at least one embodiment, multiple instances of GPGPU 3430 are located in separate data processing systems and communicate via a network device that is accessible via host interface 3432. In at least one embodiment GPU link 3440 can be configured to enable a connection to a host processor in addition to or as an alternative to host interface 3432. In at least one embodiment, GPGPU 3430 can be configured to execute a CUDA program.

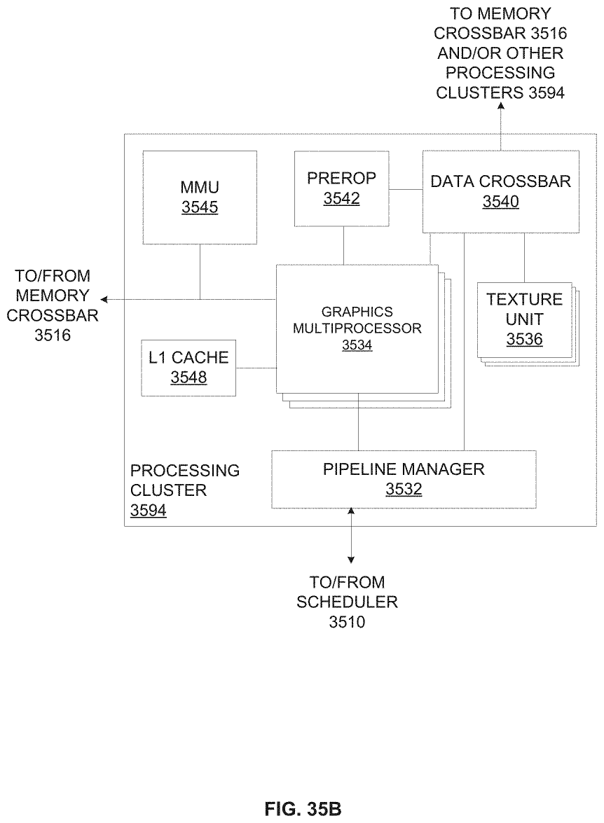

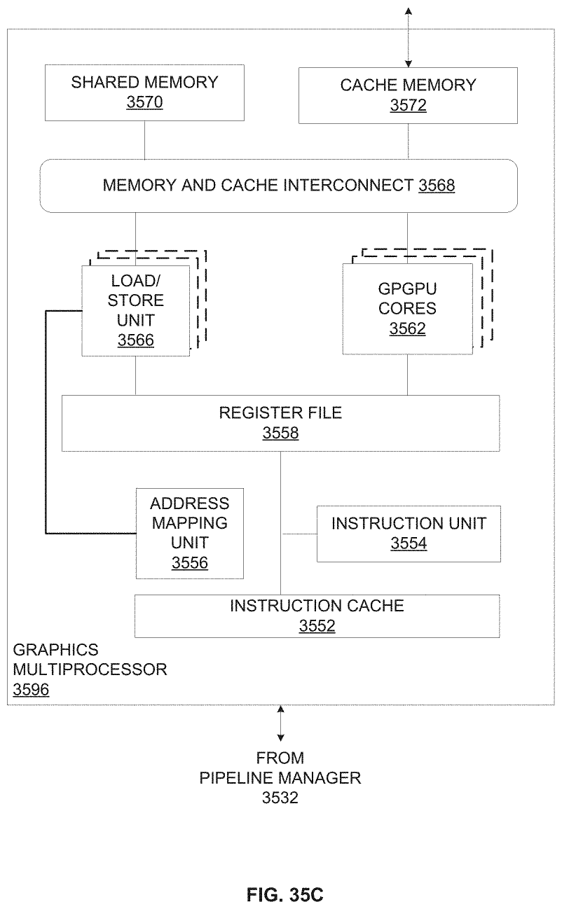

FIG. 35A illustrates a parallel processor 3500, in accordance with at least one embodiment. In at least one embodiment, various components of parallel processor 3500 may be implemented using one or more integrated circuit devices, such as programmable processors, application specific integrated circuits (“ASICs”), or FPGAs. In at least one embodiment, parallel processor 3500 performs one or more steps to perform operations discussed herein, such as decompressing or otherwise performing operations involving decoding of variable-length coded data in parallel.

In at least one embodiment, parallel processor 3500 includes a parallel processing unit 3502. In at least one embodiment, parallel processing unit 3502 includes an I/O unit 3504 that enables communication with other devices, including other instances of parallel processing unit 3502. In at least one embodiment, I/O unit 3504 may be directly connected to other devices. In at least one embodiment, I/O unit 3504 connects with other devices via use of a hub or switch interface, such as memory hub 3505. In at least one embodiment, connections between memory hub 3505 and I/O unit 3504 form a communication link. In at least one embodiment, I/O unit 3504 connects with a host interface 3506 and a memory crossbar 3516, where host interface 3506 receives commands directed to performing processing operations and memory crossbar 3516 receives commands directed to performing memory operations.

In at least one embodiment, when host interface 3506 receives a command buffer via I/O unit 3504, host interface 3506 can direct work operations to perform those commands to a front end 3508. In at least one embodiment, front end 3508 couples with a scheduler 3510, which is configured to distribute commands or other work items to a processing array 3512. In at least one embodiment, scheduler 3510 ensures that processing array 3512 is properly configured and in a valid state before tasks are distributed to processing array 3512. In at least one embodiment, scheduler 3510 is implemented via firmware logic executing on a microcontroller. In at least one embodiment, microcontroller implemented scheduler 3510 is configurable to perform complex scheduling and work distribution operations at coarse and fine granularity, enabling rapid preemption and context switching of threads executing on processing array 3512. In at least one embodiment, host software can prove workloads for scheduling on processing array 3512 via one of multiple graphics processing doorbells. In at least one embodiment, workloads can then be automatically distributed across processing array 3512 by scheduler 3510 logic within a microcontroller including scheduler 3510.

In at least one embodiment, processing array 3512 can include up to “N” clusters (e.g., cluster 3514A, cluster 3514B, through cluster 3514N). In at least one embodiment, each cluster 3514A-3514N of processing array 3512 can execute a large number of concurrent threads. In at least one embodiment, scheduler 3510 can allocate work to clusters 3514A-3514N of processing array 3512 using various scheduling and/or work distribution algorithms, which may vary depending on the workload arising for each type of program or computation. In at least one embodiment, scheduling can be handled dynamically by scheduler 3510, or can be assisted in part by compiler logic during compilation of program logic configured for execution by processing array 3512. In at least one embodiment, different clusters 3514A-3514N of processing array 3512 can be allocated for processing different types of programs or for performing different types of computations.

In at least one embodiment, processing array 3512 can be configured to perform various types of parallel processing operations. In at least one embodiment, processing array 3512 is configured to perform general-purpose parallel compute operations. For example, in at least one embodiment, processing array 3512 can include logic to execute processing tasks including filtering of video and/or audio data, performing modeling operations, including physics operations, and performing data transformations.

In at least one embodiment, processing array 3512 is configured to perform parallel graphics processing operations. In at least one embodiment, processing array 3512 can include additional logic to support execution of such graphics processing operations, including, but not limited to texture sampling logic to perform texture operations, as well as tessellation logic and other vertex processing logic. In at least one embodiment, processing array 3512 can be configured to execute graphics processing related shader programs such as, but not limited to vertex shaders, tessellation shaders, geometry shaders, and pixel shaders. In at least one embodiment, parallel processing unit 3502 can transfer data from system memory via I/O unit 3504 for processing. In at least one embodiment, during processing, transferred data can be stored to on-chip memory (e.g., a parallel processor memory 3522) during processing, then written back to system memory.

In at least one embodiment, when parallel processing unit 3502 is used to perform graphics processing, scheduler 3510 can be configured to divide a processing workload into approximately equal sized tasks, to better enable distribution of graphics processing operations to multiple clusters 3514A-3514N of processing array 3512. In at least one embodiment, portions of processing array 3512 can be configured to perform different types of processing. For example, in at least one embodiment, a first portion may be configured to perform vertex shading and topology generation, a second portion may be configured to perform tessellation and geometry shading, and a third portion may be configured to perform pixel shading or other screen space operations, to produce a rendered image for display. In at least one embodiment, intermediate data produced by one or more of clusters 3514A-3514N may be stored in buffers to allow intermediate data to be transmitted between clusters 3514A-3514N for further processing.

In at least one embodiment, processing array 3512 can receive processing tasks to be executed via scheduler 3510, which receives commands defining processing tasks from front end 3508. In at least one embodiment, processing tasks can include indices of data to be processed, e.g., surface (patch) data, primitive data, vertex data, and/or pixel data, as well as state parameters and commands defining how data is to be processed (e.g., what program is to be executed). In at least one embodiment, scheduler 3510 may be configured to fetch indices corresponding to tasks or may receive indices from front end 3508. In at least one embodiment, front end 3508 can be configured to ensure processing array 3512 is configured to a valid state before a workload specified by incoming command buffers (e.g., batch-buffers, push buffers, etc.) is initiated.

In at least one embodiment, each of one or more instances of parallel processing unit 3502 can couple with parallel processor memory 3522. In at least one embodiment, parallel processor memory 3522 can be accessed via memory crossbar 3516, which can receive memory requests from processing array 3512 as well as I/O unit 3504. In at least one embodiment, memory crossbar 3516 can access parallel processor memory 3522 via a memory interface 3518. In at least one embodiment, memory interface 3518 can include multiple partition units (e.g., a partition unit 3520A, partition unit 3520B, through partition unit 3520N) that can each couple to a portion (e.g., memory unit) of parallel processor memory 3522. In at least one embodiment, a number of partition units 3520A-3520N is configured to be equal to a number of memory units, such that a first partition unit 3520A has a corresponding first memory unit 3524A, a second partition unit 3520B has a corresponding memory unit 3524B, and an Nth partition unit 3520N has a corresponding Nth memory unit 3524N. In at least one embodiment, a number of partition units 3520A-3520N may not be equal to a number of memory devices.

In at least one embodiment, memory units 3524A-3524N can include various types of memory devices, including DRAM or graphics random access memory, such as SGRAM, including GDDR memory. In at least one embodiment, memory units 3524A-3524N may also include 3D stacked memory, including but not limited to high bandwidth memory (“HBM”). In at least one embodiment, render targets, such as frame buffers or texture maps may be stored across memory units 3524A-3524N, allowing partition units 3520A-3520N to write portions of each render target in parallel to efficiently use available bandwidth of parallel processor memory 3522. In at least one embodiment, a local instance of parallel processor memory 3522 may be excluded in favor of a unified memory design that utilizes system memory in conjunction with local cache memory.

In at least one embodiment, any one of clusters 3514A-3514N of processing array 3512 can process data that will be written to any of memory units 3524A-3524N within parallel processor memory 3522. In at least one embodiment, memory crossbar 3516 can be configured to transfer an output of each cluster 3514A-3514N to any partition unit 3520A-3520N or to another cluster 3514A-3514N, which can perform additional processing operations on an output. In at least one embodiment, each cluster 3514A-3514N can communicate with memory interface 3518 through memory crossbar 3516 to read from or write to various external memory devices. In at least one embodiment, memory crossbar 3516 has a connection to memory interface 3518 to communicate with I/O unit 3504, as well as a connection to a local instance of parallel processor memory 3522, enabling processing units within different clusters 3514A-3514N to communicate with system memory or other memory that is not local to parallel processing unit 3502. In at least one embodiment, memory crossbar 3516 can use virtual channels to separate traffic streams between clusters 3514A-3514N and partition units 3520A-3520N.

In at least one embodiment, multiple instances of parallel processing unit 3502 can be provided on a single add-in card, or multiple add-in cards can be interconnected. In at least one embodiment, different instances of parallel processing unit 3502 can be configured to inter-operate even if different instances have different numbers of processing cores, different amounts of local parallel processor memory, and/or other configuration differences. For example, in at least one embodiment, some instances of parallel processing unit 3502 can include higher precision floating point units relative to other instances. In at least one embodiment, systems incorporating one or more instances of parallel processing unit 3502 or parallel processor 3500 can be implemented in a variety of configurations and form factors, including but not limited to desktop, laptop, or handheld personal computers, servers, workstations, game consoles, and/or embedded systems.

FIG. 35B illustrates a processing cluster 3594, in accordance with at least one embodiment. In at least one embodiment, processing cluster 3594 is included within a parallel processing unit. In at least one embodiment, processing cluster 3594 is one of processing clusters 3514A-3514N of FIG. 35. In at least one embodiment, processing cluster 3594 can be configured to execute many threads in parallel, where the term “thread” refers to an instance of a particular program executing on a particular set of input data. In at least one embodiment, single instruction, multiple data (“SIMD”) instruction issue techniques are used to support parallel execution of a large number of threads without providing multiple independent instruction units. In at least one embodiment, single instruction, multiple thread (“SIMT”) techniques are used to support parallel execution of a large number of generally synchronized threads, using a common instruction unit configured to issue instructions to a set of processing engines within each processing cluster 3594.

In at least one embodiment, operation of processing cluster 3594 can be controlled via a pipeline manager 3532 that distributes processing tasks to SIMT parallel processors. In at least one embodiment, pipeline manager 3532 receives instructions from scheduler 3510 of FIG. 35 and manages execution of those instructions via a graphics multiprocessor 3534 and/or a texture unit 3536. In at least one embodiment, graphics multiprocessor 3534 is an exemplary instance of a SIMT parallel processor. However, in at least one embodiment, various types of SIMT parallel processors of differing architectures may be included within processing cluster 3594. In at least one embodiment, one or more instances of graphics multiprocessor 3534 can be included within processing cluster 3594. In at least one embodiment, graphics multiprocessor 3534 can process data and a data crossbar 3540 can be used to distribute processed data to one of multiple possible destinations, including other shader units. In at least one embodiment, pipeline manager 3532 can facilitate distribution of processed data by specifying destinations for processed data to be distributed via data crossbar 3540. In at least one embodiment, graphics multiprocessor 3534 performs one or more steps to perform operations discussed herein, such as decompressing or otherwise performing operations involving decoding of variable-length coded data in parallel.

In at least one embodiment, each graphics multiprocessor 3534 within processing cluster 3594 can include an identical set of functional execution logic (e.g., arithmetic logic units, load/store units (“LSUs”), etc.). In at least one embodiment, functional execution logic can be configured in a pipelined manner in which new instructions can be issued before previous instructions are complete. In at least one embodiment, functional execution logic supports a variety of operations including integer and floating point arithmetic, comparison operations, Boolean operations, bit-shifting, and computation of various algebraic functions. In at least one embodiment, same functional-unit hardware can be leveraged to perform different operations and any combination of functional units may be present.

In at least one embodiment, instructions transmitted to processing cluster 3594 constitute a thread. In at least one embodiment, a set of threads executing across a set of parallel processing engines is a thread group. In at least one embodiment, a thread group executes a program on different input data. In at least one embodiment, each thread within a thread group can be assigned to a different processing engine within graphics multiprocessor 3534. In at least one embodiment, a thread group may include fewer threads than a number of processing engines within graphics multiprocessor 3534. In at least one embodiment, when a thread group includes fewer threads than a number of processing engines, one or more of the processing engines may be idle during cycles in which that thread group is being processed. In at least one embodiment, a thread group may also include more threads than a number of processing engines within graphics multiprocessor 3534. In at least one embodiment, when a thread group includes more threads than the number of processing engines within graphics multiprocessor 3534, processing can be performed over consecutive clock cycles. In at least one embodiment, multiple thread groups can be executed concurrently on graphics multiprocessor 3534.

In at least one embodiment, graphics multiprocessor 3534 includes an internal cache memory to perform load and store operations. In at least one embodiment, graphics multiprocessor 3534 can forego an internal cache and use a cache memory (e.g., L1 cache 3548) within processing cluster 3594. In at least one embodiment, each graphics multiprocessor 3534 also has access to Level 2 (“L2”) caches within partition units (e.g., partition units 3520A-3520N of FIG. 35A) that are shared among all processing clusters 3594 and may be used to transfer data between threads. In at least one embodiment, graphics multiprocessor 3534 may also access off-chip global memory, which can include one or more of local parallel processor memory and/or system memory. In at least one embodiment, any memory external to parallel processing unit 3502 may be used as global memory. In at least one embodiment, processing cluster 3594 includes multiple instances of graphics multiprocessor 3534 that can share common instructions and data, which may be stored in L1 cache 3548.

In at least one embodiment, each processing cluster 3594 may include an MMU 3545 that is configured to map virtual addresses into physical addresses. In at least one embodiment, one or more instances of MMU 3545 may reside within memory interface 3518 of FIG. 35. In at least one embodiment, MMU 3545 includes a set of page table entries (“PTEs”) used to map a virtual address to a physical address of a tile and optionally a cache line index. In at least one embodiment, MMU 3545 may include address translation lookaside buffers (“TLBs”) or caches that may reside within graphics multiprocessor 3534 or L1 cache 3548 or processing cluster 3594. In at least one embodiment, a physical address is processed to distribute surface data access locality to allow efficient request interleaving among partition units. In at least one embodiment, a cache line index may be used to determine whether a request for a cache line is a hit or miss.

In at least one embodiment, processing cluster 3594 may be configured such that each graphics multiprocessor 3534 is coupled to a texture unit 3536 for performing texture mapping operations, e.g., determining texture sample positions, reading texture data, and filtering texture data. In at least one embodiment, texture data is read from an internal texture L1 cache (not shown) or from an L1 cache within graphics multiprocessor 3534 and is fetched from an L2 cache, local parallel processor memory, or system memory, as needed. In at least one embodiment, each graphics multiprocessor 3534 outputs a processed task to data crossbar 3540 to provide the processed task to another processing cluster 3594 for further processing or to store the processed task in an L2 cache, a local parallel processor memory, or a system memory via memory crossbar 3516. In at least one embodiment, a pre-raster operations unit (“preROP”) 3542 is configured to receive data from graphics multiprocessor 3534, direct data to ROP units, which may be located with partition units as described herein (e.g., partition units 3520A-3520N of FIG. 35). In at least one embodiment, PreROP 3542 can perform optimizations for color blending, organize pixel color data, and perform address translations.

FIG. 35C illustrates a graphics multiprocessor 3596, in accordance with at least one embodiment. In at least one embodiment, graphics multiprocessor 3596 is graphics multiprocessor 3534 of FIG. 35B. In at least one embodiment, graphics multiprocessor 3596 couples with pipeline manager 3532 of processing cluster 3594. In at least one embodiment, graphics multiprocessor 3596 has an execution pipeline including but not limited to an instruction cache 3552, an instruction unit 3554, an address mapping unit 3556, a register file 3558, one or more GPGPU cores 3562, and one or more LSUs 3566. GPGPU cores 3562 and LSUs 3566 are coupled with cache memory 3572 and shared memory 3570 via a memory and cache interconnect 3568. In at least one embodiment, graphics multiprocessor 3596 performs one or more steps to perform operations discussed herein, such as decompressing or otherwise performing operations involving decoding of variable-length coded data in parallel.

In at least one embodiment, instruction cache 3552 receives a stream of instructions to execute from pipeline manager 3532. In at least one embodiment, instructions are cached in instruction cache 3552 and dispatched for execution by instruction unit 3554. In at least one embodiment, instruction unit 3554 can dispatch instructions as thread groups (e.g., warps), with each thread of a thread group assigned to a different execution unit within GPGPU core 3562. In at least one embodiment, an instruction can access any of a local, shared, or global address space by specifying an address within a unified address space. In at least one embodiment, address mapping unit 3556 can be used to translate addresses in a unified address space into a distinct memory address that can be accessed by LSUs 3566.

In at least one embodiment, register file 3558 provides a set of registers for functional units of graphics multiprocessor 3596. In at least one embodiment, register file 3558 provides temporary storage for operands connected to data paths of functional units (e.g., GPGPU cores 3562, LSUs 3566) of graphics multiprocessor 3596. In at least one embodiment, register file 3558 is divided between each of functional units such that each functional unit is allocated a dedicated portion of register file 3558. In at least one embodiment, register file 3558 is divided between different thread groups being executed by graphics multiprocessor 3596.

In at least one embodiment, GPGPU cores 3562 can each include FPUs and/or integer ALUs that are used to execute instructions of graphics multiprocessor 3596. GPGPU cores 3562 can be similar in architecture or can differ in architecture. In at least one embodiment, a first portion of GPGPU cores 3562 include a single precision FPU and an integer ALU while a second portion of GPGPU cores 3562 include a double precision FPU. In at least one embodiment, FPUs can implement IEEE 754-2008 standard for floating point arithmetic or enable variable precision floating point arithmetic. In at least one embodiment, graphics multiprocessor 3596 can additionally include one or more fixed function or special function units to perform specific functions such as copy rectangle or pixel blending operations. In at least one embodiment one or more of GPGPU cores 3562 can also include fixed or special function logic.

In at least one embodiment, GPGPU cores 3562 include SIMD logic capable of performing a single instruction on multiple sets of data. In at least one embodiment GPGPU cores 3562 can physically execute SIMD4, SIMD8, and SIMD16 instructions and logically execute SIMD1, SIMD2, and SIMND32 instructions. In at least one embodiment, SIMD instructions for GPGPU cores 3562 can be generated at compile time by a shader compiler or automatically generated when executing programs written and compiled for single program multiple data (“SPMD”) or SIMT architectures. In at least one embodiment, multiple threads of a program configured for an SIMT execution model can executed via a single SIMD instruction. For example, in at least one embodiment, eight SIMT threads that perform the same or similar operations can be executed in parallel via a single SIMD8 logic unit.

In at least one embodiment, memory and cache interconnect 3568 is an interconnect network that connects each functional unit of graphics multiprocessor 3596 to register file 3558 and to shared memory 3570. In at least one embodiment, memory and cache interconnect 3568 is a crossbar interconnect that allows LSU 3566 to implement load and store operations between shared memory 3570 and register file 3558. In at least one embodiment, register file 3558 can operate at a same frequency as GPGPU cores 3562, thus data transfer between GPGPU cores 3562 and register file 3558 is very low latency. In at least one embodiment, shared memory 3570 can be used to enable communication between threads that execute on functional units within graphics multiprocessor 3596. In at least one embodiment, cache memory 3572 can be used as a data cache for example, to cache texture data communicated between functional units and texture unit 3536. In at least one embodiment, shared memory 3570 can also be used as a program managed cached. In at least one embodiment, threads executing on GPGPU cores 3562 can programmatically store data within shared memory in addition to automatically cached data that is stored within cache memory 3572.

In at least one embodiment, a parallel processor or GPGPU as described herein is communicatively coupled to host/processor cores to accelerate graphics operations, machine-learning operations, pattern analysis operations, and various general purpose GPU (GPGPU) functions. In at least one embodiment, a GPU may be communicatively coupled to host processor/cores over a bus or other interconnect (e.g., a high speed interconnect such as PCIe or NVLink). In at least one embodiment, a GPU may be integrated on the same package or chip as cores and communicatively coupled to cores over a processor bus/interconnect that is internal to a package or a chip. In at least one embodiment, regardless of the manner in which a GPU is connected, processor cores may allocate work to the GPU in the form of sequences of commands/instructions contained in a WD. In at least one embodiment, the GPU then uses dedicated circuitry/logic for efficiently processing these commands/instructions.

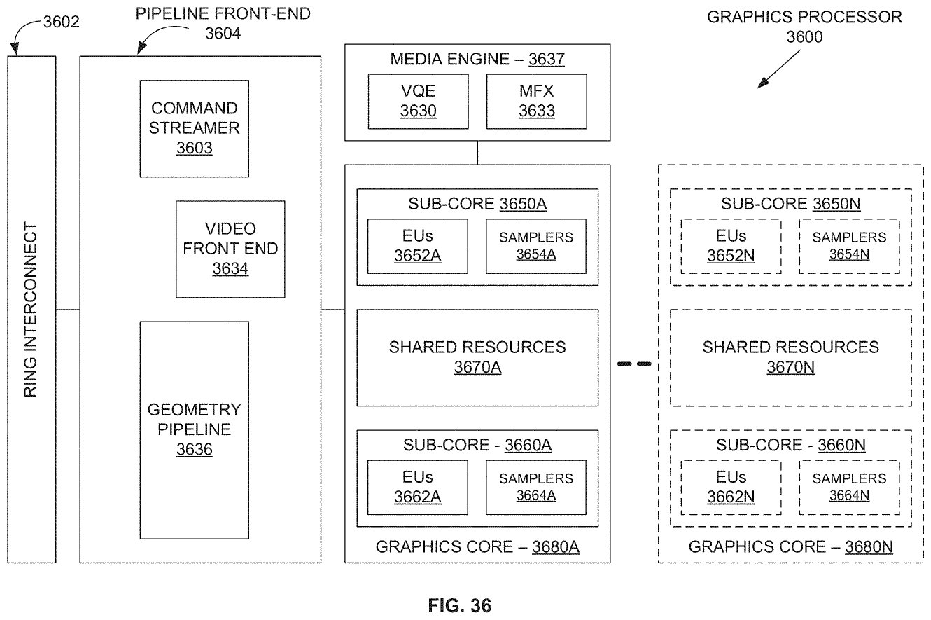

FIG. 36 illustrates a graphics processor 3600, in accordance with at least one embodiment. In at least one embodiment, graphics processor 3600 includes a ring interconnect 3602, a pipeline front-end 3604, a media engine 3637, and graphics cores 3680A-3680N. In at least one embodiment, ring interconnect 3602 couples graphics processor 3600 to other processing units, including other graphics processors or one or more general-purpose processor cores. In at least one embodiment, graphics processor 3600 is one of many processors integrated within a multi-core processing system. In at least one embodiment, graphics processor 3600 performs one or more steps to perform operations discussed herein, such as decompressing or otherwise performing operations involving decoding of variable-length coded data in parallel.

In at least one embodiment, graphics processor 3600 receives batches of commands via ring interconnect 3602. In at least one embodiment, incoming commands are interpreted by a command streamer 3603 in pipeline front-end 3604. In at least one embodiment, graphics processor 3600 includes scalable execution logic to perform 3D geometry processing and media processing via graphics core(s) 3680A-3680N. In at least one embodiment, for 3D geometry processing commands, command streamer 3603 supplies commands to geometry pipeline 3636. In at least one embodiment, for at least some media processing commands, command streamer 3603 supplies commands to a video front end 3634, which couples with a media engine 3637. In at least one embodiment, media engine 3637 includes a Video Quality Engine (“VQE”) 3630 for video and image post-processing and a multi-format encode/decode (“MFX”) engine 3633 to provide hardware-accelerated media data encode and decode. In at least one embodiment, geometry pipeline 3636 and media engine 3637 each generate execution threads for thread execution resources provided by at least one graphics core 3680A.

In at least one embodiment, graphics processor 3600 includes scalable thread execution resources featuring modular graphics cores 3680A-3680N (sometimes referred to as core slices), each having multiple sub-cores 3650A-550N, 3660A-3660N (sometimes referred to as core sub-slices). In at least one embodiment, graphics processor 3600 can have any number of graphics cores 3680A through 3680N. In at least one embodiment, graphics processor 3600 includes a graphics core 3680A having at least a first sub-core 3650A and a second sub-core 3660A. In at least one embodiment, graphics processor 3600 is a low power processor with a single sub-core (e.g., sub-core 3650A). In at least one embodiment, graphics processor 3600 includes multiple graphics cores 3680A-3680N, each including a set of first sub-cores 3650A-3650N and a set of second sub-cores 3660A-3660N. In at least one embodiment, each sub-core in first sub-cores 3650A-3650N includes at least a first set of execution units (“EUs”) 3652A-3652N and media/texture samplers 3654A-3654N. In at least one embodiment, each sub-core in second sub-cores 3660A-3660N includes at least a second set of execution units 3662A-3662N and samplers 3664A-3664N. In at least one embodiment, each sub-core 3650A-3650N, 3660A-3660N shares a set of shared resources 3670A-3670N. In at least one embodiment, shared resources 3670 include shared cache memory and pixel operation logic.

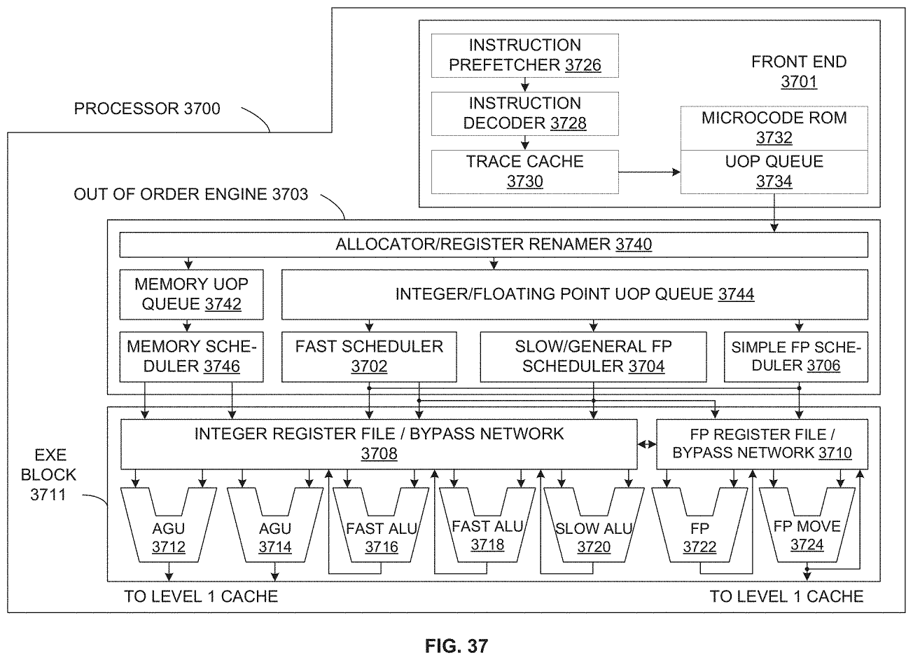

FIG. 37 illustrates a processor 3700, in accordance with at least one embodiment. In at least one embodiment, processor 3700 may include, without limitation, logic circuits to perform instructions. In at least one embodiment, processor 3700 may perform instructions, including x86 instructions, ARM instructions, specialized instructions for ASICs, etc. In at least one embodiment, processor 3710 may include registers to store packed data, such as 64-bit wide MMX™ registers in microprocessors enabled with MMX technology from Intel Corporation of Santa Clara, Calif. In at least one embodiment, MMX registers, available in both integer and floating point forms, may operate with packed data elements that accompany SIMD and streaming SIMD extensions (“SSE”) instructions. In at least one embodiment, 128-bit wide XMM registers relating to SSE2, SSE3, SSE4, AVX, or beyond (referred to generically as “SSEx”) technology may hold such packed data operands. In at least one embodiment, processors 3710 may perform instructions to accelerate CUDA programs. In at least one embodiment, processor 3700 performs one or more steps to perform operations discussed herein, such as decompressing or otherwise performing operations involving decoding of variable-length coded data in parallel.

In at least one embodiment, processor 3700 includes an in-order front end (“front end”) 3701 to fetch instructions to be executed and prepare instructions to be used later in processor pipeline. In at least one embodiment, front end 3701 may include several units. In at least one embodiment, an instruction prefetcher 3726 fetches instructions from memory and feeds instructions to an instruction decoder 3728 which in turn decodes or interprets instructions. For example, in at least one embodiment, instruction decoder 3728 decodes a received instruction into one or more operations called “micro-instructions” or “micro-operations” (also called “micro ops” or “uops”) for execution. In at least one embodiment, instruction decoder 3728 parses instruction into an opcode and corresponding data and control fields that may be used by micro-architecture to perform operations. In at least one embodiment, a trace cache 3730 may assemble decoded uops into program ordered sequences or traces in a uop queue 3734 for execution. In at least one embodiment, when trace cache 3730 encounters a complex instruction, a microcode ROM 3732 provides uops needed to complete an operation.

In at least one embodiment, some instructions may be converted into a single micro-op, whereas others need several micro-ops to complete full operation. In at least one embodiment, if more than four micro-ops are needed to complete an instruction, instruction decoder 3728 may access microcode ROM 3732 to perform instruction. In at least one embodiment, an instruction may be decoded into a small number of micro-ops for processing at instruction decoder 3728. In at least one embodiment, an instruction may be stored within microcode ROM 3732 should a number of micro-ops be needed to accomplish operation. In at least one embodiment, trace cache 3730 refers to an entry point programmable logic array (“PLA”) to determine a correct micro-instruction pointer for reading microcode sequences to complete one or more instructions from microcode ROM 3732. In at least one embodiment, after microcode ROM 3732 finishes sequencing micro-ops for an instruction, front end 3701 of machine may resume fetching micro-ops from trace cache 3730.

In at least one embodiment, out-of-order execution engine (“out of order engine”) 3703 may prepare instructions for execution. In at least one embodiment, out-of-order execution logic has a number of buffers to smooth out and re-order the flow of instructions to optimize performance as they go down a pipeline and get scheduled for execution. Out-of-order execution engine 3703 includes, without limitation, an allocator/register renamer 3740, a memory uop queue 3742, an integer/floating point uop queue 3744, a memory scheduler 3746, a fast scheduler 3702, a slow/general floating point scheduler (“slow/general FP scheduler”) 3704, and a simple floating point scheduler (“simple FP scheduler”) 3706. In at least one embodiment, fast schedule 3702, slow/general floating point scheduler 3704, and simple floating point scheduler 3706 are also collectively referred to herein as “uop schedulers 3702, 3704, 3706.” Allocator/register renamer 3740 allocates machine buffers and resources that each uop needs in order to execute. In at least one embodiment, allocator/register renamer 3740 renames logic registers onto entries in a register file. In at least one embodiment, allocator/register renamer 3740 also allocates an entry for each uop in one of two uop queues, memory uop queue 3742 for memory operations and integer/floating point uop queue 3744 for non-memory operations, in front of memory scheduler 3746 and uop schedulers 3702, 3704, 3706. In at least one embodiment, uop schedulers 3702, 3704, 3706, determine when a uop is ready to execute based on readiness of their dependent input register operand sources and availability of execution resources uops need to complete their operation. In at least one embodiment, fast scheduler 3702 of at least one embodiment may schedule on each half of main clock cycle while slow/general floating point scheduler 3704 and simple floating point scheduler 3706 may schedule once per main processor clock cycle. In at least one embodiment, uop schedulers 3702, 3704, 3706 arbitrate for dispatch ports to schedule uops for execution.

In at least one embodiment, execution block 3711 includes, without limitation, an integer register file/bypass network 3708, a floating point register file/bypass network (“FP register file/bypass network”) 3710, address generation units (“AGUs”) 3712 and 3714, fast ALUs 3716 and 3718, a slow ALU 3720, a floating point ALU (“FP”) 3722, and a floating point move unit (“FP move”) 3724. In at least one embodiment, integer register file/bypass network 3708 and floating point register file/bypass network 3710 are also referred to herein as “register files 3708, 3710.” In at least one embodiment, AGUSs 3712 and 3714, fast ALUs 3716 and 3718, slow ALU 3720, floating point ALU 3722, and floating point move unit 3724 are also referred to herein as “execution units 3712, 3714, 3716, 3718, 3720, 3722, and 3724.” In at least one embodiment, an execution block may include, without limitation, any number (including zero) and type of register files, bypass networks, address generation units, and execution units, in any combination.

In at least one embodiment, register files 3708, 3710 may be arranged between uop schedulers 3702, 3704, 3706, and execution units 3712, 3714, 3716, 3718, 3720, 3722, and 3724. In at least one embodiment, integer register file/bypass network 3708 performs integer operations. In at least one embodiment, floating point register file/bypass network 3710 performs floating point operations. In at least one embodiment, each of register files 3708, 3710 may include, without limitation, a bypass network that may bypass or forward just completed results that have not yet been written into register file to new dependent uops. In at least one embodiment, register files 3708, 3710 may communicate data with each other. In at least one embodiment, integer register file/bypass network 3708 may include, without limitation, two separate register files, one register file for low-order thirty-two bits of data and a second register file for high order thirty-two bits of data. In at least one embodiment, floating point register file/bypass network 3710 may include, without limitation, 128-bit wide entries because floating point instructions typically have operands from 64 to 128 bits in width.

In at least one embodiment, execution units 3712, 3714, 3716, 3718, 3720, 3722, 3724 may execute instructions. In at least one embodiment, register files 3708, 3710 store integer and floating point data operand values that micro-instructions need to execute. In at least one embodiment, processor 3700 may include, without limitation, any number and combination of execution units 3712, 3714, 3716, 3718, 3720, 3722, 3724. In at least one embodiment, floating point ALU 3722 and floating point move unit 3724 may execute floating point, MMX, SIMD, AVX and SSE, or other operations. In at least one embodiment, floating point ALU 3722 may include, without limitation, a 64-bit by 64-bit floating point divider to execute divide, square root, and remainder micro ops. In at least one embodiment, instructions involving a floating point value may be handled with floating point hardware. In at least one embodiment, ALU operations may be passed to fast ALUs 3716, 3718. In at least one embodiment, fast ALUS 3716, 3718 may execute fast operations with an effective latency of half a clock cycle. In at least one embodiment, most complex integer operations go to slow ALU 3720 as slow ALU 3720 may include, without limitation, integer execution hardware for long-latency type of operations, such as a multiplier, shifts, flag logic, and branch processing. In at least one embodiment, memory load/store operations may be executed by AGUs 3712, 3714. In at least one embodiment, fast ALU 3716, fast ALU 3718, and slow ALU 3720 may perform integer operations on 64-bit data operands. In at least one embodiment, fast ALU 3716, fast ALU 3718, and slow ALU 3720 may be implemented to support a variety of data bit sizes including sixteen, thirty-two, 128, 256, etc. In at least one embodiment, floating point ALU 3722 and floating point move unit 3724 may be implemented to support a range of operands having bits of various widths. In at least one embodiment, floating point ALU 3722 and floating point move unit 3724 may operate on 128-bit wide packed data operands in conjunction with SIMD and multimedia instructions.

In at least one embodiment, uop schedulers 3702, 3704, 3706 dispatch dependent operations before parent load has finished executing. In at least one embodiment, as uops may be speculatively scheduled and executed in processor 3700, processor 3700 may also include logic to handle memory misses. In at least one embodiment, if a data load misses in a data cache, there may be dependent operations in flight in pipeline that have left a scheduler with temporarily incorrect data. In at least one embodiment, a replay mechanism tracks and re-executes instructions that use incorrect data. In at least one embodiment, dependent operations might need to be replayed and independent ones may be allowed to complete. In at least one embodiment, schedulers and replay mechanisms of at least one embodiment of a processor may also be designed to catch instruction sequences for text string comparison operations.

In at least one embodiment, the term “registers” may refer to on-board processor storage locations that may be used as part of instructions to identify operands. In at least one embodiment, registers may be those that may be usable from outside of a processor (from a programmer's perspective). In at least one embodiment, registers might not be limited to a particular type of circuit. Rather, in at least one embodiment, a register may store data, provide data, and perform functions described herein. In at least one embodiment, registers described herein may be implemented by circuitry within a processor using any number of different techniques, such as dedicated physical registers, dynamically allocated physical registers using register renaming, combinations of dedicated and dynamically allocated physical registers, etc. In at least one embodiment, integer registers store 32-bit integer data. A register file of at least one embodiment also contains eight multimedia SIMD registers for packed data.

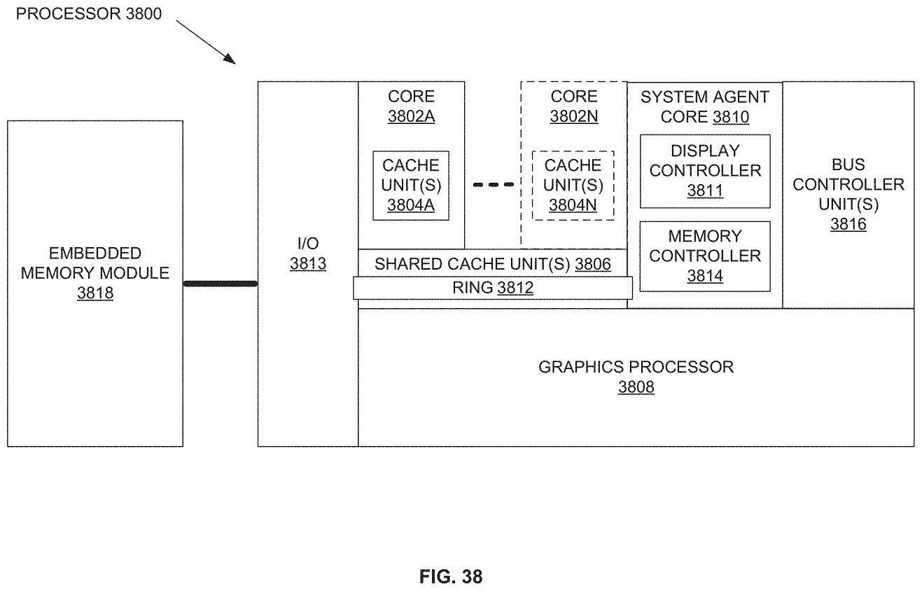

FIG. 38 illustrates a processor 3800, in accordance with at least one embodiment. In at least one embodiment, processor 3800 includes, without limitation, one or more processor cores (“cores”) 3802A-3802N, an integrated memory controller 3814, and an integrated graphics processor 3808. In at least one embodiment, processor 3800 can include additional cores up to and including additional processor core 3802N represented by dashed lined boxes. In at least one embodiment, each of processor cores 3802A-3802N includes one or more internal cache units 3804A-3804N. In at least one embodiment, each processor core also has access to one or more shared cached units 3806. In at least one embodiment, processor 3800 performs one or more steps to perform operations discussed herein, such as decompressing or otherwise performing operations involving decoding of variable-length coded data in parallel.

In at least one embodiment, internal cache units 3804A-3804N and shared cache units 3806 represent a cache memory hierarchy within processor 3800. In at least one embodiment, cache memory units 3804A-3804N may include at least one level of instruction and data cache within each processor core and one or more levels of shared mid-level cache, such as an L2, L3, Level 4 (“L4”), or other levels of cache, where a highest level of cache before external memory is classified as an LLC. In at least one embodiment, cache coherency logic maintains coherency between various cache units 3806 and 3804A-3804N.

In at least one embodiment, processor 3800 may also include a set of one or more bus controller units 3816 and a system agent core 3810. In at least one embodiment, one or more bus controller units 3816 manage a set of peripheral buses, such as one or more PCI or PCI express buses. In at least one embodiment, system agent core 3810 provides management functionality for various processor components. In at least one embodiment, system agent core 3810 includes one or more integrated memory controllers 3814 to manage access to various external memory devices (not shown).

In at least one embodiment, one or more of processor cores 3802A-3802N include support for simultaneous multi-threading. In at least one embodiment, system agent core 3810 includes components for coordinating and operating processor cores 3802A-3802N during multi-threaded processing. In at least one embodiment, system agent core 3810 may additionally include a power control unit (“PCU”), which includes logic and components to regulate one or more power states of processor cores 3802A-3802N and graphics processor 3808.

In at least one embodiment, processor 3800 additionally includes graphics processor 3808 to execute graphics processing operations. In at least one embodiment, graphics processor 3808 couples with shared cache units 3806, and system agent core 3810, including one or more integrated memory controllers 3814. In at least one embodiment, system agent core 3810 also includes a display controller 3811 to drive graphics processor output to one or more coupled displays. In at least one embodiment, display controller 3811 may also be a separate module coupled with graphics processor 3808 via at least one interconnect, or may be integrated within graphics processor 3808.

In at least one embodiment, a ring based interconnect unit 3812 is used to couple internal components of processor 3800. In at least one embodiment, an alternative interconnect unit may be used, such as a point-to-point interconnect, a switched interconnect, or other techniques. In at least one embodiment, graphics processor 3808 couples with ring interconnect 3812 via an I/O link 3813.

In at least one embodiment, I/O link 3813 represents at least one of multiple varieties of I/O interconnects, including an on package I/O interconnect which facilitates communication between various processor components and a high-performance embedded memory module 3818, such as an eDRAM module. In at least one embodiment, each of processor cores 3802A-3802N and graphics processor 3808 use embedded memory modules 3818 as a shared LLC.

In at least one embodiment, processor cores 3802A-3802N are homogeneous cores executing a common instruction set architecture. In at least one embodiment, processor cores 3802A-3802N are heterogeneous in terms of ISA, where one or more of processor cores 3802A-3802N execute a common instruction set, while one or more other cores of processor cores 3802A-38-02N executes a subset of a common instruction set or a different instruction set. In at least one embodiment, processor cores 3802A-3802N are heterogeneous in terms of microarchitecture, where one or more cores having a relatively higher power consumption couple with one or more cores having a lower power consumption. In at least one embodiment, processor 3800 can be implemented on one or more chips or as an SoC integrated circuit.

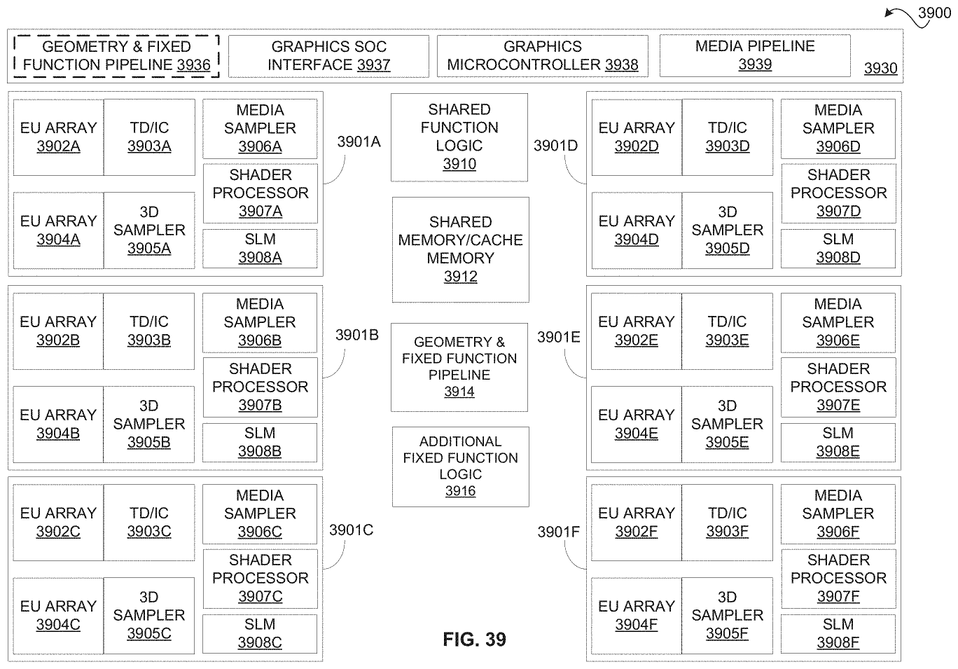

FIG. 39 illustrates a graphics processor core 3900, in accordance with at least one embodiment described. In at least one embodiment, graphics processor core 3900 is included within a graphics core array. In at least one embodiment, graphics processor core 3900, sometimes referred to as a core slice, can be one or multiple graphics cores within a modular graphics processor. In at least one embodiment, graphics processor core 3900 is exemplary of one graphics core slice, and a graphics processor as described herein may include multiple graphics core slices based on target power and performance envelopes. In at least one embodiment, each graphics core 3900 can include a fixed function block 3930 coupled with multiple sub-cores 3901A-3901F, also referred to as sub-slices, that include modular blocks of general-purpose and fixed function logic. In at least one embodiment, graphics processor core 3900 performs one or more steps to perform operations discussed herein, such as decompressing or otherwise performing operations involving decoding of variable-length coded data in parallel.

In at least one embodiment, fixed function block 3930 includes a geometry/fixed function pipeline 3936 that can be shared by all sub-cores in graphics processor 3900, for example, in lower performance and/or lower power graphics processor implementations. In at least one embodiment, geometry/fixed function pipeline 3936 includes a 3D fixed function pipeline, a video front-end unit, a thread spawner and thread dispatcher, and a unified return buffer manager, which manages unified return buffers.

In at least one embodiment, fixed function block 3930 also includes a graphics SoC interface 3937, a graphics microcontroller 3938, and a media pipeline 3939. Graphics SoC interface 3937 provides an interface between graphics core 3900 and other processor cores within an SoC integrated circuit. In at least one embodiment, graphics microcontroller 3938 is a programmable sub-processor that is configurable to manage various functions of graphics processor 3900, including thread dispatch, scheduling, and pre-emption. In at least one embodiment, media pipeline 3939 includes logic to facilitate decoding, encoding, pre-processing, and/or post-processing of multimedia data, including image and video data. In at least one embodiment, media pipeline 3939 implements media operations via requests to compute or sampling logic within sub-cores 3901-3901F.

In at least one embodiment, SoC interface 3937 enables graphics core 3900 to communicate with general-purpose application processor cores (e.g., CPUs) and/or other components within an SoC, including memory hierarchy elements such as a shared LLC memory, system RAM, and/or embedded on-chip or on-package DRAM. In at least one embodiment, SoC interface 3937 can also enable communication with fixed function devices within an SoC, such as camera imaging pipelines, and enables use of and/or implements global memory atomics that may be shared between graphics core 3900 and CPUs within an SoC. In at least one embodiment, SoC interface 3937 can also implement power management controls for graphics core 3900 and enable an interface between a clock domain of graphic core 3900 and other clock domains within an SoC. In at least one embodiment, SoC interface 3937 enables receipt of command buffers from a command streamer and global thread dispatcher that are configured to provide commands and instructions to each of one or more graphics cores within a graphics processor. In at least one embodiment, commands and instructions can be dispatched to media pipeline 3939, when media operations are to be performed, or a geometry and fixed function pipeline (e.g., geometry and fixed function pipeline 3936, geometry and fixed function pipeline 3914) when graphics processing operations are to be performed.

In at least one embodiment, graphics microcontroller 3938 can be configured to perform various scheduling and management tasks for graphics core 3900. In at least one embodiment, graphics microcontroller 3938 can perform graphics and/or compute workload scheduling on various graphics parallel engines within execution unit (EU) arrays 3902A-3902F, 3904A-3904F within sub-cores 3901A-3901F. In at least one embodiment, host software executing on a CPU core of an SoC including graphics core 3900 can submit workloads one of multiple graphic processor doorbells, which invokes a scheduling operation on an appropriate graphics engine. In at least one embodiment, scheduling operations include determining which workload to run next, submitting a workload to a command streamer, pre-empting existing workloads running on an engine, monitoring progress of a workload, and notifying host software when a workload is complete. In at least one embodiment, graphics microcontroller 3938 can also facilitate low-power or idle states for graphics core 3900, providing graphics core 3900 with an ability to save and restore registers within graphics core 3900 across low-power state transitions independently from an operating system and/or graphics driver software on a system.

In at least one embodiment, graphics core 3900 may have greater than or fewer than illustrated sub-cores 3901A-3901F, up to N modular sub-cores. For each set of N sub-cores, in at least one embodiment, graphics core 3900 can also include shared function logic 3910, shared and/or cache memory 3912, a geometry/fixed function pipeline 3914, as well as additional fixed function logic 3916 to accelerate various graphics and compute processing operations. In at least one embodiment, shared function logic 3910 can include logic units (e.g., sampler, math, and/or inter-thread communication logic) that can be shared by each N sub-cores within graphics core 3900. Shared and/or cache memory 3912 can be an LLC for N sub-cores 3901A-3901F within graphics core 3900 and can also serve as shared memory that is accessible by multiple sub-cores. In at least one embodiment, geometry/fixed function pipeline 3914 can be included instead of geometry/fixed function pipeline 3936 within fixed function block 3930 and can include same or similar logic units.

In at least one embodiment, graphics core 3900 includes additional fixed function logic 3916 that can include various fixed function acceleration logic for use by graphics core 3900. In at least one embodiment, additional fixed function logic 3916 includes an additional geometry pipeline for use in position only shading. In position-only shading, at least two geometry pipelines exist, whereas in a full geometry pipeline within geometry/fixed function pipeline 3916, 3936, and a cull pipeline, which is an additional geometry pipeline which may be included within additional fixed function logic 3916. In at least one embodiment, cull pipeline is a trimmed down version of a full geometry pipeline. In at least one embodiment, a full pipeline and a cull pipeline can execute different instances of an application, each instance having a separate context. In at least one embodiment, position only shading can hide long cull runs of discarded triangles, enabling shading to be completed earlier in some instances. For example, in at least one embodiment, cull pipeline logic within additional fixed function logic 3916 can execute position shaders in parallel with a main application and generally generates critical results faster than a full pipeline, as a cull pipeline fetches and shades position attribute of vertices, without performing rasterization and rendering of pixels to a frame buffer. In at least one embodiment, a cull pipeline can use generated critical results to compute visibility information for all triangles without regard to whether those triangles are culled. In at least one embodiment, a full pipeline (which in this instance may be referred to as a replay pipeline) can consume visibility information to skip culled triangles to shade only visible triangles that are finally passed to a rasterization phase.

In at least one embodiment, additional fixed function logic 3916 can also include general purpose processing acceleration logic, such as fixed function matrix multiplication logic, for accelerating CUDA programs.

In at least one embodiment, each graphics sub-core 3901A-3901F includes a set of execution resources that may be used to perform graphics, media, and compute operations in response to requests by graphics pipeline, media pipeline, or shader programs. In at least one embodiment, graphics sub-cores 3901A-3901F include multiple EU arrays 3902A-3902F, 3904A-3904F, thread dispatch and inter-thread communication (“TD/IC”) logic 3903A-3903F, a 3D (e.g., texture) sampler 3905A-3905F, a media sampler 3906A-3906F, a shader processor 3907A-3907F, and shared local memory (“SLM”) 3908A-3908F. EU arrays 3902A-3902F, 3904A-3904F each include multiple execution units, which are GPGPUs capable of performing floating-point and integer/fixed-point logic operations in service of a graphics, media, or compute operation, including graphics, media, or compute shader programs. In at least one embodiment, TD/IC logic 3903A-3903F performs local thread dispatch and thread control operations for execution units within a sub-core and facilitate communication between threads executing on execution units of a sub-core. In at least one embodiment, 3D sampler 3905A-3905F can read texture or other 3D graphics related data into memory. In at least one embodiment, 3D sampler can read texture data differently based on a configured sample state and texture format associated with a given texture. In at least one embodiment, media sampler 3906A-3906F can perform similar read operations based on a type and format associated with media data. In at least one embodiment, each graphics sub-core 3901A-3901F can alternately include a unified 3D and media sampler. In at least one embodiment, threads executing on execution units within each of sub-cores 3901A-3901F can make use of shared local memory 3908A-3908F within each sub-core, to enable threads executing within a thread group to execute using a common pool of on-chip memory.

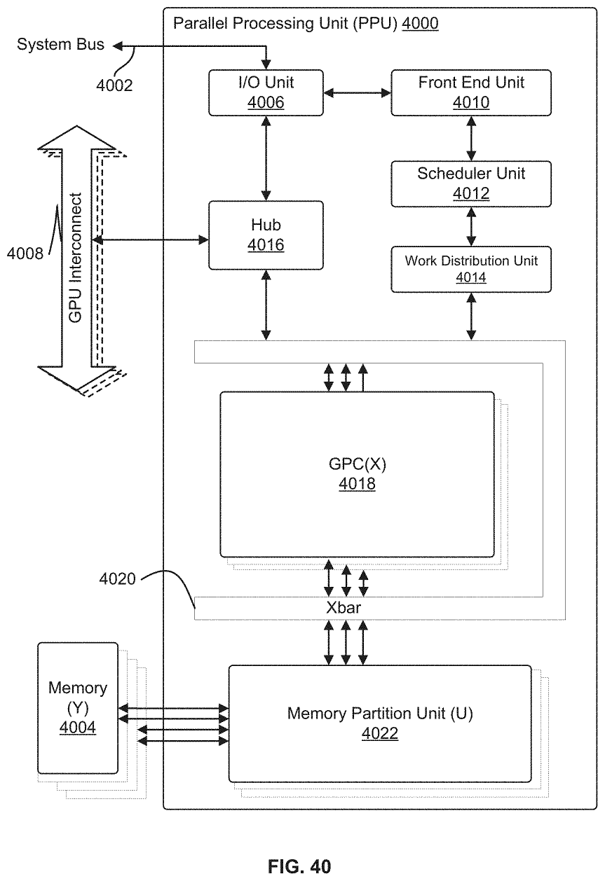

FIG. 40 illustrates a parallel processing unit (“PPU”) 4000, in accordance with at least one embodiment. In at least one embodiment, PPU 4000 is configured with machine-readable code that, if executed by PPU 4000, causes PPU 4000 to perform some or all of processes and techniques described herein. In at least one embodiment, PPU 4000 is a multi-threaded processor that is implemented on one or more integrated circuit devices and that utilizes multithreading as a latency-hiding technique designed to process computer-readable instructions (also referred to as machine-readable instructions or simply instructions) on multiple threads in parallel. In at least one embodiment, a thread refers to a thread of execution and is an instantiation of a set of instructions configured to be executed by PPU 4000. In at least one embodiment, PPU 4000 is a GPU configured to implement a graphics rendering pipeline for processing three-dimensional (“3D”) graphics data in order to generate two-dimensional (“2D”) image data for display on a display device such as an LCD device. In at least one embodiment, PPU 4000 is utilized to perform computations such as linear algebra operations and machine-learning operations. FIG. 40 illustrates an example parallel processor for illustrative purposes only and should be construed as a non-limiting example of a processor architecture that may be implemented in at least one embodiment. In at least one embodiment, PPU 4000 performs one or more steps to perform operations discussed herein, such as decompressing or otherwise performing operations involving decoding of variable-length coded data in parallel.

In at least one embodiment, one or more PPUs 4000 are configured to accelerate High Performance Computing (“HPC”), data center, and machine learning applications. In at least one embodiment, one or more PPUs 4000 are configured to accelerate CUDA programs. In at least one embodiment, PPU 4000 includes, without limitation, an I/O unit 4006, a front-end unit 4010, a scheduler unit 4012, a work distribution unit 4014, a hub 4016, a crossbar (“Xbar”) 4020, one or more general processing clusters (“GPCs”) 4018, and one or more partition units (“memory partition units”) 4022. In at least one embodiment, PPU 4000 is connected to a host processor or other PPUs 4000 via one or more high-speed GPU interconnects (“GPU interconnects”) 4008. In at least one embodiment, PPU 4000 is connected to a host processor or other peripheral devices via a system bus or interconnect 4002. In at least one embodiment, PPU 4000 is connected to a local memory comprising one or more memory devices (“memory”) 4004. In at least one embodiment, memory devices 4004 include, without limitation, one or more dynamic random access memory (DRAM) devices. In at least one embodiment, one or more DRAM devices are configured and/or configurable as high-bandwidth memory (“HBM”) subsystems, with multiple DRAM dies stacked within each device.

In at least one embodiment, high-speed GPU interconnect 4008 may refer to a wire-based multi-lane communications link that is used by systems to scale and include one or more PPUs 4000 combined with one or more CPUs, supports cache coherence between PPUs 4000 and CPUs, and CPU mastering. In at least one embodiment, data and/or commands are transmitted by high-speed GPU interconnect 4008 through hub 4016 to/from other units of PPU 4000 such as one or more copy engines, video encoders, video decoders, power management units, and other components which may not be explicitly illustrated in FIG. 40.

In at least one embodiment, I/O unit 4006 is configured to transmit and receive communications (e.g., commands, data) from a host processor (not illustrated in FIG. 40) over system bus 4002. In at least one embodiment, I/O unit 4006 communicates with host processor directly via system bus 4002 or through one or more intermediate devices such as a memory bridge. In at least one embodiment, I/O unit 4006 may communicate with one or more other processors, such as one or more of PPUs 4000 via system bus 4002. In at least one embodiment, I/O unit 4006 implements a PCIe interface for communications over a PCIe bus. In at least one embodiment, I/O unit 4006 implements interfaces for communicating with external devices.

In at least one embodiment, I/O unit 4006 decodes packets received via system bus 4002. In at least one embodiment, at least some packets represent commands configured to cause PPU 4000 to perform various operations. In at least one embodiment, I/O unit 4006 transmits decoded commands to various other units of PPU 4000 as specified by commands. In at least one embodiment, commands are transmitted to front-end unit 4010 and/or transmitted to hub 4016 or other units of PPU 4000 such as one or more copy engines, a video encoder, a video decoder, a power management unit, etc. (not explicitly illustrated in FIG. 40). In at least one embodiment, I/O unit 4006 is configured to route communications between and among various logical units of PPU 4000.

In at least one embodiment, a program executed by host processor encodes a command stream in a buffer that provides workloads to PPU 4000 for processing. In at least one embodiment, a workload comprises instructions and data to be processed by those instructions. In at least one embodiment, buffer is a region in a memory that is accessible (e.g., read/write) by both a host processor and PPU 4000 a host interface unit may be configured to access buffer in a system memory connected to system bus 4002 via memory requests transmitted over system bus 4002 by I/O unit 4006. In at least one embodiment, a host processor writes a command stream to a buffer and then transmits a pointer to the start of the command stream to PPU 4000 such that front-end unit 4010 receives pointers to one or more command streams and manages one or more command streams, reading commands from command streams and forwarding commands to various units of PPU 4000.

In at least one embodiment, front-end unit 4010 is coupled to scheduler unit 4012 that configures various GPCs 4018 to process tasks defined by one or more command streams. In at least one embodiment, scheduler unit 4012 is configured to track state information related to various tasks managed by scheduler unit 4012 where state information may indicate which of GPCs 4018 a task is assigned to, whether task is active or inactive, a priority level associated with task, and so forth. In at least one embodiment, scheduler unit 4012 manages execution of a plurality of tasks on one or more of GPCs 4018.

In at least one embodiment, scheduler unit 4012 is coupled to work distribution unit 4014 that is configured to dispatch tasks for execution on GPCs 4018. In at least one embodiment, work distribution unit 4014 tracks a number of scheduled tasks received from scheduler unit 4012 and work distribution unit 4014 manages a pending task pool and an active task pool for each of GPCs 4018. In at least one embodiment, pending task pool comprises a number of slots (e.g., 32 slots) that contain tasks assigned to be processed by a particular GPC 4018; active task pool may comprise a number of slots (e.g., 4 slots) for tasks that are actively being processed by GPCs 4018 such that as one of GPCs 4018 completes execution of a task, that task is evicted from active task pool for GPC 4018 and one of other tasks from pending task pool is selected and scheduled for execution on GPC 4018. In at least one embodiment, if an active task is idle on GPC 4018, such as while waiting for a data dependency to be resolved, then the active task is evicted from GPC 4018 and returned to a pending task pool while another task in the pending task pool is selected and scheduled for execution on GPC 4018.

In at least one embodiment, work distribution unit 4014 communicates with one or more GPCs 4018 via XBar 4020. In at least one embodiment, XBar 4020 is an interconnect network that couples many units of PPU 4000 to other units of PPU 4000 and can be configured to couple work distribution unit 4014 to a particular GPC 4018. In at least one embodiment, one or more other units of PPU 4000 may also be connected to XBar 4020 via hub 4016.

In at least one embodiment, tasks are managed by scheduler unit 4012 and dispatched to one of GPCs 4018 by work distribution unit 4014. GPC 4018 is configured to process task and generate results. In at least one embodiment, results may be consumed by other tasks within GPC 4018, routed to a different GPC 4018 via XBar 4020, or stored in memory 4004. In at least one embodiment, results can be written to memory 4004 via partition units 4022, which implement a memory interface for reading and writing data to/from memory 4004. In at least one embodiment, results can be transmitted to another PPU 4004 or CPU via high-speed GPU interconnect 4008. In at least one embodiment, PPU 4000 includes, without limitation, a number U of partition units 4022 that is equal to number of separate and distinct memory devices 4004 coupled to PPU 4000.

In at least one embodiment, a host processor executes a driver kernel that implements an application programming interface (“API”) that enables one or more applications executing on host processor to schedule operations for execution on PPU 4000. In at least one embodiment, multiple compute applications are simultaneously executed by PPU 4000 and PPU 4000 provides isolation, quality of service (“QoS”), and independent address spaces for multiple compute applications. In at least one embodiment, an application generates instructions (e.g., in the form of API calls) that cause a driver kernel to generate one or more tasks for execution by PPU 4000 and the driver kernel outputs tasks to one or more streams being processed by PPU 4000. In at least one embodiment, each task comprises one or more groups of related threads, which may be referred to as a warp. In at least one embodiment, a warp comprises a plurality of related threads (e.g., 32 threads) that can be executed in parallel. In at least one embodiment, cooperating threads can refer to a plurality of threads including instructions to perform a task and that exchange data through shared memory.

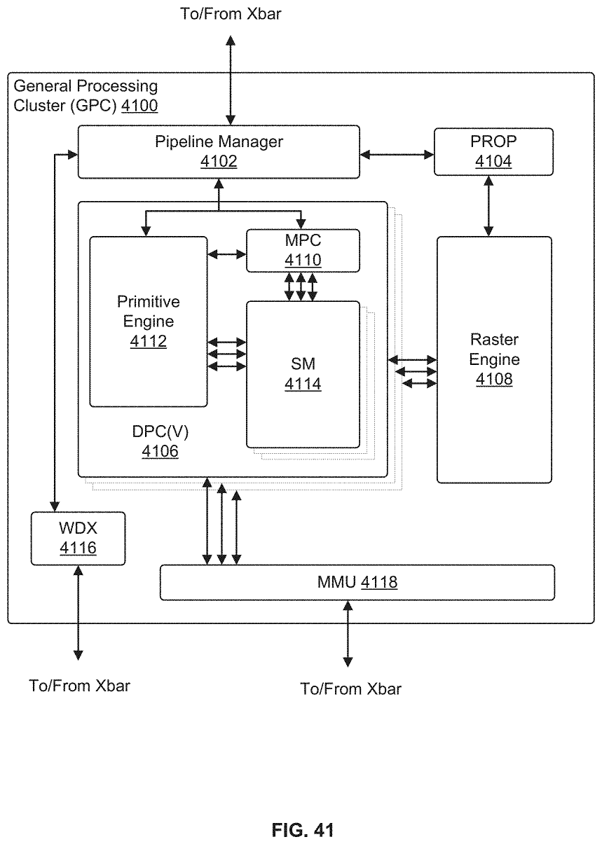

FIG. 41 illustrates a GPC 4100, in accordance with at least one embodiment. In at least one embodiment, GPC 4100 is GPC 4018 of FIG. 40. In at least one embodiment, each GPC 4100 includes, without limitation, a number of hardware units for processing tasks and each GPC 4100 includes, without limitation, a pipeline manager 4102, a pre-raster operations unit (“PROP”) 4104, a raster engine 4108, a work distribution crossbar (“WDX”) 4116, an MMU 4118, one or more Data Processing Clusters (“DPCs”) 4106, and any suitable combination of parts. In at least one embodiment, GPC 4100 performs one or more steps to perform operations discussed herein, such as decompressing or otherwise performing operations involving decoding of variable-length coded data in parallel.

In at least one embodiment, operation of GPC 4100 is controlled by pipeline manager 4102. In at least one embodiment, pipeline manager 4102 manages configuration of one or more DPCs 4106 for processing tasks allocated to GPC 4100. In at least one embodiment, pipeline manager 4102 configures at least one of one or more DPCs 4106 to implement at least a portion of a graphics rendering pipeline. In at least one embodiment, DPC 4106 is configured to execute a vertex shader program on a programmable streaming multiprocessor (“SM”) 4114. In at least one embodiment, pipeline manager 4102 is configured to route packets received from a work distribution unit to appropriate logical units within GPC 4100 and, in at least one embodiment, some packets may be routed to fixed function hardware units in PROP 4104 and/or raster engine 4108 while other packets may be routed to DPCs 4106 for processing by a primitive engine 4112 or SM 4114. In at least one embodiment, pipeline manager 4102 configures at least one of DPCs 4106 to implement a computing pipeline. In at least one embodiment, pipeline manager 4102 configures at least one of DPCs 4106 to execute at least a portion of a CUDA program.

In at least one embodiment, PROP unit 4104 is configured to route data generated by raster engine 4108 and DPCs 4106 to a Raster Operations (“ROP”) unit in a partition unit, such as memory partition unit 4022 described in more detail above in conjunction with FIG. 40. In at least one embodiment, PROP unit 4104 is configured to perform optimizations for color blending, organize pixel data, perform address translations, and more. In at least one embodiment, raster engine 4108 includes, without limitation, a number of fixed function hardware units configured to perform various raster operations and, in at least one embodiment, raster engine 4108 includes, without limitation, a setup engine, a coarse raster engine, a culling engine, a clipping engine, a fine raster engine, a tile coalescing engine, and any suitable combination thereof. In at least one embodiment, a setup engine receives transformed vertices and generates plane equations associated with geometric primitive defined by vertices; plane equations are transmitted to a coarse raster engine to generate coverage information (e.g., an x, y coverage mask for a tile) for a primitive; the output of the coarse raster engine is transmitted to a culling engine where fragments associated with a primitive that fail a z-test are culled, and transmitted to a clipping engine where fragments lying outside a viewing frustum are clipped. In at least one embodiment, fragments that survive clipping and culling are passed to a fine raster engine to generate attributes for pixel fragments based on plane equations generated by a setup engine. In at least one embodiment, the output of raster engine 4108 comprises fragments to be processed by any suitable entity such as by a fragment shader implemented within DPC 4106.

In at least one embodiment, each DPC 4106 included in GPC 4100 comprise, without limitation, an M-Pipe Controller (“MPC”) 4110; primitive engine 4112; one or more SMs 4114; and any suitable combination thereof. In at least one embodiment, MPC 4110 controls operation of DPC 4106, routing packets received from pipeline manager 4102 to appropriate units in DPC 4106. In at least one embodiment, packets associated with a vertex are routed to primitive engine 4112, which is configured to fetch vertex attributes associated with vertex from memory; in contrast, packets associated with a shader program may be transmitted to SM 4114.

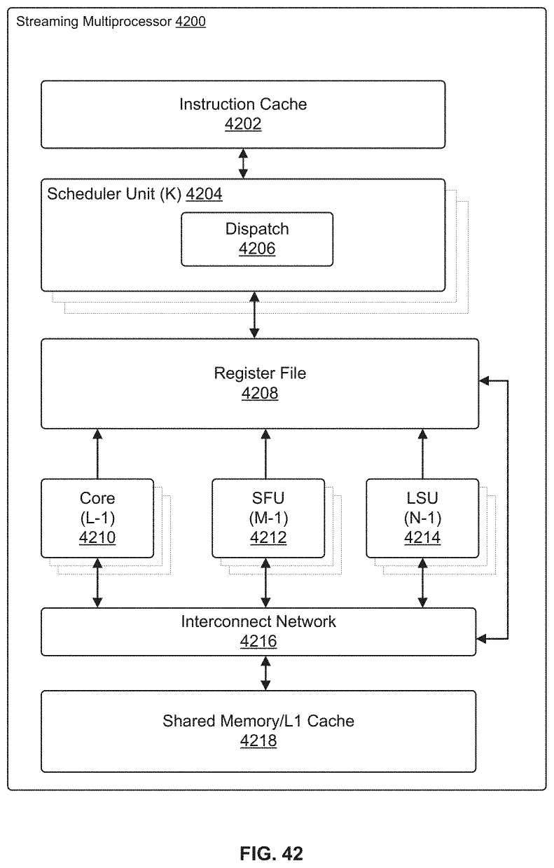

In at least one embodiment, SM 4114 comprises, without limitation, a programmable streaming processor that is configured to process tasks represented by a number of threads. In at least one embodiment, SM 4114 is multi-threaded and configured to execute a plurality of threads (e.g., 32 threads) from a particular group of threads concurrently and implements a SIMD architecture where each thread in a group of threads (e.g., a warp) is configured to process a different set of data based on same set of instructions. In at least one embodiment, all threads in group of threads execute same instructions. In at least one embodiment, SM 4114 implements a SIMT architecture wherein each thread in a group of threads is configured to process a different set of data based on same set of instructions, but where individual threads in group of threads are allowed to diverge during execution. In at least one embodiment, a program counter, a call stack, and an execution state is maintained for each warp, enabling concurrency between warps and serial execution within warps when threads within a warp diverge. In another embodiment, a program counter, a call stack, and an execution state is maintained for each individual thread, enabling equal concurrency between all threads, within and between warps. In at least one embodiment, an execution state is maintained for each individual thread and threads executing the same instructions may be converged and executed in parallel for better efficiency. At least one embodiment of SM 4114 is described in more detail in conjunction with FIG. 42.

In at least one embodiment, MMU 4118 provides an interface between GPC 4100 and a memory partition unit (e.g., partition unit 4022 of FIG. 40) and MMU 4118 provides translation of virtual addresses into physical addresses, memory protection, and arbitration of memory requests. In at least one embodiment, MMU 4118 provides one or more translation lookaside buffers (TLBs) for performing translation of virtual addresses into physical addresses in memory.

FIG. 42 illustrates a streaming multiprocessor (“SM”) 4200, in accordance with at least one embodiment. In at least one embodiment, SM 4200 is SM 4114 of FIG. 41. In at least one embodiment, SM 4200 includes, without limitation, an instruction cache 4202; one or more scheduler units 4204; a register file 4208; one or more processing cores (“cores”) 4210; one or more special function units (“SFUs”) 4212; one or more LSUs 4214; an interconnect network 4216; a shared memory/L1 cache 4218; and any suitable combination thereof. In at least one embodiment, a work distribution unit dispatches tasks for execution on GPCs of parallel processing units (PPUs) and each task is allocated to a particular Data Processing Cluster (DPC) within a GPC and, if a task is associated with a shader program, then the task is allocated to one of SMs 4200. In at least one embodiment, scheduler unit 4204 receives tasks from a work distribution unit and manages instruction scheduling for one or more thread blocks assigned to SM 4200. In at least one embodiment, scheduler unit 4204 schedules thread blocks for execution as warps of parallel threads, wherein each thread block is allocated at least one warp. In at least one embodiment, each warp executes threads. In at least one embodiment, scheduler unit 4204 manages a plurality of different thread blocks, allocating warps to different thread blocks and then dispatching instructions from a plurality of different cooperative groups to various functional units (e.g., processing cores 4210, SFUs 4212, and LSUs 4214) during each clock cycle. In at least one embodiment, SM 4200 performs one or more steps to perform operations discussed herein, such as decompressing or otherwise performing operations involving decoding of variable-length coded data in parallel.

In at least one embodiment, “cooperative groups” may refer to a programming model for organizing groups of communicating threads that allows developers to express granularity at which threads are communicating, enabling expression of richer, more efficient parallel decompositions. In at least one embodiment, cooperative launch APIs support synchronization amongst thread blocks for execution of parallel algorithms. In at least one embodiment, APIs of conventional programming models provide a single, simple construct for synchronizing cooperating threads: a barrier across all threads of a thread block (e.g., syncthreads( ) function). However, in at least one embodiment, programmers may define groups of threads at smaller than thread block granularities and synchronize within defined groups to enable greater performance, design flexibility, and software reuse in the form of collective group-wide function interfaces. In at least one embodiment, cooperative groups enable programmers to define groups of threads explicitly at sub-block and multi-block granularities, and to perform collective operations such as synchronization on threads in a cooperative group. In at least one embodiment, a sub-block granularity is as small as a single thread. In at least one embodiment, a programming model supports clean composition across software boundaries, so that libraries and utility functions can synchronize safely within their local context without having to make assumptions about convergence. In at least one embodiment, cooperative group primitives enable new patterns of cooperative parallelism, including, without limitation, producer-consumer parallelism, opportunistic parallelism, and global synchronization across an entire grid of thread blocks.

In at least one embodiment, a dispatch unit 4206 is configured to transmit instructions to one or more of functional units and scheduler unit 4204 includes, without limitation, two dispatch units 4206 that enable two different instructions from same warp to be dispatched during each clock cycle. In at least one embodiment, each scheduler unit 4204 includes a single dispatch unit 4206 or additional dispatch units 4206.

In at least one embodiment, each SM 4200, in at least one embodiment, includes, without limitation, register file 4208 that provides a set of registers for functional units of SM 4200. In at least one embodiment, register file 4208 is divided between each of the functional units such that each functional unit is allocated a dedicated portion of register file 4208. In at least one embodiment, register file 4208 is divided between different warps being executed by SM 4200 and register file 4208 provides temporary storage for operands connected to data paths of functional units. In at least one embodiment, each SM 4200 comprises, without limitation, a plurality of L processing cores 4210. In at least one embodiment, SM 4200 includes, without limitation, a large number (e.g., 128 or more) of distinct processing cores 4210. In at least one embodiment, each processing core 4210 includes, without limitation, a fully-pipelined, single-precision, double-precision, and/or mixed precision processing unit that includes, without limitation, a floating point arithmetic logic unit and an integer arithmetic logic unit. In at least one embodiment, floating point arithmetic logic units implement IEEE 754-2008 standard for floating point arithmetic. In at least one embodiment, processing cores 4210 include, without limitation, 64 single-precision (32-bit) floating point cores, 64 integer cores, 32 double-precision (64-bit) floating point cores, and 8 tensor cores.

In at least one embodiment, tensor cores are configured to perform matrix operations. In at least one embodiment, one or more tensor cores are included in processing cores 4210. In at least one embodiment, tensor cores are configured to perform deep learning matrix arithmetic, such as convolution operations for neural network training and inferencing. In at least one embodiment, each tensor core operates on a 4×4 matrix and performs a matrix multiply and accumulate operation D=A×B+C, where A, B, C, and D are 4×4 matrices.

In at least one embodiment, matrix multiply inputs A and B are 16-bit floating point matrices and accumulation matrices C and D are 16-bit floating point or 32-bit floating point matrices. In at least one embodiment, tensor cores operate on 16-bit floating point input data with 32-bit floating point accumulation. In at least one embodiment, 16-bit floating point multiply uses 64 operations and results in a full precision product that is then accumulated using 32-bit floating point addition with other intermediate products for a 4×4×4 matrix multiply. Tensor cores are used to perform much larger two-dimensional or higher dimensional matrix operations, built up from these smaller elements, in at least one embodiment. In at least one embodiment, an API, such as a CUDA-C++ API, exposes specialized matrix load, matrix multiply and accumulate, and matrix store operations to efficiently use tensor cores from a CUDA-C++ program. In at least one embodiment, at the CUDA level, a warp-level interface assumes 16×16 size matrices spanning all 32 threads of a warp.

In at least one embodiment, each SM 4200 comprises, without limitation, M SFUs 4212 that perform special functions (e.g., attribute evaluation, reciprocal square root, and like). In at least one embodiment, SFUs 4212 include, without limitation, a tree traversal unit configured to traverse a hierarchical tree data structure. In at least one embodiment, SFUs 4212 include, without limitation, a texture unit configured to perform texture map filtering operations. In at least one embodiment, texture units are configured to load texture maps (e.g., a 2D array of texels) from memory and sample texture maps to produce sampled texture values for use in shader programs executed by SM 4200. In at least one embodiment, texture maps are stored in shared memory/L1 cache 4218. In at least one embodiment, texture units implement texture operations such as filtering operations using mip-maps (e.g., texture maps of varying levels of detail). In at least one embodiment, each SM 4200 includes, without limitation, two texture units.

In at least one embodiment, each SM 4200 comprises, without limitation, N LSUs 4214 that implement load and store operations between shared memory/L1 cache 4218 and register file 4208. In at least one embodiment, each SM 4200 includes, without limitation, interconnect network 4216 that connects each of the functional units to register file 4208 and LSU 4214 to register file 4208 and shared memory/L1 cache 4218. In at least one embodiment, interconnect network 4216 is a crossbar that can be configured to connect any of the functional units to any of the registers in register file 4208 and connect LSUs 4214 to register file 4208 and memory locations in shared memory/L1 cache 4218.

In at least one embodiment, shared memory/L1 cache 4218 is an array of on-chip memory that allows for data storage and communication between SM 4200 and a primitive engine and between threads in SM 4200. In at least one embodiment, shared memory/L1 cache 4218 comprises, without limitation, 128 KB of storage capacity and is in a path from SM 4200 to a partition unit. In at least one embodiment, shared memory/L1 cache 4218 is used to cache reads and writes. In at least one embodiment, one or more of shared memory/L1 cache 4218, L2 cache, and memory are backing stores.

In at least one embodiment, combining data cache and shared memory functionality into a single memory block provides improved performance for both types of memory accesses. In at least one embodiment, capacity is used or is usable as a cache by programs that do not use shared memory, such as if shared memory is configured to use half of capacity, texture and load/store operations can use remaining capacity. In at least one embodiment, integration within shared memory/L1 cache 4218 enables shared memory/L1 cache 4218 to function as a high-throughput conduit for streaming data while simultaneously providing high-bandwidth and low-latency access to frequently reused data. In at least one embodiment, when configured for general purpose parallel computation, a simpler configuration can be used compared with graphics processing. In at least one embodiment, fixed function GPUs are bypassed, creating a much simpler programming model. In at least one embodiment and in a general purpose parallel computation configuration, a work distribution unit assigns and distributes blocks of threads directly to DPCs. In at least one embodiment, threads in a block execute the same program, using a unique thread ID in a calculation to ensure each thread generates unique results, using SM 4200 to execute a program and perform calculations, shared memory/L1 cache 4218 to communicate between threads, and LSU 4214 to read and write global memory through shared memory/L1 cache 4218 and a memory partition unit. In at least one embodiment, when configured for general purpose parallel computation, SM 4200 writes commands that scheduler unit 4204 can use to launch new work on DPCs.

In at least one embodiment, PPU is included in or coupled to a desktop computer, a laptop computer, a tablet computer, servers, supercomputers, a smart-phone (e.g., a wireless, hand-held device), a PDA, a digital camera, a vehicle, a head mounted display, a hand-held electronic device, and more. In at least one embodiment, PPU is embodied on a single semiconductor substrate. In at least one embodiment, PPU is included in an SoC along with one or more other devices such as additional PPUs, memory, a RISC CPU, an MMU, a digital-to-analog converter (“DAC”), and like.

In at least one embodiment, PPU may be included on a graphics card that includes one or more memory devices. In at least one embodiment, a graphics card may be configured to interface with a PCIe slot on a motherboard of a desktop computer. In at least one embodiment, PPU may be an integrated GPU (“iGPU”) included in chipset of motherboard.

### Software Constructions for General-Purpose Computing

The following figures set forth, without limitation, exemplary software constructs for implementing at least one embodiment.

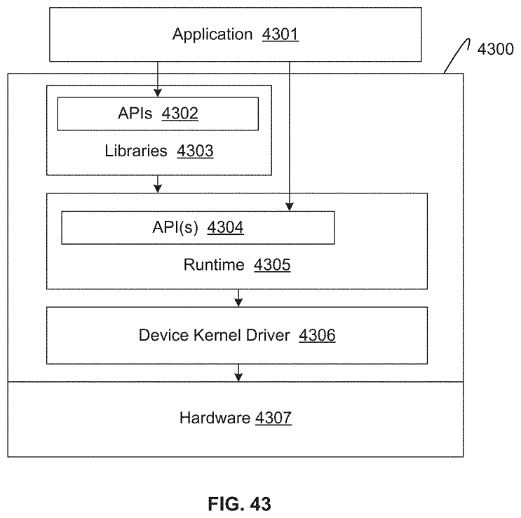

FIG. 43 illustrates a software stack of a programming platform, in accordance with at least one embodiment. In at least one embodiment, a programming platform is a platform for leveraging hardware on a computing system to accelerate computational tasks. A programming platform may be accessible to software developers through libraries, compiler directives, and/or extensions to programming languages, in at least one embodiment. In at least one embodiment, a programming platform may be, but is not limited to, CUDA, Radeon Open Compute Platform (“ROCm”), OpenCL (OpenCL™ is developed by Khronos group), SYCL, or Intel One API.

In at least one embodiment, a software stack 4300 of a programming platform provides an execution environment for an application 4301. In at least one embodiment, application 4301 may include any computer software capable of being launched on software stack 4300. In at least one embodiment, application 4301 may include, but is not limited to, an artificial intelligence (“AI”)/machine learning (“ML”) application, a high performance computing (“HPC”) application, a virtual desktop infrastructure (“VDI”), or a data center workload. In at least one embodiment, application 4301 performs one or more steps to perform operations discussed herein, such as decompressing or otherwise performing operations involving decoding of variable-length coded data in parallel.

In at least one embodiment, application 4301 and software stack 4300 run on hardware 4307. Hardware 4307 may include one or more GPUs, CPUs, FPGAs, AI engines, and/or other types of compute devices that support a programming platform, in at least one embodiment. In at least one embodiment, such as with CUDA, software stack 4300 may be vendor specific and compatible with only devices from particular vendor(s). In at least one embodiment, such as in with OpenCL, software stack 4300 may be used with devices from different vendors. In at least one embodiment, hardware 4307 includes a host connected to one more devices that can be accessed to perform computational tasks via application programming interface (“API”) calls. A device within hardware 4307 may include, but is not limited to, a GPU, FPGA, AI engine, or other compute device (but may also include a CPU) and its memory, as opposed to a host within hardware 4307 that may include, but is not limited to, a CPU (but may also include a compute device) and its memory, in at least one embodiment.

In at least one embodiment, software stack 4300 of a programming platform includes, without limitation, a number of libraries 4303, a runtime 4305, and a device kernel driver 4306. Each of libraries 4303 may include data and programming code that can be used by computer programs and leveraged during software development, in at least one embodiment. In at least one embodiment, libraries 4303 may include, but are not limited to, pre-written code and subroutines, classes, values, type specifications, configuration data, documentation, help data, and/or message templates. In at least one embodiment, libraries 4303 include functions that are optimized for execution on one or more types of devices. In at least one embodiment, libraries 4303 may include, but are not limited to, functions for performing mathematical, deep learning, and/or other types of operations on devices. In at least one embodiment, libraries 4303 are associated with corresponding APIs 4302, which may include one or more APIs, that expose functions implemented in libraries 4303.

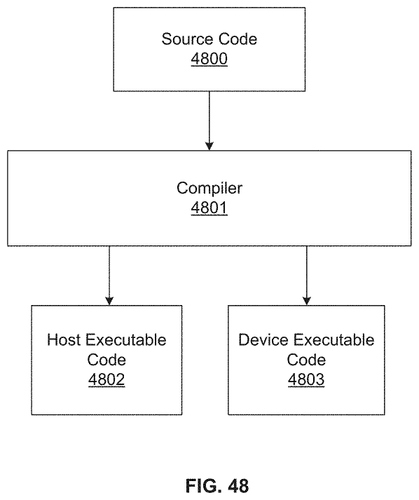

In at least one embodiment, application 4301 is written as source code that is compiled into executable code, as discussed in greater detail below in conjunction with FIGS. 48-50. Executable code of application 4301 may run, at least in part, on an execution environment provided by software stack 4300, in at least one embodiment. In at least one embodiment, during execution of application 4301, code may be reached that needs to run on a device, as opposed to a host. In such a case, runtime 4305 may be called to load and launch requisite code on the device, in at least one embodiment. In at least one embodiment, runtime 4305 may include any technically feasible runtime system that is able to support execution of application S01.

In at least one embodiment, runtime 4305 is implemented as one or more runtime libraries associated with corresponding APIs, which are shown as API(s) 4304. One or more of such runtime libraries may include, without limitation, functions for memory management, execution control, device management, error handling, and/or synchronization, among other things, in at least one embodiment. In at least one embodiment, memory management functions may include, but are not limited to, functions to allocate, deallocate, and copy device memory, as well as transfer data between host memory and device memory. In at least one embodiment, execution control functions may include, but are not limited to, functions to launch a function (sometimes referred to as a “kernel” when a function is a global function callable from a host) on a device and set attribute values in a buffer maintained by a runtime library for a given function to be executed on a device.

Runtime libraries and corresponding API(s) 4304 may be implemented in any technically feasible manner, in at least one embodiment. In at least one embodiment, one (or any number of) API may expose a low-level set of functions for fine-grained control of a device, while another (or any number of) API may expose a higher-level set of such functions. In at least one embodiment, a high-level runtime API may be built on top of a low-level API. In at least one embodiment, one or more of runtime APIs may be language-specific APIs that are layered on top of a language-independent runtime API.

In at least one embodiment, device kernel driver 4306 is configured to facilitate communication with an underlying device. In at least one embodiment, device kernel driver 4306 may provide low-level functionalities upon which APIs, such as API(s) 4304, and/or other software relies. In at least one embodiment, device kernel driver 4306 may be configured to compile intermediate representation (“IR”) code into binary code at runtime. For CUDA, device kernel driver 4306 may compile Parallel Thread Execution (“PTX”) IR code that is not hardware specific into binary code for a specific target device at runtime (with caching of compiled binary code), which is also sometimes referred to as “finalizing” code, in at least one embodiment. Doing so may permit finalized code to run on a target device, which may not have existed when source code was originally compiled into PTX code, in at least one embodiment. Alternatively, in at least one embodiment, device source code may be compiled into binary code offline, without requiring device kernel driver 4306 to compile IR code at runtime.

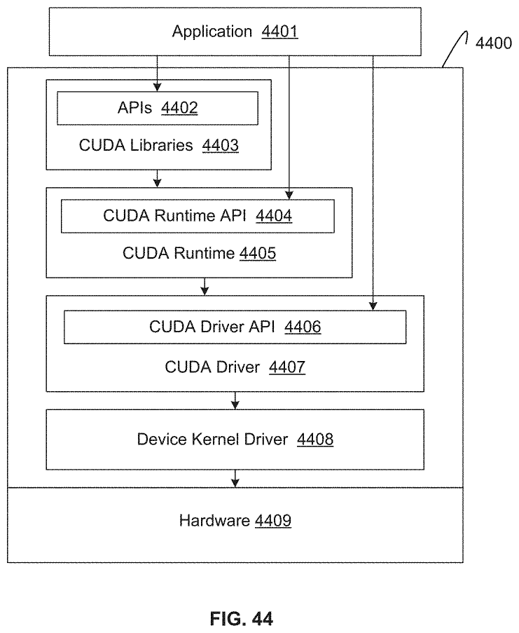

FIG. 44 illustrates a CUDA implementation of software stack 4300 of FIG. 43, in accordance with at least one embodiment. In at least one embodiment, a CUDA software stack 4400, on which an application 4401 may be launched, includes CUDA libraries 4403, a CUDA runtime 4405, a CUDA driver 4407, and a device kernel driver 4408. In at least one embodiment, CUDA software stack 4400 executes on hardware 4409, which may include a GPU that supports CUDA and is developed by NVIDIA Corporation of Santa Clara, Calif. In at least one embodiment, application 4401 performs one or more steps to perform operations discussed herein, such as decompressing or otherwise performing operations involving decoding of variable-length coded data in parallel.

In at least one embodiment, application 4401, CUDA runtime 4405, and device kernel driver 4408 may perform similar functionalities as application 4301, runtime 4305, and device kernel driver 4306, respectively, which are described above in conjunction with FIG. 43. In at least one embodiment, CUDA driver 4407 includes a library (libcuda.so) that implements a CUDA driver API 4406. Similar to a CUDA runtime API 4404 implemented by a CUDA runtime library (cudart), CUDA driver API 4406 may, without limitation, expose functions for memory management, execution control, device management, error handling, synchronization, and/or graphics interoperability, among other things, in at least one embodiment. In at least one embodiment, CUDA driver API 4406 differs from CUDA runtime API 4404 in that CUDA runtime API 4404 simplifies device code management by providing implicit initialization, context (analogous to a process) management, and module (analogous to dynamically loaded libraries) management. In contrast to high-level CUDA runtime API 4404, CUDA driver API 4406 is a low-level API providing more fine-grained control of the device, particularly with respect to contexts and module loading, in at least one embodiment. In at least one embodiment, CUDA driver API 4406 may expose functions for context management that are not exposed by CUDA runtime API 4404. In at least one embodiment, CUDA driver API 4406 is also language-independent and supports, e.g., OpenCL in addition to CUDA runtime API 4404. Further, in at least one embodiment, development libraries, including CUDA runtime 4405, may be considered as separate from driver components, including user-mode CUDA driver 4407 and kernel-mode device driver 4408 (also sometimes referred to as a “display” driver).

In at least one embodiment, CUDA libraries 4403 may include, but are not limited to, mathematical libraries, deep learning libraries, parallel algorithm libraries, and/or signal/image/video processing libraries, which parallel computing applications such as application 4401 may utilize. In at least one embodiment, CUDA libraries 4403 may include mathematical libraries such as a cuBLAS library that is an implementation of Basic Linear Algebra Subprograms (“BLAS”) for performing linear algebra operations, a cuFFT library for computing fast Fourier transforms (“FFTs”), and a cuRAND library for generating random numbers, among others. In at least one embodiment, CUDA libraries 4403 may include deep learning libraries such as a cuDNN library of primitives for deep neural networks and a TensorRT platform for high-performance deep learning inference, among others.

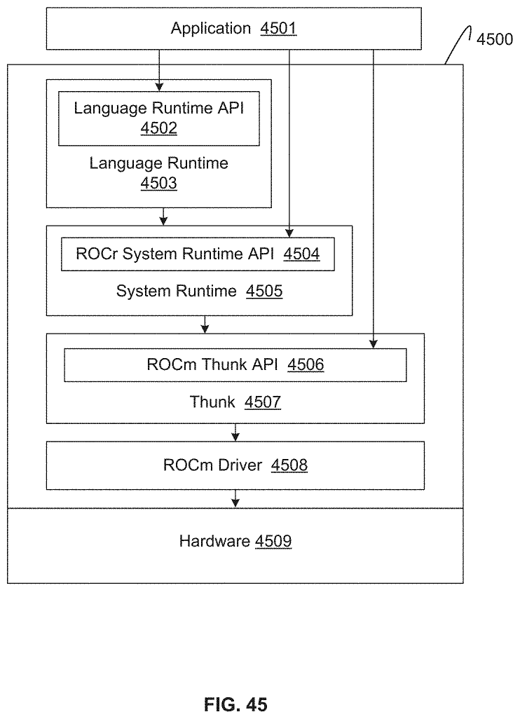

FIG. 45 illustrates a ROCm implementation of software stack 4300 of FIG. 43, in accordance with at least one embodiment. In at least one embodiment, a ROCm software stack 4500, on which an application 4501 may be launched, includes a language runtime 4503, a system runtime 4505, a thunk 4507, and a ROCm kernel driver 4508. In at least one embodiment, ROCm software stack 4500 executes on hardware 4509, which may include a GPU that supports ROCm and is developed by AMD Corporation of Santa Clara, Calif. In at least one embodiment, application 4501 performs one or more steps to perform operations discussed herein, such as decompressing or otherwise performing operations involving decoding of variable-length coded data in parallel.

In at least one embodiment, application 4501 may perform similar functionalities as application 4301 discussed above in conjunction with FIG. 43. In addition, language runtime 4503 and system runtime 4505 may perform similar functionalities as runtime 4305 discussed above in conjunction with FIG. 43, in at least one embodiment. In at least one embodiment, language runtime 4503 and system runtime 4505 differ in that system runtime 4505 is a language-independent runtime that implements a ROCr system runtime API 4504 and makes use of a Heterogeneous System Architecture (“HSA”) Runtime API. HSA runtime API is a thin, user-mode API that exposes interfaces to access and interact with an AMD GPU, including functions for memory management, execution control via architected dispatch of kernels, error handling, system and agent information, and runtime initialization and shutdown, among other things, in at least one embodiment. In contrast to system runtime 4505, language runtime 4503 is an implementation of a language-specific runtime API 4502 layered on top of ROCr system runtime API 4504, in at least one embodiment. In at least one embodiment, language runtime API may include, but is not limited to, a Heterogeneous compute Interface for Portability (“HIP”) language runtime API, a Heterogeneous Compute Compiler (“HCC”) language runtime API, or an OpenCL API, among others. HIP language in particular is an extension of C++ programming language with functionally similar versions of CUDA mechanisms, and, in at least one embodiment, a HIP language runtime API includes functions that are similar to those of CUDA runtime API 4404 discussed above in conjunction with FIG. 44, such as functions for memory management, execution control, device management, error handling, and synchronization, among other things.

In at least one embodiment, thunk (ROCt) 4507 is an interface 4506 that can be used to interact with underlying ROCm driver 4508. In at least one embodiment, ROCm driver 4508 is a ROCk driver, which is a combination of an AMDGPU driver and a HSA kernel driver (amdkfd). In at least one embodiment, AMDGPU driver is a device kernel driver for GPUs developed by AMD that performs similar functionalities as device kernel driver 4306 discussed above in conjunction with FIG. 43. In at least one embodiment, HSA kernel driver is a driver permitting different types of processors to share system resources more effectively via hardware features.

In at least one embodiment, various libraries (not shown) may be included in ROCm software stack 4500 above language runtime 4503 and provide functionality similarity to CUDA libraries 4403, discussed above in conjunction with FIG. 44. In at least one embodiment, various libraries may include, but are not limited to, mathematical, deep learning, and/or other libraries such as a hipBLAS library that implements functions similar to those of CUDA cuBLAS, a rocFFT library for computing FFTs that is similar to CUDA cuFFT, among others.

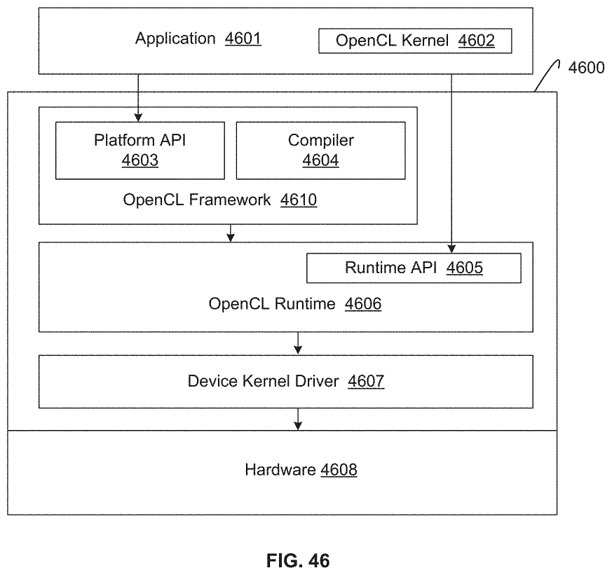

FIG. 46 illustrates an OpenCL implementation of software stack 4300 of FIG. 43, in accordance with at least one embodiment. In at least one embodiment, an OpenCL software stack 4600, on which an application 4601 may be launched, includes an OpenCL framework 4610, an OpenCL runtime 4606, and a driver 4607. In at least one embodiment, OpenCL software stack 4600 executes on hardware 4409 that is not vendor-specific. As OpenCL is supported by devices developed by different vendors, specific OpenCL drivers may be required to interoperate with hardware from such vendors, in at least one embodiment. In at least one embodiment, application 4601 performs one or more steps to perform operations discussed herein, such as decompressing or otherwise performing operations involving decoding of variable-length coded data in parallel.

In at least one embodiment, application 4601, OpenCL runtime 4606, device kernel driver 4607, and hardware 4608 may perform similar functionalities as application 4301, runtime 4305, device kernel driver 4306, and hardware 4307, respectively, that are discussed above in conjunction with FIG. 43. In at least one embodiment, application 4601 further includes an OpenCL kernel 4602 with code that is to be executed on a device.

In at least one embodiment, OpenCL defines a “platform” that allows a host to control devices connected to the host. In at least one embodiment, an OpenCL framework provides a platform layer API and a runtime API, shown as platform API 4603 and runtime API 4605. In at least one embodiment, runtime API 4605 uses contexts to manage execution of kernels on devices. In at least one embodiment, each identified device may be associated with a respective context, which runtime API 4605 may use to manage command queues, program objects, and kernel objects, share memory objects, among other things, for that device. In at least one embodiment, platform API 4603 exposes functions that permit device contexts to be used to select and initialize devices, submit work to devices via command queues, and enable data transfer to and from devices, among other things. In addition, OpenCL framework provides various built-in functions (not shown), including math functions, relational functions, and image processing functions, among others, in at least one embodiment.

In at least one embodiment, a compiler 4604 is also included in OpenCL frame-work 4610. Source code may be compiled offline prior to executing an application or online during execution of an application, in at least one embodiment. In contrast to CUDA and ROCm, OpenCL applications in at least one embodiment may be compiled online by compiler 4604, which is included to be representative of any number of compilers that may be used to compile source code and/or IR code, such as Standard Portable Intermediate Representation (“SPIR-V”) code, into binary code. Alternatively, in at least one embodiment, OpenCL applications may be compiled offline, prior to execution of such applications.

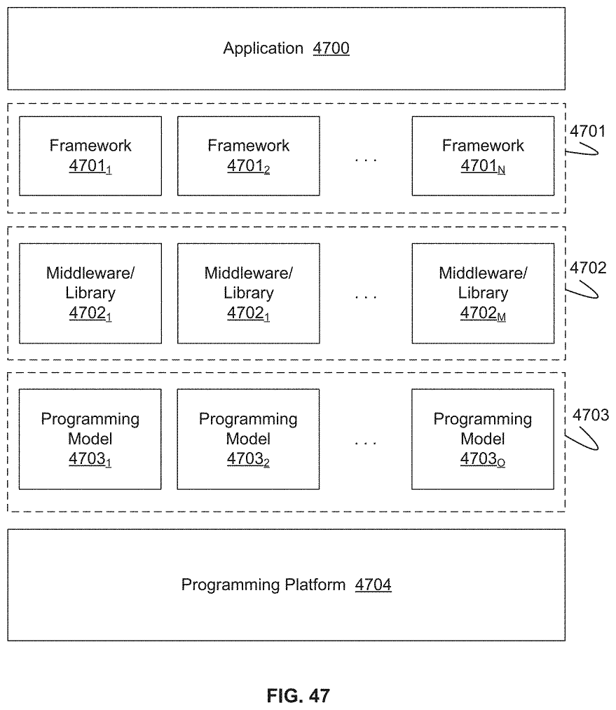

FIG. 47 illustrates software that is supported by a programming platform, in accordance with at least one embodiment. In at least one embodiment, a programming platform 4704 is configured to support various programming models 4703, middlewares and/or libraries 4702, and frameworks 4701 that an application 4700 may rely upon. In at least one embodiment, application 4700 may be an AI/ML application implemented using, for example, a deep learning framework such as MXNet, PyTorch, or TensorFlow, which may rely on libraries such as cuDNN, NVIDIA Collective Communications Library (“NCCL”), and/or NVIDA Developer Data Loading Library (“DALI”) CUDA libraries to provide accelerated computing on underlying hardware. In at least one embodiment, application 4700 performs one or more steps to perform operations discussed herein, such as decompressing or otherwise performing operations involving decoding of variable-length coded data in parallel.

In at least one embodiment, programming platform 4704 may be one of a CUDA, ROCm, or OpenCL platform described above in conjunction with FIG. 44, FIG. 45, and FIG. 46, respectively. In at least one embodiment, programming platform 4704 supports multiple programming models 4703, which are abstractions of an underlying computing system permitting expressions of algorithms and data structures. Programming models 4703 may expose features of underlying hardware in order to improve performance, in at least one embodiment. In at least one embodiment, programming models 4703 may include, but are not limited to, CUDA, HIP, OpenCL, C++ Accelerated Massive Parallelism (“C++ AMP”), Open Multi-Processing (“OpenMP”), Open Accelerators (“OpenACC”), and/or Vulcan Compute.

In at least one embodiment, libraries and/or middlewares 4702 provide implementations of abstractions of programming models 4704. In at least one embodiment, such libraries include data and programming code that may be used by computer programs and leveraged during software development. In at least one embodiment, such middlewares include software that provides services to applications beyond those available from programming platform 4704. In at least one embodiment, libraries and/or middlewares 4702 may include, but are not limited to, cuBLAS, cuFFT, cuRAND, and other CUDA libraries, or rocBLAS, rocFFT, rocRAND, and other ROCm libraries. In addition, in at least one embodiment, libraries and/or middlewares 4702 may include NCCL and ROCm Communication Collectives Library (“RCCL”) libraries providing communication routines for GPUs, a MIOpen library for deep learning acceleration, and/or an Eigen library for linear algebra, matrix and vector operations, geometrical transformations, numerical solvers, and related algorithms.

In at least one embodiment, application frameworks 4701 depend on libraries and/or middlewares 4702. In at least one embodiment, each of application frameworks 4701 is a software framework used to implement a standard structure of application software. Returning to the AI/ML example discussed above, an AI/ML application may be implemented using a framework such as Caffe, Caffe2, TensorFlow, Keras, PyTorch, or MxNet deep learning frameworks, in at least one embodiment.

FIG. 48 illustrates compiling code to execute on one of programming platforms of FIGS. 43-46, in accordance with at least one embodiment. In at least one embodiment, a compiler 4801 receives source code 4800 that includes both host code as well as device code. In at least one embodiment, complier 4801 is configured to convert source code 4800 into host executable code 4802 for execution on a host and device executable code 4803 for execution on a device. In at least one embodiment, source code 4800 may either be compiled offline prior to execution of an application, or online during execution of an application. In at least one embodiment, source code 4800 includes instructions to execute operations discussed herein, such as decompressing or otherwise performing operations involving decoding of variable-length coded data in parallel.

In at least one embodiment, source code 4800 may include code in any programming language supported by compiler 4801, such as C++, C, Fortran, etc. In at least one embodiment, source code 4800 may be included in a single-source file having a mixture of host code and device code, with locations of device code being indicated therein. In at least one embodiment, a single-source file may be a .cu file that includes CUDA code or a .hip.cpp file that includes HIP code. Alternatively, in at least one embodiment, source code 4800 may include multiple source code files, rather than a single-source file, into which host code and device code are separated.

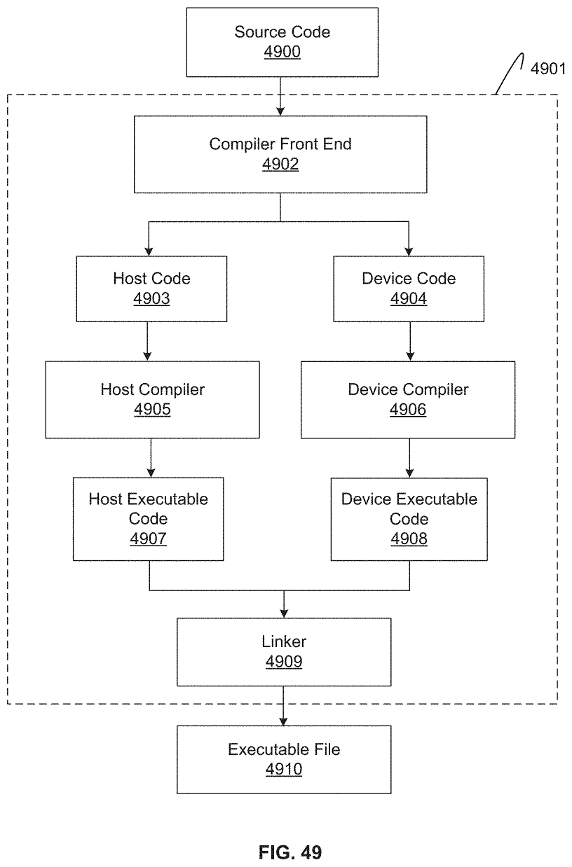

In at least one embodiment, compiler 4801 is configured to compile source code 4800 into host executable code 4802 for execution on a host and device executable code 4803 for execution on a device. In at least one embodiment, compiler 4801 performs operations including parsing source code 4800 into an abstract system tree (AST), performing optimizations, and generating executable code. In at least one embodiment in which source code 4800 includes a single-source file, compiler 4801 may separate device code from host code in such a single-source file, compile device code and host code into device executable code 4803 and host executable code 4802, respectively, and link device executable code 4803 and host executable code 4802 together in a single file, as discussed in greater detail below with respect to FIG. 49.

In at least one embodiment, host executable code 4802 and device executable code 4803 may be in any suitable format, such as binary code and/or IR code. In the case of CUDA, host executable code 4802 may include native object code and device executable code 4803 may include code in PTX intermediate representation, in at least one embodiment. In the case of ROCm, both host executable code 4802 and device executable code 4803 may include target binary code, in at least one embodiment.

FIG. 49 is a more detailed illustration of compiling code to execute on one of programming platforms of FIGS. 43-46, in accordance with at least one embodiment. In at least one embodiment, a compiler 4901 is configured to receive source code 4900, compile source code 4900, and output an executable file 4910. In at least one embodiment, source code 4900 is a single-source file, such as a .cu file, a .hip.cpp file, or a file in another format, that includes both host and device code. In at least one embodiment, compiler 4901 may be, but is not limited to, an NVIDIA CUDA compiler (“NVCC”) for compiling CUDA code in .cu files, or a HCC compiler for compiling HIP code in .hip.cpp files. In at least one embodiment, source code 4900 contains instructions for executing operations discussed herein, such as decompressing or otherwise performing operations involving decoding of variable-length coded data in parallel.

In at least one embodiment, compiler 4901 includes a compiler front end 4902, a host compiler 4905, a device compiler 4906, and a linker 4909. In at least one embodiment, compiler front end 4902 is configured to separate device code 4904 from host code 4903 in source code 4900. Device code 4904 is compiled by device compiler 4906 into device executable code 4908, which as described may include binary code or IR code, in at least one embodiment. Separately, host code 4903 is compiled by host compiler 4905 into host executable code 4907, in at least one embodiment. For NVCC, host compiler 4905 may be, but is not limited to, a general purpose C/C++ compiler that outputs native object code, while device compiler 4906 may be, but is not limited to, a Low Level Virtual Machine (“LLVM”)-based compiler that forks a LLVM compiler infrastructure and outputs PTX code or binary code, in at least one embodiment. For HCC, both host compiler 4905 and device compiler 4906 may be, but are not limited to, LLVM-based compilers that output target binary code, in at least one embodiment.

Subsequent to compiling source code 4900 into host executable code 4907 and device executable code 4908, linker 4909 links host and device executable code 4907 and 4908 together in executable file 4910, in at least one embodiment. In at least one embodiment, native object code for a host and PTX or binary code for a device may be linked together in an Executable and Linkable Format (“ELF”) file, which is a container format used to store object code.

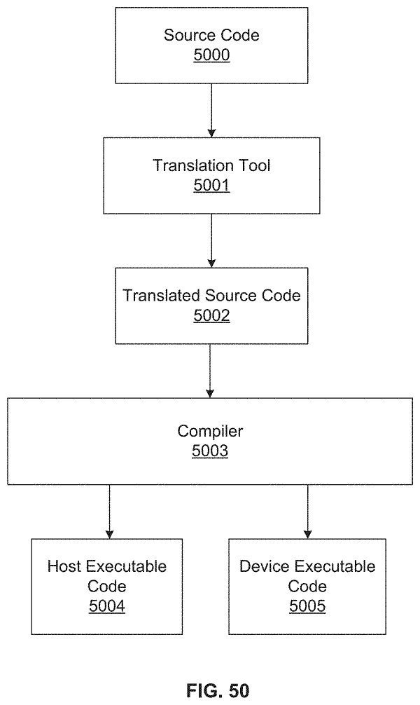

FIG. 50 illustrates translating source code prior to compiling source code, in accordance with at least one embodiment. In at least one embodiment, source code 5000 is passed through a translation tool 5001, which translates source code 5000 into translated source code 5002. In at least one embodiment, a compiler 5003 is used to compile translated source code 5002 into host executable code 5004 and device executable code 5005 in a process that is similar to compilation of source code 4800 by compiler 4801 into host executable code 4802 and device executable 4803, as discussed above in conjunction with FIG. 48. In at least one embodiment, source code 5000 includes instructions to execute operations discussed herein, such as decompressing or otherwise performing operations involving decoding of variable-length coded data in parallel.

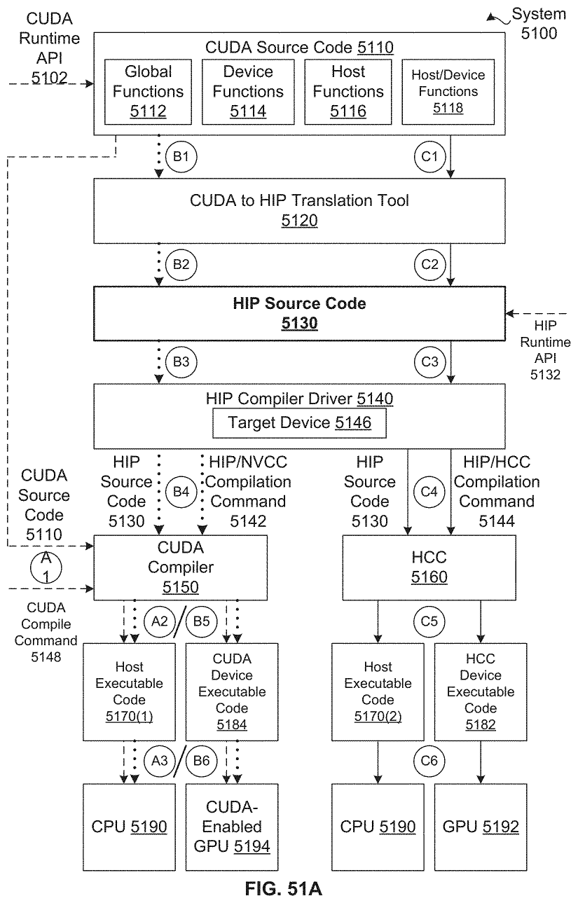

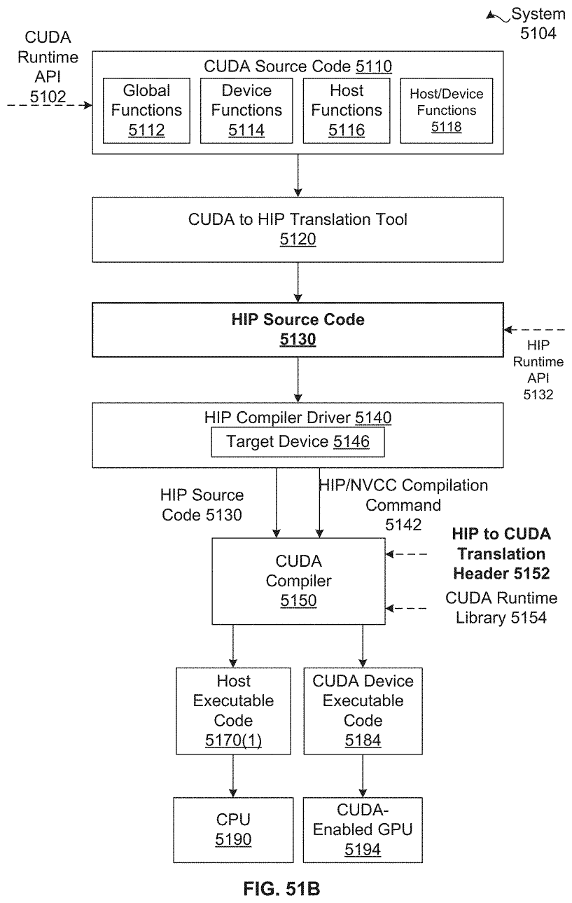

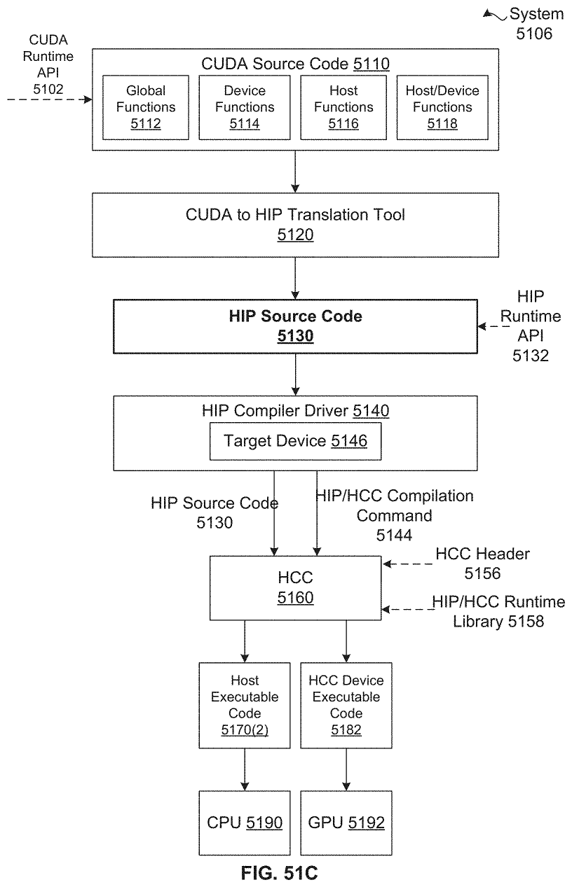

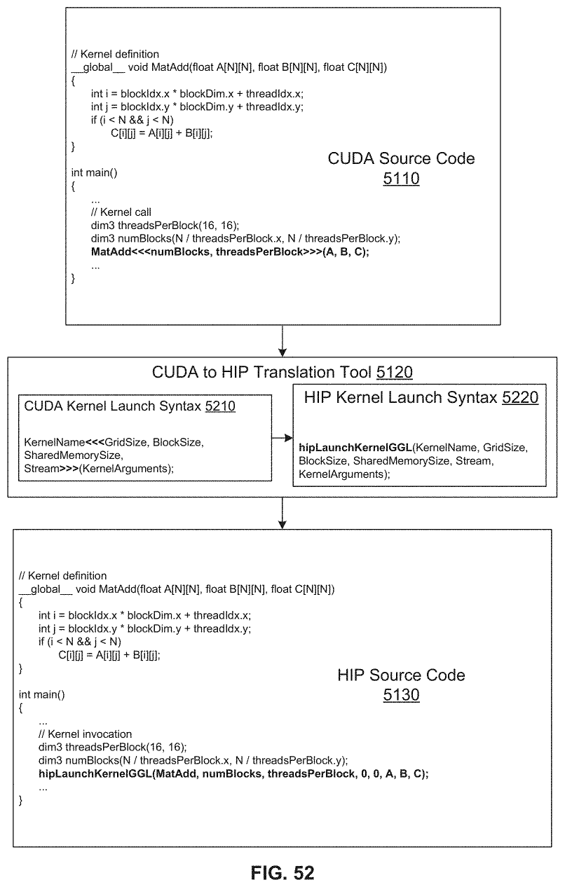

In at least one embodiment, a translation performed by translation tool 5001 is used to port source 5000 for execution in a different environment than that in which it was originally intended to run. In at least one embodiment, translation tool 5001 may include, but is not limited to, a HIP translator that is used to “hipify” CUDA code intended for a CUDA platform into HIP code that can be compiled and executed on a ROCm platform. In at least one embodiment, translation of source code 5000 may include parsing source code 5000 and converting calls to API(s) provided by one programming model (e.g., CUDA) into corresponding calls to API(s) provided by another programming model (e.g., HIP), as discussed in greater detail below in conjunction with FIGS. 51A-52. Returning to the example of hipifying CUDA code, calls to CUDA runtime API, CUDA driver API, and/or CUDA libraries may be converted to corresponding HIP API calls, in at least one embodiment. In at least one embodiment, automated translations performed by translation tool 5001 may sometimes be incomplete, requiring additional, manual effort to fully port source code 5000.

### Configuring GPUs for General-Purpose Computing

The following figures set forth, without limitation, exemplary architectures for compiling and executing compute source code, in accordance with at least one embodiment.

FIG. 51A illustrates a system 51A00 configured to compile and execute CUDA source code 5110 using different types of processing units, in accordance with at least one embodiment. In at least one embodiment, system 51A00 includes, without limitation, CUDA source code 5110, a CUDA compiler 5150, host executable code 5170(1), host executable code 5170(2), CUDA device executable code 5184, a CPU 5190, a CUDA-enabled GPU 5194, a GPU 5192, a CUDA to HIP translation tool 5120, HIP source code 5130, a HIP compiler driver 5140, an HCC 5160, and HCC device executable code 5182. In at least one embodiment, CUDA source code 5110 includes code to execute operations discussed herein, such as decompressing or otherwise performing operations involving decoding of variable-length coded data in parallel.

In at least one embodiment, CUDA source code 5110 is a collection of human-readable code in a CUDA programming language. In at least one embodiment, CUDA code is human-readable code in a CUDA programming language. In at least one embodiment, a CUDA programming language is an extension of the C++ programming language that includes, without limitation, mechanisms to define device code and distinguish between device code and host code. In at least one embodiment, device code is source code that, after compilation, is executable in parallel on a device. In at least one embodiment, a device may be a processor that is optimized for parallel instruction processing, such as CUDA-enabled GPU 5190, GPU 51192, or another GPGPU, etc. In at least one embodiment, host code is source code that, after compilation, is executable on a host. In at least one embodiment, a host is a processor that is optimized for sequential instruction processing, such as CPU 5190.

In at least one embodiment, CUDA source code 5110 includes, without limitation, any number (including zero) of global functions 5112, any number (including zero) of device functions 5114, any number (including zero) of host functions 5116, and any number (including zero) of host/device functions 5118. In at least one embodiment, global functions 5112, device functions 5114, host functions 5116, and host/device functions 5118 may be mixed in CUDA source code 5110. In at least one embodiment, each of global functions 5112 is executable on a device and callable from a host. In at least one embodiment, one or more of global functions 5112 may therefore act as entry points to a device. In at least one embodiment, each of global functions 5112 is a kernel. In at least one embodiment and in a technique known as dynamic parallelism, one or more of global functions 5112 defines a kernel that is executable on a device and callable from such a device. In at least one embodiment, a kernel is executed N (where N is any positive integer) times in parallel by N different threads on a device during execution.

In at least one embodiment, each of device functions 5114 is executed on a device and callable from such a device only. In at least one embodiment, each of host functions 5116 is executed on a host and callable from such a host only. In at least one embodiment, each of host/device functions 5116 defines both a host version of a function that is executable on a host and callable from such a host only and a device version of the function that is executable on a device and callable from such a device only.

In at least one embodiment, CUDA source code 5110 may also include, without limitation, any number of calls to any number of functions that are defined via a CUDA runtime API 5102. In at least one embodiment, CUDA runtime API 5102 may include, without limitation, any number of functions that execute on a host to allocate and deallocate device memory, transfer data between host memory and device memory, manage systems with multiple devices, etc. In at least one embodiment, CUDA source code 5110 may also include any number of calls to any number of functions that are specified in any number of other CUDA APIs. In at least one embodiment, a CUDA API may be any API that is designed for use by CUDA code. In at least one embodiment, CUDA APIs include, without limitation, CUDA runtime API 5102, a CUDA driver API, APIs for any number of CUDA libraries, etc. In at least one embodiment and relative to CUDA runtime API 5102, a CUDA driver API is a lower-level API but provides finer-grained control of a device. In at least one embodiment, examples of CUDA libraries include, without limitation, cuBLAS, cuFFT, cuRAND, cuDNN, etc.

In at least one embodiment, CUDA compiler 5150 compiles input CUDA code (e.g., CUDA source code 5110) to generate host executable code 5170(1) and CUDA device executable code 5184. In at least one embodiment, CUDA compiler 5150 is NVCC. In at least one embodiment, host executable code 5170(1) is a compiled version of host code included in input source code that is executable on CPU 5190. In at least one embodiment, CPU 5190 may be any processor that is optimized for sequential instruction processing.

In at least one embodiment, CUDA device executable code 5184 is a compiled version of device code included in input source code that is executable on CUDA-enabled GPU 5194. In at least one embodiment, CUDA device executable code 5184 includes, without limitation, binary code. In at least one embodiment, CUDA device executable code 5184 includes, without limitation, IR code, such as PTX code, that is further compiled at runtime into binary code for a specific target device (e.g., CUDA-enabled GPU 5194) by a device driver. In at least one embodiment, CUDA-enabled GPU 5194 may be any processor that is optimized for parallel instruction processing and that supports CUDA. In at least one embodiment, CUDA-enabled GPU 5194 is developed by NVIDIA Corporation of Santa Clara, Calif.

In at least one embodiment, CUDA to HIP translation tool 5120 is configured to translate CUDA source code 5110 to functionally similar HIP source code 5130. In a least one embodiment, HIP source code 5130 is a collection of human-readable code in a HIP programming language. In at least one embodiment, HIP code is human-readable code in a HIP programming language. In at least one embodiment, a HIP programming language is an extension of the C++ programming language that includes, without limitation, functionally similar versions of CUDA mechanisms to define device code and distinguish between device code and host code. In at least one embodiment, a HIP programming language may include a subset of functionality of a CUDA programming language. In at least one embodiment, for example, a HIP programming language includes, without limitation, mechanism(s) to define global functions 5112, but such a HIP programming language may lack support for dynamic parallelism and therefore global functions 5112 defined in HIP code may be callable from a host only.

In at least one embodiment, HIP source code 5130 includes, without limitation, any number (including zero) of global functions 5112, any number (including zero) of device functions 5114, any number (including zero) of host functions 5116, and any number (including zero) of host/device functions 5118. In at least one embodiment, HIP source code 5130 may also include any number of calls to any number of functions that are specified in a HIP runtime API 5132. In at least one embodiment, HIP runtime API 5132 includes, without limitation, functionally similar versions of a subset of functions included in CUDA runtime API 5102. In at least one embodiment, HIP source code 5130 may also include any number of calls to any number of functions that are specified in any number of other HIP APIs. In at least one embodiment, a HIP API may be any API that is designed for use by HIP code and/or ROCm. In at least one embodiment, HIP APIs include, without limitation, HIP runtime API 5132, a HIP driver API, APIs for any number of HIP libraries, APIs for any number of ROCm libraries, etc.

In at least one embodiment, CUDA to HIP translation tool 5120 converts each kernel call in CUDA code from a CUDA syntax to a HIP syntax and converts any number of other CUDA calls in CUDA code to any number of other functionally similar HIP calls. In at least one embodiment, a CUDA call is a call to a function specified in a CUDA API, and a HIP call is a call to a function specified in a HIP API. In at least one embodiment, CUDA to HIP translation tool 5120 converts any number of calls to functions specified in CUDA runtime API 5102 to any number of calls to functions specified in HIP runtime API 5132.

In at least one embodiment, CUDA to HIP translation tool 5120 is a tool known as hipify-perl that executes a text-based translation process. In at least one embodiment, CUDA to HIP translation tool 5120 is a tool known as hipify-clang that, relative to hipify-perl, executes a more complex and more robust translation process that involves parsing CUDA code using clang (a compiler front-end) and then translating resulting symbols. In at least one embodiment, properly converting CUDA code to HIP code may require modifications (e.g., manual edits) in addition to those performed by CUDA to HIP translation tool 5120.

In at least one embodiment, HIP compiler driver 5140 is a front end that determines a target device 5146 and then configures a compiler that is compatible with target device 5146 to compile HIP source code 5130. In at least one embodiment, target device 5146 is a processor that is optimized for parallel instruction processing. In at least one embodiment, HIP compiler driver 5140 may determine target device 5146 in any technically feasible fashion.

In at least one embodiment, if target device 5146 is compatible with CUDA (e.g., CUDA-enabled GPU 5194), then HIP compiler driver 5140 generates a HIP/NVCC compilation command 5142. In at least one embodiment and as described in greater detail in conjunction with FIG. 51B, HIP/NVCC compilation command 5142 configures CUDA compiler 5150 to compile HIP source code 5130 using, without limitation, a HIP to CUDA translation header and a CUDA runtime library. In at least one embodiment and in response to HIP/NVCC compilation command 5142, CUDA compiler 5150 generates host executable code 5170(1) and CUDA device executable code 5184.

In at least one embodiment, if target device 5146 is not compatible with CUDA, then HIP compiler driver 5140 generates a HIP/HCC compilation command 5144. In at least one embodiment and as described in greater detail in conjunction with FIG. 51C, HIP/HCC compilation command 5144 configures HCC 5160 to compile HIP source code 5130 using, without limitation, an HCC header and a HIP/HCC runtime library. In at least one embodiment and in response to HIP/HCC compilation command 5144, HCC 5160 generates host executable code 5170(2) and HCC device executable code 5182. In at least one embodiment, HCC device executable code 5182 is a compiled version of device code included in HIP source code 5130 that is executable on GPU 5192. In at least one embodiment, GPU 5192 may be any processor that is optimized for parallel instruction processing, is not compatible with CUDA, and is compatible with HCC. In at least one embodiment, GPU 5192 is developed by AMD Corporation of Santa Clara, Calif. In at least one embodiment GPU, 5192 is a non-CUDA-enabled GPU 5192.

For explanatory purposes only, three different flows that may be implemented in at least one embodiment to compile CUDA source code 5110 for execution on CPU 5190 and different devices are illustrated in FIG. 51A. In at least one embodiment, a direct CUDA flow compiles CUDA source code 5110 for execution on CPU 5190 and CUDA-enabled GPU 5194 without translating CUDA source code 5110 to HIP source code 5130. In at least one embodiment, an indirect CUDA flow translates CUDA source code 5110 to HIP source code 5130 and then compiles HIP source code 5130 for execution on CPU 5190 and CUDA-enabled GPU 5194. In at least one embodiment, a CUDA/HCC flow translates CUDA source code 5110 to HIP source code 5130 and then compiles HIP source code 5130 for execution on CPU 5190 and GPU 5192.

A direct CUDA flow that may be implemented in at least one embodiment is illustrated via dashed lines and a series of bubbles annotated A1-A3. In at least one embodiment and as illustrated with bubble annotated A1, CUDA compiler 5150 receives CUDA source code 5110 and a CUDA compile command 5148 that configures CUDA compiler 5150 to compile CUDA source code 5110. In at least one embodiment, CUDA source code 5110 used in a direct CUDA flow is written in a CUDA programming language that is based on a programming language other than C++ (e.g., C, Fortran, Python, Java, etc.). In at least one embodiment and in response to CUDA compile command 5148, CUDA compiler 5150 generates host executable code 5170(1) and CUDA device executable code 5184 (illustrated with bubble annotated A2). In at least one embodiment and as illustrated with bubble annotated A3, host executable code 5170(1) and CUDA device executable code 5184 may be executed on, respectively, CPU 5190 and CUDA-enabled GPU 5194. In at least one embodiment, CUDA device executable code 5184 includes, without limitation, binary code. In at least one embodiment, CUDA device executable code 5184 includes, without limitation, PTX code and is further compiled into binary code for a specific target device at runtime.

An indirect CUDA flow that may be implemented in at least one embodiment is illustrated via dotted lines and a series of bubbles annotated B1-B6. In at least one embodiment and as illustrated with bubble annotated B1, CUDA to HIP translation tool 5120 receives CUDA source code 5110. In at least one embodiment and as illustrated with bubble annotated B2, CUDA to HIP translation tool 5120 translates CUDA source code 5110 to HIP source code 5130. In at least one embodiment and as illustrated with bubble annotated B3, HIP compiler driver 5140 receives HIP source code 5130 and determines that target device 5146 is CUDA-enabled.

In at least one embodiment and as illustrated with bubble annotated B4, HIP compiler driver 5140 generates HIP/NVCC compilation command 5142 and transmits both HIP/NVCC compilation command 5142 and HIP source code 5130 to CUDA compiler 5150. In at least one embodiment and as described in greater detail in conjunction with FIG. 51B, HIP/NVCC compilation command 5142 configures CUDA compiler 5150 to compile HIP source code 5130 using, without limitation, a HIP to CUDA translation header and a CUDA runtime library. In at least one embodiment and in response to HIP/NVCC compilation command 5142, CUDA compiler 5150 generates host executable code 5170(1) and CUDA device executable code 5184 (illustrated with bubble annotated B5). In at least one embodiment and as illustrated with bubble annotated B6, host executable code 5170(1) and CUDA device executable code 5184 may be executed on, respectively, CPU 5190 and CUDA-enabled GPU 5194. In at least one embodiment, CUDA device executable code 5184 includes, without limitation, binary code. In at least one embodiment, CUDA device executable code 5184 includes, without limitation, PTX code and is further compiled into binary code for a specific target device at runtime.

A CUDA/HCC flow that may be implemented in at least one embodiment is illustrated via solid lines and a series of bubbles annotated C1-C6. In at least one embodiment and as illustrated with bubble annotated C1, CUDA to HIP translation tool 5120 receives CUDA source code 5110. In at least one embodiment and as illustrated with bubble annotated C2, CUDA to HIP translation tool 5120 translates CUDA source code 5110 to HIP source code 5130. In at least one embodiment and as illustrated with bubble annotated C3, HIP compiler driver 5140 receives HIP source code 5130 and determines that target device 5146 is not CUDA-enabled.

In at least one embodiment, HIP compiler driver 5140 generates HIP/HCC compilation command 5144 and transmits both HIP/HCC compilation command 5144 and HIP source code 5130 to HCC 5160 (illustrated with bubble annotated C4). In at least one embodiment and as described in greater detail in conjunction with FIG. 51C, HIP/HCC compilation command 5144 configures HCC 5160 to compile HIP source code 5130 using, without limitation, an HCC header and a HIP/HCC runtime library. In at least one embodiment and in response to HIP/HCC compilation command 5144, HCC 5160 generates host executable code 5170(2) and HCC device executable code 5182 (illustrated with bubble annotated C5). In at least one embodiment and as illustrated with bubble annotated C6, host executable code 5170(2) and HCC device executable code 5182 may be executed on, respectively, CPU 5190 and GPU 5192.

In at least one embodiment, after CUDA source code 5110 is translated to HIP source code 5130, HIP compiler driver 5140 may subsequently be used to generate executable code for either CUDA-enabled GPU 5194 or GPU 5192 without re-executing CUDA to HIP translation tool 5120. In at least one embodiment, CUDA to HIP translation tool 5120 translates CUDA source code 5110 to HIP source code 5130 that is then stored in memory. In at least one embodiment, HIP compiler driver 5140 then configures HCC 5160 to generate host executable code 5170(2) and HCC device executable code 5182 based on HIP source code 5130. In at least one embodiment, HIP compiler driver 5140 subsequently configures CUDA compiler 5150 to generate host executable code 5170(1) and CUDA device executable code 5184 based on stored HIP source code 5130.

FIG. 51B illustrates a system 5104 configured to compile and execute CUDA source code 5110 of FIG. 51A using CPU 5190 and CUDA-enabled GPU 5194, in accordance with at least one embodiment. In at least one embodiment, system 5104 includes, without limitation, CUDA source code 5110, CUDA to HIP translation tool 5120, HIP source code 5130, HIP compiler driver 5140, CUDA compiler 5150, host executable code 5170(1), CUDA device executable code 5184, CPU 5190, and CUDA-enabled GPU 5194.

In at least one embodiment and as described previously herein in conjunction with FIG. 51A, CUDA source code 5110 includes, without limitation, any number (including zero) of global functions 5112, any number (including zero) of device functions 5114, any number (including zero) of host functions 5116, and any number (including zero) of host/device functions 5118. In at least one embodiment, CUDA source code 5110 also includes, without limitation, any number of calls to any number of functions that are specified in any number of CUDA APIs. In at least one embodiment, CUDA source code 5110 include instructions to execute operations discussed herein, such as decompressing or otherwise performing operations involving decoding of variable-length coded data in parallel.

In at least one embodiment, CUDA to HIP translation tool 5120 translates CUDA source code 5110 to HIP source code 5130. In at least one embodiment, CUDA to HIP translation tool 5120 converts each kernel call in CUDA source code 5110 from a CUDA syntax to a HIP syntax and converts any number of other CUDA calls in CUDA source code 5110 to any number of other functionally similar HIP calls.

In at least one embodiment, HIP compiler driver 5140 determines that target device 5146 is CUDA-enabled and generates HIP/NVCC compilation command 5142. In at least one embodiment, HIP compiler driver 5140 then configures CUDA compiler 5150 via HIP/NVCC compilation command 5142 to compile HIP source code 5130. In at least one embodiment, HIP compiler driver 5140 provides access to a HIP to CUDA translation header 5152 as part of configuring CUDA compiler 5150. In at least one embodiment, HIP to CUDA translation header 5152 translates any number of mechanisms (e.g., functions) specified in any number of HIP APIs to any number of mechanisms specified in any number of CUDA APIs. In at least one embodiment, CUDA compiler 5150 uses HIP to CUDA translation header 5152 in conjunction with a CUDA runtime library 5154 corresponding to CUDA runtime API 5102 to generate host executable code 5170(1) and CUDA device executable code 5184. In at least one embodiment, host executable code 5170(1) and CUDA device executable code 5184 may then be executed on, respectively, CPU 5190 and CUDA-enabled GPU 5194. In at least one embodiment, CUDA device executable code 5184 includes, without limitation, binary code. In at least one embodiment, CUDA device executable code 5184 includes, without limitation, PTX code and is further compiled into binary code for a specific target device at runtime.

FIG. 51C illustrates a system 5106 configured to compile and execute CUDA source code 5110 of FIG. 51A using CPU 5190 and non-CUDA-enabled GPU 5192, in accordance with at least one embodiment. In at least one embodiment, system 5106 includes, without limitation, CUDA source code 5110, CUDA to HIP translation tool 5120, HIP source code 5130, HIP compiler driver 5140, HCC 5160, host executable code 5170(2), HCC device executable code 5182, CPU 5190, and GPU 5192. In at least one embodiment, CUDA source code 5110 include instructions to execute operations discussed herein, such as decompressing or otherwise performing operations involving decoding of variable-length coded data in parallel.

In at least one embodiment and as described previously herein in conjunction with FIG. 51A, CUDA source code 5110 includes, without limitation, any number (including zero) of global functions 5112, any number (including zero) of device functions 5114, any number (including zero) of host functions 5116, and any number (including zero) of host/device functions 5118. In at least one embodiment, CUDA source code 5110 also includes, without limitation, any number of calls to any number of functions that are specified in any number of CUDA APIs.

In at least one embodiment, CUDA to HIP translation tool 5120 translates CUDA source code 5110 to HIP source code 5130. In at least one embodiment, CUDA to HIP translation tool 5120 converts each kernel call in CUDA source code 5110 from a CUDA syntax to a HIP syntax and converts any number of other CUDA calls in source code 5110 to any number of other functionally similar HIP calls.

In at least one embodiment, HIP compiler driver 5140 subsequently determines that target device 5146 is not CUDA-enabled and generates HIP/HCC compilation command 5144. In at least one embodiment, HIP compiler driver 5140 then configures HCC 5160 to execute HIP/HCC compilation command 5144 to compile HIP source code 5130. In at least one embodiment, HIP/HCC compilation command 5144 configures HCC 5160 to use, without limitation, a HIP/HCC runtime library 5158 and an HCC header 5156 to generate host executable code 5170(2) and HCC device executable code 5182. In at least one embodiment, HIP/HCC runtime library 5158 corresponds to HIP runtime API 5132. In at least one embodiment, HCC header 5156 includes, without limitation, any number and type of interoperability mechanisms for HIP and HCC. In at least one embodiment, host executable code 5170(2) and HCC device executable code 5182 may be executed on, respectively, CPU 5190 and GPU 5192.

FIG. 52 illustrates an exemplary kernel translated by CUDA-to-HIP translation tool 5120 of FIG. 51C, in accordance with at least one embodiment. In at least one embodiment, CUDA source code 5110 partitions an overall problem that a given kernel is designed to solve into relatively coarse sub-problems that can independently be solved using thread blocks. In at least one embodiment, each thread block includes, without limitation, any number of threads. In at least one embodiment, each sub-problem is partitioned into relatively fine pieces that can be solved cooperatively in parallel by threads within a thread block. In at least one embodiment, threads within a thread block can cooperate by sharing data through shared memory and by synchronizing execution to coordinate memory accesses. In at least one embodiment, CUDA source code 5110 include instructions to execute operations discussed herein, such as decompressing or otherwise performing operations involving decoding of variable-length coded data in parallel.

In at least one embodiment, CUDA source code 5110 organizes thread blocks associated with a given kernel into a one-dimensional, a two-dimensional, or a three-dimensional grid of thread blocks. In at least one embodiment, each thread block includes, without limitation, any number of threads, and a grid includes, without limitation, any number of thread blocks.

In at least one embodiment, a kernel is a function in device code that is defined using a “global_” declaration specifier. In at least one embodiment, the dimension of a grid that executes a kernel for a given kernel call and associated streams are specified using a CUDA kernel launch syntax 5210. In at least one embodiment, CUDA kernel launch syntax 5210 is specified as “KernelName<<<GridSize, BlockSize, SharedMemorySize, Stream>>>(KernelArguments);”. In at least one embodiment, an execution configuration syntax is a “<<< . . . >>>” construct that is inserted between a kernel name (“KernelName”) and a parenthesized list of kernel arguments (“KernelArguments”). In at least one embodiment, CUDA kernel launch syntax 5210 includes, without limitation, a CUDA launch function syntax instead of an execution configuration syntax.

In at least one embodiment, “GridSize” is of a type dim3 and specifies the dimension and size of a grid. In at least one embodiment, type dim3 is a CUDA-defined structure that includes, without limitation, unsigned integers x, y, and z. In at least one embodiment, if z is not specified, then z defaults to one. In at least one embodiment, if y is not specified, then y defaults to one. In at least one embodiment, the number of thread blocks in a grid is equal to the product of GridSize.x, GridSize.y, and GridSize.z. In at least one embodiment, “BlockSize” is of type dim3 and specifies the dimension and size of each thread block. In at least one embodiment, the number of threads per thread block is equal to the product of BlockSize.x, BlockSize.y, and BlockSize.z. In at least one embodiment, each thread that executes a kernel is given a unique thread ID that is accessible within the kernel through a built-in variable (e.g., “threadIdx”).

In at least one embodiment and with respect to CUDA kernel launch syntax 5210, “SharedMemorySize” is an optional argument that specifies a number of bytes in a shared memory that is dynamically allocated per thread block for a given kernel call in addition to statically allocated memory. In at least one embodiment and with respect to CUDA kernel launch syntax 5210, SharedMemorySize defaults to zero. In at least one embodiment and with respect to CUDA kernel launch syntax 5210, “Stream” is an optional argument that specifies an associated stream and defaults to zero to specify a default stream. In at least one embodiment, a stream is a sequence of commands (possibly issued by different host threads) that execute in order. In at least one embodiment, different streams may execute commands out of order with respect to one another or concurrently.

In at least one embodiment, CUDA source code 5110 includes, without limitation, a kernel definition for an exemplary kernel “MatAdd” and a main function. In at least one embodiment, main function is host code that executes on a host and includes, without limitation, a kernel call that causes kernel MatAdd to execute on a device. In at least one embodiment and as shown, kernel MatAdd adds two matrices A and B of size N×N, where N is a positive integer, and stores the result in a matrix C. In at least one embodiment, main function defines a threadsPerBlock variable as 16 by 16 and a numBlocks variable as N/16 by N/16. In at least one embodiment, main function then specifies kernel call “MatAdd<<<numBlocks, threadsPerBlock>>>(A, B, C);”. In at least one embodiment and as per CUDA kernel launch syntax 5210, kernel MatAdd is executed using a grid of thread blocks having a dimension N/16 by N/16, where each thread block has a dimension of 16 by 16. In at least one embodiment, each thread block includes 256 threads, a grid is created with enough blocks to have one thread per matrix element, and each thread in such a grid executes kernel MatAdd to perform one pair-wise addition.

In at least one embodiment, while translating CUDA source code 5110 to HIP source code 5130, CUDA to HIP translation tool 5120 translates each kernel call in CUDA source code 5110 from CUDA kernel launch syntax 5210 to a HIP kernel launch syntax 5220 and converts any number of other CUDA calls in source code 5110 to any number of other functionally similar HIP calls. In at least one embodiment, HIP kernel launch syntax 5220 is specified as “hipLaunchKernelGGL(KernelName,GridSize, BlockSize, SharedMemorySize, Stream, KernelArguments);”. In at least one embodiment, each of KernelName, GridSize, BlockSize, ShareMemorySize, Stream, and KernelArguments has the same meaning in HIP kernel launch syntax 5220 as in CUDA kernel launch syntax 5210 (described previously herein). In at least one embodiment, arguments SharedMemorySize and Stream are required in HIP kernel launch syntax 5220 and are optional in CUDA kernel launch syntax 5210.

In at least one embodiment, a portion of HIP source code 5130 illustrated in FIG. 52 is identical to a portion of CUDA source code 5110 illustrated in FIG. 52 except for a kernel call that causes kernel MatAdd to execute on a device. In at least one embodiment, kernel MatAdd is defined in HIP source code 5130 with the same “_global_” declaration specifier with which kernel MatAdd is defined in CUDA source code 5110. In at least one embodiment, a kernel call in HIP source code 5130 is “hipLaunchKernelGGL(MatAdd, numBlocks, threadsPerBlock, 0, 0, A, B, C);”, while a corresponding kernel call in CUDA source code 5110 is “MatAdd<<<numBlocks, threadsPerBlock>>>(A, B, C);”.

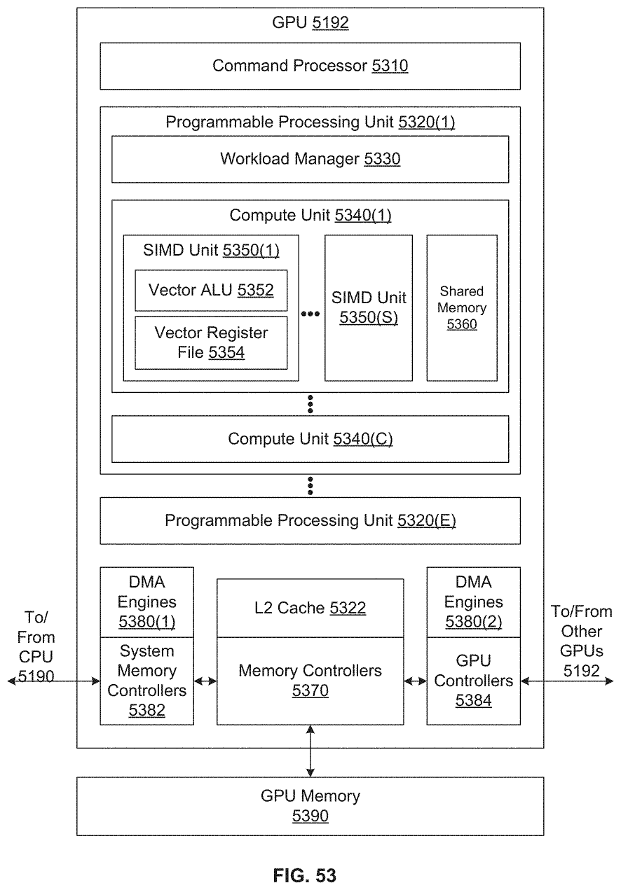

FIG. 53 illustrates non-CUDA-enabled GPU 5192 of FIG. 51C in greater detail, in accordance with at least one embodiment. In at least one embodiment, GPU 5192 is developed by AMD corporation of Santa Clara. In at least one embodiment, GPU 5192 can be configured to perform compute operations in a highly-parallel fashion. In at least one embodiment, GPU 5192 is configured to execute graphics pipeline operations such as draw commands, pixel operations, geometric computations, and other operations associated with rendering an image to a display. In at least one embodiment, GPU 5192 is configured to execute operations unrelated to graphics. In at least one embodiment, GPU 5192 is configured to execute both operations related to graphics and operations unrelated to graphics. In at least one embodiment, GPU 5192 can be configured to execute device code included in HIP source code 5130. In at least one embodiment, GPU 5192 performs one or more steps to perform operations discussed herein, such as decompressing or otherwise performing operations involving decoding of variable-length coded data in parallel.

In at least one embodiment, GPU 5192 includes, without limitation, any number of programmable processing units 5320, a command processor 5310, an L2 cache 5322, memory controllers 5370, DMA engines 5380(1), system memory controllers 5382, DMA engines 5380(2), and GPU controllers 5384. In at least one embodiment, each programmable processing unit 5320 includes, without limitation, a workload manager 5330 and any number of compute units 5340. In at least one embodiment, command processor 5310 reads commands from one or more command queues (not shown) and distributes commands to workload managers 5330. In at least one embodiment, for each programmable processing unit 5320, associated workload manager 5330 distributes work to compute units 5340 included in programmable processing unit 5320. In at least one embodiment, each compute unit 5340 may execute any number of thread blocks, but each thread block executes on a single compute unit 5340. In at least one embodiment, a workgroup is a thread block.

In at least one embodiment, each compute unit 5340 includes, without limitation, any number of SIMD units 5350 and a shared memory 5360. In at least one embodiment, each SIMD unit 5350 implements a SIMD architecture and is configured to perform operations in parallel. In at least one embodiment, each SIMD unit 5350 includes, without limitation, a vector ALU 5352 and a vector register file 5354. In at least one embodiment, each SIMD unit 5350 executes a different warp. In at least one embodiment, a warp is a group of threads (e.g., 16 threads), where each thread in the warp belongs to a single thread block and is configured to process a different set of data based on a single set of instructions. In at least one embodiment, predication can be used to disable one or more threads in a warp. In at least one embodiment, a lane is a thread. In at least one embodiment, a work item is a thread. In at least one embodiment, a wavefront is a warp. In at least one embodiment, different wavefronts in a thread block may synchronize together and communicate via shared memory 5360.

In at least one embodiment, programmable processing units 5320 are referred to as “shader engines.” In at least one embodiment, each programmable processing unit 5320 includes, without limitation, any amount of dedicated graphics hardware in addition to compute units 5340. In at least one embodiment, each programmable processing unit 5320 includes, without limitation, any number (including zero) of geometry processors, any number (including zero) of rasterizers, any number (including zero) of render back ends, workload manager 5330, and any number of compute units 5340.

In at least one embodiment, compute units 5340 share L2 cache 5322. In at least one embodiment, L2 cache 5322 is partitioned. In at least one embodiment, a GPU memory 5390 is accessible by all compute units 5340 in GPU 5192. In at least one embodiment, memory controllers 5370 and system memory controllers 5382 facilitate data transfers between GPU 5192 and a host, and DMA engines 5380(1) enable asynchronous memory transfers between GPU 5192 and such a host. In at least one embodiment, memory controllers 5370 and GPU controllers 5384 facilitate data transfers between GPU 5192 and other GPUs 5192, and DMA engines 5380(2) enable asynchronous memory transfers between GPU 5192 and other GPUs 5192.

In at least one embodiment, GPU 5192 includes, without limitation, any amount and type of system interconnect that facilitates data and control transmissions across any number and type of directly or indirectly linked components that may be internal or external to GPU 5192. In at least one embodiment, GPU 5192 includes, without limitation, any number and type of I/O interfaces (e.g., PCIe) that are coupled to any number and type of peripheral devices. In at least one embodiment, GPU 5192 may include, without limitation, any number (including zero) of adisplay engines and any number (including zero) of multimedia engines. In at least one embodiment, GPU 5192 implements a memory subsystem that includes, without limitation, any amount and type of memory controllers (e.g., memory controllers 5370 and system memory controllers 5382) and memory devices (e.g., shared memories 5360) that may be dedicated to one component or shared among multiple components. In at least one embodiment, GPU 5192 implements a cache subsystem that includes, without limitation, one or more cache memories (e.g., L2 cache 5322) that may each be private to or shared between any number of components (e.g., SIMD units 5350, compute units 5340, and programmable processing units 5320).

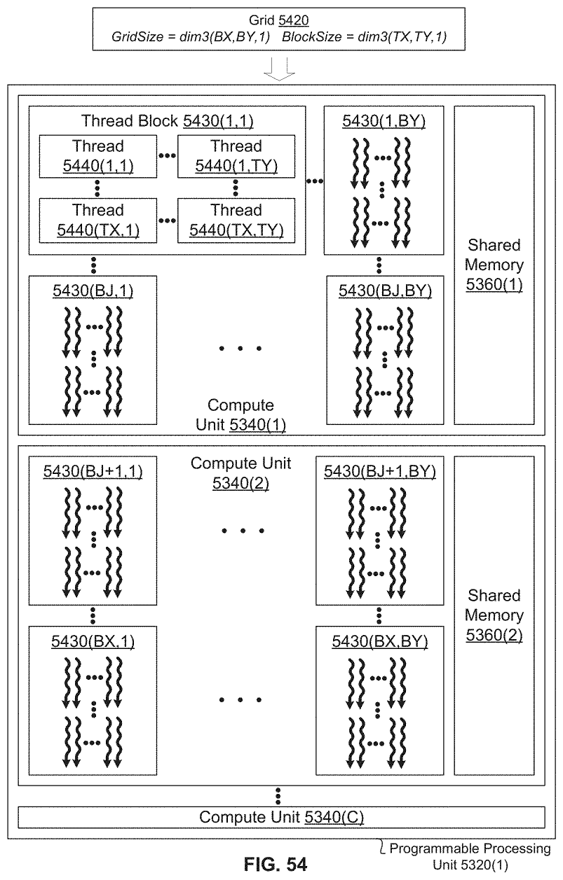

FIG. 54 illustrates how threads of an exemplary CUDA grid 5420 are mapped to different compute units 5340 of FIG. 53, in accordance with at least one embodiment. In at least one embodiment and for explanatory purposes only, grid 5420 has a GridSize of BX by BY by 1 and a BlockSize of TX by TY by 1. In at least one embodiment, grid 5420 therefore includes, without limitation, (BX*BY) thread blocks 5430 and each thread block 5430 includes, without limitation, (TX*TY) threads 5440. Threads 5440 are illustrated in FIG. 54 as squiggly arrows. In at least one embodiment, CUDA grid 5420 performs one or more steps to perform operations discussed herein, such as decompressing or otherwise performing operations involving decoding of variable-length coded data in parallel.

In at least one embodiment, grid 5420 is mapped to programmable processing unit 5320(1) that includes, without limitation, compute units 5340(1)-5340(C). In at least one embodiment and as shown, (BJ*BY) thread blocks 5430 are mapped to compute unit 5340(1), and the remaining thread blocks 5430 are mapped to compute unit 5340(2). In at least one embodiment, each thread block 5430 may include, without limitation, any number of warps, and each warp is mapped to a different SIMD unit 5350 of FIG. 53.

In at least one embodiment, warps in a given thread block 5430 may synchronize together and communicate through shared memory 5360 included in associated compute unit 5340. For example and in at least one embodiment, warps in thread block 5430(BJ,1) can synchronize together and communicate through shared memory 5360(1). For example and in at least one embodiment, warps in thread block 5430(BJ+1,1) can synchronize together and communicate through shared memory 5360(2).

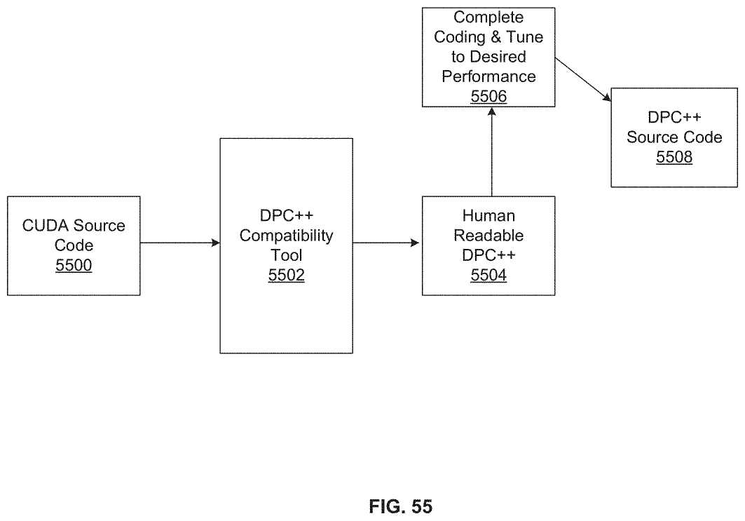

FIG. 55 illustrates how to migrate existing CUDA code to Data Parallel C++ code, in accordance with at least one embodiment. Data Parallel C++ (DPC++) may refer to an open, standards-based alternative to single-architecture proprietary languages that allows developers to reuse code across hardware targets (CPUs and accelerators such as GPUs and FPGAs) and also perform custom tuning for a specific accelerator. DPC++ use similar and/or identical C and C++ constructs in accordance with ISO C++ which developers may be familiar with. DPC++ incorporates standard SYCL from The Khronos Group to support data parallelism and heterogeneous programming. SYCL refers to a cross-platform abstraction layer that builds on underlying concepts, portability and efficiency of OpenCL that enables code for heterogeneous processors to be written in a “single-source” style using standard C++. SYCL may enable single source development where C++ template functions can contain both host and device code to construct complex algorithms that use OpenCL acceleration, and then re-use them throughout their source code on different types of data.

In at least one embodiment, a DPC++ compiler is used to compile DPC++ source code which can be deployed across diverse hardware targets. In at least one embodiment, a DPC++ compiler is used to generate DPC++ applications that can be deployed across diverse hardware targets and a DPC++ compatibility tool can be used to migrate CUDA applications to a multiplatform program in DPC++. In at least one embodiment, a DPC++ base tool kit includes a DPC++ compiler to deploy applications across diverse hardware targets; a DPC++ library to increase productivity and performance across CPUs, GPUs, and FPGAs; a DPC++ compatibility tool to migrate CUDA applications to multi-platform applications; and any suitable combination thereof.

In at least one embodiment, a DPC++ programming model is utilized to simply one or more aspects relating to programming CPUs and accelerators by using modern C++ features to express parallelism with a programming language called Data Parallel C++. DPC++ programming language may be utilized to code reuse for hosts (e.g., a CPU) and accelerators (e.g., a GPU or FPGA) using a single source language, with execution and memory dependencies being clearly communicated. Mappings within DPC++ code can be used to transition an application to run on a hardware or set of hardware devices that best accelerates a workload. A host may be available to simplify development and debugging of device code, even on platforms that do not have an accelerator available.

In at least one embodiment, CUDA source code 5500 is provided as an input to a DPC++ compatibility tool 5502 to generate human readable DPC++ 5504. In at least one embodiment, human readable DPC++ 5504 includes inline comments generated by DPC++ compatibility tool 5502 that guides a developer on how and/or where to modify DPC++ code to complete coding and tuning to desired performance 5506, thereby generating DPC++ source code 5508. In at least one embodiment, CUDA source code 5500 includes code that executes one or more steps to perform operations discussed herein, such as decompressing or otherwise performing operations involving decoding of variable-length coded data in parallel.

In at least one embodiment, CUDA source code 5500 is or includes a collection of human-readable source code in a CUDA programming language. In at least one embodiment, CUDA source code 5500 is human-readable source code in a CUDA programming language. In at least one embodiment, a CUDA programming language is an extension of the C++ programming language that includes, without limitation, mechanisms to define device code and distinguish between device code and host code. In at least one embodiment, device code is source code that, after compilation, is executable on a device (e.g., GPU or FPGA) and may include or more parallelizable workflows that can be executed on one or more processor cores of a device. In at least one embodiment, a device may be a processor that is optimized for parallel instruction processing, such as CUDA-enabled GPU, GPU, or another GPGPU, etc. In at least one embodiment, host code is source code that, after compilation, is executable on a host. In least one embodiment, some or all of host code and device code can be executed in parallel across a CPU and GPU/FPGA. In at least one embodiment, a host is a processor that is optimized for sequential instruction processing, such as CPU. CUDA source code 5500 described in connection with FIG. 55 may be in accordance with those discussed elsewhere in this document.

In at least one embodiment, DPC++ compatibility tool 5502 refers to an executable tool, program, application, or any other suitable type of tool that is used to facilitate migration of CUDA source code 5500 to DPC++ source code 5508. In at least one embodiment, DPC++ compatibility tool 5502 is a command-line-based code migration tool available as part of a DPC++ tool kit that is used to port existing CUDA sources to DPC++. In at least one embodiment, DPC++ compatibility tool 5502 converts some or all source code of a CUDA application from CUDA to DPC++ and generates a resulting file that is written at least partially in DPC++, referred to as human readable DPC++ 5504. In at least one embodiment, human readable DPC++ 5504 includes comments that are generated by DPC++ compatibility tool 5502 to indicate where user intervention may be necessary. In at least one embodiment, user intervention is necessary when CUDA source code 5500 calls a CUDA API that has no analogous DPC++ API; other examples where user intervention is required are discussed later in greater detail.

In at least one embodiment, a workflow for migrating CUDA source code 5500 (e.g., application or portion thereof) includes creating one or more compilation database files; migrating CUDA to DPC++ using a DPC++ compatibility tool 5502; completing migration and verifying correctness, thereby generating DPC++ source code 5508; and compiling DPC++ source code 5508 with a DPC++ compiler to generate a DPC++ application. In at least one embodiment, a compatibility tool provides a utility that intercepts commands used when Makefile executes and stores them in a compilation database file. In at least one embodiment, a file is stored in JSON format. In at least one embodiment, an intercept-built command converts Makefile command to a DPC compatibility command.

In at least one embodiment, intercept-build is a utility script that intercepts a build process to capture compilation options, macro defs, and include paths, and writes this data to a compilation database file. In at least one embodiment, a compilation database file is a JSON file. In at least one embodiment, DPC++ compatibility tool 5502 parses a compilation database and applies options when migrating input sources. In at least one embodiment, use of intercept-build is optional, but highly recommended for Make or CMake based environments. In at least one embodiment, a migration database includes commands, directories, and files: command may include necessary compilation flags; directory may include paths to header files; file may include paths to CUDA files.

In at least one embodiment, DPC++ compatibility tool 5502 migrates CUDA code (e.g., applications) written in CUDA to DPC++ by generating DPC++ wherever possible. In at least one embodiment, DPC++ compatibility tool 5502 is available as part of a tool kit. In at least one embodiment, a DPC++ tool kit includes an intercept-build tool. In at least one embodiment, an intercept-built tool creates a compilation database that captures compilation commands to migrate CUDA files. In at least one embodiment, a compilation database generated by an intercept-built tool is used by DPC++ compatibility tool 5502 to migrate CUDA code to DPC++. In at least one embodiment, non-CUDA C++ code and files are migrated as is. In at least one embodiment, DPC++ compatibility tool 5502 generates human readable DPC++ 5504 which may be DPC++ code that, as generated by DPC++ compatibility tool 5502, cannot be compiled by DPC++ compiler and requires additional plumbing for verifying portions of code that were not migrated correctly, and may involve manual intervention, such as by a developer. In at least one embodiment, DPC++ compatibility tool 5502 provides hints or tools embedded in code to help developers manually migrate additional code that could not be migrated automatically. In at least one embodiment, migration is a one-time activity for a source file, project, or application.

In at least one embodiment, DPC++ compatibility tool 55002 is able to successfully migrate all portions of CUDA code to DPC++ and there may simply be an optional step for manually verifying and tuning performance of DPC++ source code that was generated. In at least one embodiment, DPC++ compatibility tool 5502 directly generates DPC++ source code 5508 which is compiled by a DPC++ compiler without requiring or utilizing human intervention to modify DPC++ code generated by DPC++ compatibility tool 5502. In at least one embodiment, DPC++ compatibility tool generates compile-able DPC++ code which can be optionally tuned by a developer for performance, readability, maintainability, other various considerations; or any combination thereof.

In at least one embodiment, one or more CUDA source files are migrated to DPC++ source files at least partially using DPC++ compatibility tool 5502. In at least one embodiment, CUDA source code includes one or more header files which may include CUDA header files. In at least one embodiment, a CUDA source file includes a <cuda.h> header file and a <stdio.h> header file which can be used to print text. In at least one embodiment, a portion of a vector addition kernel CUDA source file may be written as or related to:

```
#include <cuda.h>
#include <stdio.h>
#define VECTOR_SIZE 256
[ ] global_{——} void VectorAddKernel(float* A, float* B, float* C)
{
  A[threadIdx.x] = threadIdx.x + 1.0f;
  B[threadIdx.x] = threadIdx.x + 1.0f;
  C[threadIdx.x] = A[threadIdx.x] + B[threadIdx.x];
}
int main( )
{
  float *d_A, *d_B, *d_C;
  cudaMalloc(&d_A, VECTOR_SIZE*sizeof(float));
  cudaMalloc(&d_B, VECTOR_SIZE*sizeof(float));
  cudaMalloc(&d_C, VECTOR_SIZE*sizeof(float));
  VectorAddKernel<<<1, VECTOR_SIZE>>>(d_A, d_B, d_C);
  float Result[VECTOR_SIZE] = { };
  cudaMemcpy(Result, d_C, VECTOR_SIZE*sizeof(float),
cudaMemcpyDeviceToHost);
  cudaFree(d_A);
  cudaFree(d_B);
  cudaFree(d_C);
  for (int i=0; i<VECTOR_SIZE; i++ {
    if (i % 16 == 0) {
      printf(“\n”);
    }
    printf(“%f“, Result[i]);
  }
  return 0;
}
```

In at least one embodiment and in connection with CUDA source file presented above, DPC++ compatibility tool 5502 parses a CUDA source code and replaces header files with appropriate DPC++ and SYCL header files. In at least one embodiment, DPC++ header files includes helper declarations. In CUDA, there is a concept of a thread ID and correspondingly, in DPC++ or SYCL, for each element there is a local identifier.

In at least one embodiment and in connection with CUDA source file presented above, there are two vectors A and B which are initialized and a vector addition result is put into vector C as part of VectorAddKernel( ). In at least one embodiment, DPC++ compatibility tool 5502 converts CUDA thread IDs used to index work elements to SYCL standard addressing for work elements via a local ID as part of migrating CUDA code to DPC++ code. In at least one embodiment, DPC++ code generated by DPC++ compatibility tool 5502 can be optimized—for example, by reducing dimensionality of an nd_item, thereby increasing memory and/or processor utilization.

In at least one embodiment and in connection with CUDA source file presented above, memory allocation is migrated. In at least one embodiment, cudaMalloc( ) is migrated to a unified shared memory SYCL call malloc_device( ) to which a device and context is passed, relying on SYCL concepts such as platform, device, context, and queue. In at least one embodiment, a SYCL platform can have multiple devices (e.g., host and GPU devices); a device may have multiple queues to which jobs can be submitted; each device may have a context; and a context may have multiple devices and manage shared memory objects.

In at least one embodiment and in connection with CUDA source file presented above, a main( ) function invokes or calls VectorAddKernel( ) to add two vectors A and B together and store result in vector C. In at least one embodiment, CUDA code to invoke VectorAddKernel( ) is replaced by DPC++ code to submit a kernel to a command queue for execution. In at least one embodiment, a command group handler cgh passes data, synchronization, and computation that is submitted to the queue, parallel_for is called for a number of global elements and a number of work items in that work group where VectorAddKernel( ) is called.

In at least one embodiment and in connection with CUDA source file presented above, CUDA calls to copy device memory and then free memory for vectors A, B, and C are migrated to corresponding DPC++ calls. In at least one embodiment, C++ code (e.g., standard ISO C++ code for printing a vector of floating point variables) is migrated as is, without being modified by DPC++ compatibility tool 5502. In at least one embodiment, DPC++ compatibility tool 5502 modify CUDA APIs for memory setup and/or host calls to execute kernel on the acceleration device. In at least one embodiment and in connection with CUDA source file presented above, a corresponding human readable DPC++ 5504 (e.g., which can be compiled) is written as or related to:

```
#include <CL/sycl.hpp>
#include <dpct/dpct.hpp>
#define VECTOR_SIZE 256
void VectorAddKernel(float* A, float* B, float* C,
          sycl::nd_item<3> item_ct1)
{
  A[item_ct1.get_local_id(2)] = item_ct1.get_local_id(2) + 1.0f;
  B[item_ct1.get_local_id(2)] = item_ct1.get_local_id(2) + 1.0f;
  C[item_ct1.get_local_id(2)] =
      A[item_ct1.get_local_id(2)] + B[item_ct1.get_local_id(2)];
}
int main( )
{
  float *d_A, *d_B, *d_C;
  d_A = (float *)sycl::malloc_device(VECTOR_SIZE * sizeof(float),
    dpct::get_current_device( ),
    dpct::get_default_context( ));
  d_B = (float *)sycl::malloc_device(VECTOR_SIZE * sizeof(float),
    dpct::get_current_device( ),
    dpct::get_default_context( ));
  d_C = (float *)sycl::malloc_device(VECTOR_SIZE * sizeof(float),
    dpct::get_current_device( ),
    dpct::get_default_context( ));
  dpct::get_default_queue_wait( ).submit([&](sycl::handler &cgh) {
    cgh.parallel_for(
      sycl::nd_range<3>(sycl::range<3>(1, 1, 1) *
            sycl::range<3>(1, 1, VECTOR_SIZE) *
            sycl::range<3>(1, 1, VECTOR_SIZE)),
      [=](sycl::nd_items<3> item_ct1) {
        VectorAddKernel(d_A, d_B, d_C, item_ct1);
      });
  });
  float Result[VECTOR_SIZE] = { };
  dpct::get_default_queue_wait( )
    .memcpy(Result, d_C, VECTOR_SIZE * sizeof(float))
    .wait( );
  sycl::free(d_A, dpct::get_default_context( ));
  sycl::free(d_B, dpct::get_default_context( ));
  sycl::free(d_C, dpct::get_default_context( ));
  for (int i=0; i<VECTOR_SIZE; i++ {
    if (i % 16 == 0) {
        printf(“\n”);
    }
    printf(“%f“, Result[i]);
  }
  return 0;
}
```

In at least one embodiment, human readable DPC++ 5504 refers to output generated by DPC++ compatibility tool 5502 and may be optimized in one manner or another. In at least one embodiment, human readable DPC++ 5504 generated by DPC++ compatibility tool 5502 can be manually edited by a developer after migration to make it more maintainable, performance, or other considerations. In at least one embodiment, DPC++ code generated by DPC++ compatibility tool 55002 such as DPC++ disclosed can be optimized by removing repeat calls to get current_device( ) and/or get_default_context( ) for each malloc_device( ) call. In at least one embodiment, DPC++ code generated above uses a 3 dimensional nd_range which can be refactored to use only a single dimension, thereby reducing memory usage. In at least one embodiment, a developer can manually edit DPC++ code generated by DPC++ compatibility tool 5502 replace uses of unified shared memory with accessors. In at least one embodiment, DPC++ compatibility tool 5502 has an option to change how it migrates CUDA code to DPC++ code. In at least one embodiment, DPC++ compatibility tool 5502 is verbose because it is using a general template to migrate CUDA code to DPC++ code that works for a large number of cases.

In at least one embodiment, a CUDA to DPC++ migration workflow includes steps to: prepare for migration using intercept-build script; perform migration of CUDA projects to DPC++ using DPC++ compatibility tool 5502; review and edit migrated source files manually for completion and correctness; and compile final DPC++ code to generate a DPC++ application. In at least one embodiment, manual review of DPC++ source code may be required in one or more scenarios including but not limited to: migrated API does not return error code (CUDA code can return an error code which can then be consumed by the application but SYCL uses exceptions to report errors, and therefore does not use error codes to surface errors); CUDA compute capability dependent logic is not supported by DPC++; statement could not be removed. In at least one embodiment, scenarios in which DPC++ code requires manual intervention may include, without limitation: error code logic replaced with (*,0) code or commented out; equivalent DPC++ API not available; CUDA compute capability-dependent logic; hardware-dependent API (clock( )); missing features unsupported API; execution time measurement logic; handling built-in vector type conflicts; migration of cuBLAS API; and more.

In at least one embodiment, one or more techniques described herein utilize a oneAPI programming model. In at least one embodiment, a oneAPI programming model refers to a programming model for interacting with various compute accelerator architectures. In at least one embodiment, oneAPI refers to an application programming interface (API) designed to interact with various compute accelerator architectures. In at least one embodiment, a oneAPI programming model utilizes a DPC++ programming language. In at least one embodiment, a DPC++ programming language refers to a high-level language for data parallel programming productivity. In at least one embodiment, a DPC++ programming language is based at least in part on C and/or C++ programming languages. In at least one embodiment, a oneAPI programming model is a programming model such as those developed by Intel Corporation of Santa Clara, Calif.

In at least one embodiment, oneAPI and/or oneAPI programming model is utilized to interact with various accelerator, GPU, processor, and/or variations thereof, architectures. In at least one embodiment, oneAPI includes a set of libraries that implement various functionalities. In at least one embodiment, oneAPI includes at least a oneAPI DPC++ library, a oneAPI math kernel library, a oneAPI data analytics library, a oneAPI deep neural network library, a oneAPI collective communications library, a oneAPI threading building blocks library, a oneAPI video processing library, and/or variations thereof.

In at least one embodiment, a oneAPI DPC++ library, also referred to as oneDPL, is a library that implements algorithms and functions to accelerate DPC++ kernel programming. In at least one embodiment, oneDPL implements one or more standard template library (STL) functions. In at least one embodiment, oneDPL implements one or more parallel STL functions. In at least one embodiment, oneDPL provides a set of library classes and functions such as parallel algorithms, iterators, function object classes, range-based API, and/or variations thereof. In at least one embodiment, oneDPL implements one or more classes and/or functions of a C++ standard library. In at least one embodiment, oneDPL implements one or more random number generator functions.

In at least one embodiment, a oneAPI math kernel library, also referred to as oneMKL, is a library that implements various optimized and parallelized routines for various mathematical functions and/or operations. In at least one embodiment, oneMKL implements one or more basic linear algebra subprograms (BLAS) and/or linear algebra package (LAPACK) dense linear algebra routines. In at least one embodiment, oneMKL implements one or more sparse BLAS linear algebra routines. In at least one embodiment, oneMKL implements one or more random number generators (RNGs). In at least one embodiment, oneMKL implements one or more vector mathematics (VM) routines for mathematical operations on vectors. In at least one embodiment, oneMKL implements one or more Fast Fourier Transform (FFT) functions.

In at least one embodiment, a oneAPI data analytics library, also referred to as oneDAL, is a library that implements various data analysis applications and distributed computations. In at least one embodiment, oneDAL implements various algorithms for preprocessing, transformation, analysis, modeling, validation, and decision making for data analytics, in batch, online, and distributed processing modes of computation. In at least one embodiment, oneDAL implements various C++ and/or Java APIs and various connectors to one or more data sources. In at least one embodiment, oneDAL implements DPC++ API extensions to a traditional C++ interface and enables GPU usage for various algorithms.

In at least one embodiment, a oneAPI deep neural network library, also referred to as oneDNN, is a library that implements various deep learning functions. In at least one embodiment, oneDNN implements various neural network, machine learning, and deep learning functions, algorithms, and/or variations thereof.

In at least one embodiment, a oneAPI collective communications library, also referred to as oneCCL, is a library that implements various applications for deep learning and machine learning workloads. In at least one embodiment, oneCCL is built upon lower-level communication middleware, such as message passing interface (MPI) and libfabrics. In at least one embodiment, oneCCL enables a set of deep learning specific optimizations, such as prioritization, persistent operations, out of order executions, and/or variations thereof. In at least one embodiment, oneCCL implements various CPU and GPU functions.

In at least one embodiment, a oneAPI threading building blocks library, also referred to as oneTBB, is a library that implements various parallelized processes for various applications. In at least one embodiment, oneTBB is utilized for task-based, shared parallel programming on a host. In at least one embodiment, oneTBB implements generic parallel algorithms. In at least one embodiment, oneTBB implements concurrent containers. In at least one embodiment, oneTBB implements a scalable memory allocator. In at least one embodiment, oneTBB implements a work-stealing task scheduler. In at least one embodiment, oneTBB implements low-level synchronization primitives. In at least one embodiment, oneTBB is compiler-independent and usable on various processors, such as GPUs, PPUs, CPUs, and/or variations thereof.

In at least one embodiment, a oneAPI video processing library, also referred to as oneVPL, is a library that is utilized for accelerating video processing in one or more applications. In at least one embodiment, oneVPL implements various video decoding, encoding, and processing functions. In at least one embodiment, oneVPL implements various functions for media pipelines on CPUs, GPUs, and other accelerators. In at least one embodiment, oneVPL implements device discovery and selection in media centric and video analytics workloads. In at least one embodiment, oneVPL implements API primitives for zero-copy buffer sharing.

In at least one embodiment, a oneAPI programming model utilizes a DPC++ programming language. In at least one embodiment, a DPC++ programming language is a programming language that includes, without limitation, functionally similar versions of CUDA mechanisms to define device code and distinguish between device code and host code. In at least one embodiment, a DPC++ programming language may include a subset of functionality of a CUDA programming language. In at least one embodiment, one or more CUDA programming model operations are performed using a oneAPI programming model using a DPC++ programming language.

It should be noted that, while example embodiments described herein may relate to a CUDA programming model, techniques described herein can be utilized with any suitable programming model, such HIP, oneAPI, and/or variations thereof.

At least one embodiment of the disclosure can be described in view of the following clauses:

1. A processor comprising: one or more circuits to cause decoding variable-length coded data in parallel.

2. The processor of clause 1, wherein the one or more circuits are further to cause decoding the variable-length coded data in parallel by at least: causing storage of a value representing starting positions of overlapping portions of the data.

3. The processor of clauses 1-2, wherein the one or more circuits are further to cause:
decoding overlapping portions of the data to calculate one or more locations to decode the data.

4. The processor of clauses 1-3, wherein the one or more circuits are further to cause:
creating a vector based, at least in part on decoding overlapping portions of the data.

5. The processor of clauses 1-4, wherein the one or more circuits are further to cause:
calculating a value based at least in part on incomplete codes in overlapping portions of the data.

6. The processor of clauses 1-5, wherein the one or more circuits are further to cause:
decoding a first subportion of data in portions of the data, wherein the data overlaps.

7. The processor of clauses 1-6, wherein the one or more circuits are further to cause:
full decoding of some, but not all, overlapping portions of the data.

8. The processor of clauses 1-7, wherein the one or more circuits are further to cause:
outputting of elements of decoded data in parallel.

9. A computer-implemented method, comprising:
decoding variable-length coded data in parallel.

10. The method of clause 9, wherein the method of decoding variable-length coded data in parallel at least:
decodes overlapping portions of the data to calculate a location to start decoding the data, wherein the overlapping portions each begin at a different location of the data.

11. The method of clauses 9-10, further comprising:
calculating a number of extra bits required to complete decoding overlapping portions of the data.

12. The method of clauses 9-11, further comprising:
creating one or more vectors based, at least in part on decoding overlapping portions of the data; and
scanning the vectors to determine, at least in part, starting locations in the data when decoding the data.

13. The method of clauses 9-12, further comprising:
decoding a first code in portions of the data, wherein the portions of data overlap.

14. The method of clauses 9-13, further comprising:
copying a result from decoding an overlapping portions of data; and
applying the result to another overlapping portion of data.

15. The method of clauses 9-14, further comprising:
outputting an element of decoded data by combining at least two instructions to copy other identical elements into one copy instruction.

16. The method of clauses 9-15, further comprising:
outputting elements of decoded data in parallel, wherein one thread of a graphics processing unit (GPU) outputs one element before outputting another element.

17. A non-transitory computer-readable storage medium storing instructions that, when executed by a processor, causes the processor to perform steps comprising:
decoding variable-length coded data in parallel.

18. The non-transitory computer-readable storage medium of clauses 17, further comprising:
decoding overlapping portions of the data to determine which overlapping portions begin with a proper starting location to decode the data, wherein the overlapping portions each begin at a different location of the data.

19. The non-transitory computer-readable storage medium of clauses 17-18, further comprising:
calculating a number of extra bits required from data next in sequence to complete decoding overlapping portions of the data.

20. The non-transitory computer-readable storage medium of clauses 17-19, further comprising:
calculating values based, at least in part, on decoding overlapping portions of the data; and
storing the values in an array.

21. The non-transitory computer-readable storage medium of clauses 17-20, further comprising:
scanning an array using composition operations to determine, at least in part, starting locations when decoding the data.

22. The non-transitory computer-readable storage medium of clauses 17-21, further comprising:
portions of the data that overlap, decoding a first code in each portion; and
writing a result from one portion to be a result applied to another portion based on the first code in the one portion.

23. The non-transitory computer-readable storage medium of clauses 17-22, further comprising:
outputting an element of decoded data in parallel, wherein the processor includes threads, and at least one thread outputs one element by copying another element.

24. The non-transitory computer-readable storage medium of clauses 17-23, wherein the variable-length coded data is Huffman coded.

25. A system comprising memory to store instructions that, if executed, further cause the system to:
decode variable-length coded data in parallel.

26. The system of clause 25, wherein the memory stores further instructions, that if executed, further cause the system to:
decode overlapping portions of the data, wherein each portion begins with a different bit of the data and ends with the last bit of the data.

27. The system of clauses 25-26, wherein the memory stores further instructions, that if executed, further cause the system to:
store a value representing starting positions of overlapping portions of the data;
calculate a number of extra bits required to complete decoding any incomplete codes in overlapping portions of the data;
create at least one vector based on a mapping of the values and calculations; and
store the at least one vector in an array.

28. The system of clause 25-27, wherein the memory stores further instructions, that if executed, further cause the system to:
store a value based on calculating a number of extra bits required from data next in sequence to complete decoding any incomplete codes in overlapping portions of the data.

29. The system of clauses 25-28, wherein the memory stores further instructions, that if executed, further cause the system to:
creating one or more vectors based, at least in part on decoding overlapping portions of the data, wherein the data was compressed, at least in part, with a Deflate algorithm.

30. The system of clauses 25-29, the memory stores further instructions, that if executed, further cause the system to:
scan on or more vectors stored in an array and based, at least in part, on decoding overlapping portions of the data, wherein the scanning is a prefix scan.

31. The system of clauses 25-30, wherein the memory stores further instructions, that if executed, further cause the system to:
decoding a first code for portions of data, wherein the data overlaps;
calculating, based at least in part on the first code's end point, if subsequent decoding of one portion would match subsequent decoding of another portion; and
copying subsequent decoding results from the other portion as results of the one portion.

32. The system of clauses 25-31, wherein the memory stores further instructions, that if executed, further cause the system to:
create overlapping portions of the data;
assign a thread to each portion of overlapping data, wherein the thread is to decode the portion or copy results from another thread decoding another portion.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. term “connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. Use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). A number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (e.g., as a result of being executed) by one or more processors of a computer system, cause computer system to perform operations described herein. A set of non-transitory computer-readable storage media, in at least one embodiment, comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

All references, including publications, patent applications, and patents, cited herein are hereby incorporated by reference to same extent as if each reference were individually and specifically indicated to be incorporated by reference and were set forth in its entirety herein.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. Terms “system” and “method” are used herein interchangeably insofar as system may embody one or more methods and methods may be considered a system.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In present document, references may be made to obtaining, acquiring, receiving, or inputting analog or digital data into a subsystem, computer system, or computer-implemented machine. Process of obtaining, acquiring, receiving, or inputting analog and digital data can be accomplished in a variety of ways such as by receiving data as a parameter of a function call or a call to an application programming interface. In some implementations, process of obtaining, acquiring, receiving, or inputting analog or digital data can be accomplished by transferring data via a serial or parallel interface. In another implementation, process of obtaining, acquiring, receiving, or inputting analog or digital data can be accomplished by transferring data via a computer network from providing entity to acquiring entity. References may also be made to providing, outputting, transmitting, sending, or presenting analog or digital data. In various examples, process of providing, outputting, transmitting, sending, or presenting analog or digital data can be accomplished by transferring data as an input or output parameter of a function call, a parameter of an application programming interface or interprocess communication mechanism.

Although discussion above sets forth example implementations of described techniques, other architectures may be used to implement described functionality, and are intended to be within scope of this disclosure. Furthermore, although specific distributions of responsibilities are defined above for purposes of discussion, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A processor comprising: one or more circuits to cause decoding variable-length coded data in parallel.

2. The processor of claim 1, wherein the one or more circuits are further to cause decoding the variable-length coded data in parallel by at least:
causing storage of a value representing starting positions of overlapping portions of the data.

3. The processor of claim 1, wherein the one or more circuits are further to cause:
decoding overlapping portions of the data to calculate one or more locations to decode the data.

4. The processor of claim 1, wherein the one or more circuits are further to cause:
creating a vector based, at least in part on decoding overlapping portions of the data.

5. The processor of claim 1, wherein the one or more circuits are further to cause:
calculating a value based at least in part on incomplete codes in overlapping portions of the data.

6. The processor of claim 1, wherein the one or more circuits are further to cause:
decoding a first subportion of data in portions of the data, wherein the data overlaps.

7. The processor of claim 1, wherein the one or more circuits are further to cause:
full decoding of some, but not all, overlapping portions of the data.

8. The processor of claim 1, wherein the one or more circuits are further to cause:
outputting of elements of decoded data in parallel.

9. A computer-implemented method, comprising:
decoding variable-length coded data in parallel.

10. The method of claim 9, wherein the method of decoding variable-length coded data in parallel at least:
decodes overlapping portions of the data to calculate a location to start decoding the data, wherein the overlapping portions each begin at a different location of the data.

11. The method of claim 9, further comprising:
calculating a number of extra bits required to complete decoding overlapping portions of the data.

12. The method of claim 9, further comprising:
creating one or more vectors based, at least in part on decoding overlapping portions of the data; and
scanning the vectors to determine, at least in part, starting locations in the data when decoding the data.

13. The method of claim 9, further comprising:
decoding a first code in portions of the data, wherein the portions of data overlap.

14. The method of claim 9, further comprising:
copying a result from decoding an overlapping portions of data; and
applying the result to another overlapping portion of data.

15. The method of claim 9, further comprising:
outputting an element of decoded data by combining at least two instructions to copy other identical elements into one copy instruction.

16. The method of claim 9, further comprising:
outputting elements of decoded data in parallel, wherein one thread of a graphics processing unit (GPU) outputs one element before outputting another element.

17. A non-transitory computer-readable storage medium storing instructions that, when executed by a processor, causes the processor to perform steps comprising:
decoding variable-length coded data in parallel.

18. The non-transitory computer-readable storage medium of claim 17, further comprising:
decoding overlapping portions of the data to determine which overlapping portions begin with a proper starting location to decode the data, wherein the overlapping portions each begin at a different location of the data.

19. The non-transitory computer-readable storage medium of claim 17, further comprising:
calculating a number of extra bits required from data next in sequence to complete decoding overlapping portions of the data.

20. The non-transitory computer-readable storage medium of claim 17, further comprising:
calculating values based, at least in part, on decoding overlapping portions of the data; and
storing the values in an array.

21. The non-transitory computer-readable storage medium of claim 17, further comprising:
scanning an array using composition operations to determine, at least in part, starting locations when decoding the data.

22. The non-transitory computer-readable storage medium of claim 17, further comprising:
decoding a first code in portions of data, wherein the portions overlap; and
writing a result from one portion to be a result applied to another portion based on the first code in the one portion.

23. The non-transitory computer-readable storage medium of claim 17, further comprising:
outputting an element of decoded data in parallel, wherein the processor includes threads, and at least one thread outputs one element by copying another element.

24. The non-transitory computer-readable storage medium of claim 17, wherein the variable-length coded data is Huffman coded.

25. A system comprising memory to store instructions that, if executed, further cause the system to:
decode variable-length coded data in parallel.

26. The system of claim 25, wherein the memory stores further instructions, that if executed, further cause the system to:
decode overlapping portions of the data, wherein each portion begins with a different bit of the data and ends with the last bit of the data.

27. The system of claim 25, wherein the memory stores further instructions, that if executed, further cause the system to:
store a value representing starting positions of overlapping portions of the data;
calculate a number of extra bits required to complete decoding any incomplete codes in overlapping portions of the data;
create at least one vector based on a mapping of the values and calculations; and
store the at least one vector in an array.

28. The system of claim 25, wherein the memory stores further instructions, that if executed, further cause the system to:
store a value based on calculating a number of extra bits required from data next in sequence to complete decoding any incomplete codes in overlapping portions of the data.

29. The system of claim 25, wherein the memory stores further instructions, that if executed, further cause the system to:
creating one or more vectors based, at least in part on decoding overlapping portions of the data, wherein the data was compressed, at least in part, with a Deflate algorithm.

30. The system of claim 25, the memory stores further instructions, that if executed, further cause the system to:
scan on or more vectors stored in an array and based, at least in part, on decoding overlapping portions of the data, wherein the scanning is a prefix scan.

31. The system of claim 25, wherein the memory stores further instructions, that if executed, further cause the system to:
decoding a first code for portions of data, wherein the data overlaps;
calculating, based at least in part on the first code's end point, if subsequent decoding of one portion would match subsequent decoding of another portion; and
copying subsequent decoding results from the other portion as results of the one portion.

32. The system of claim 25, wherein the memory stores further instructions, that if executed, further cause the system to:
create overlapping portions of the data; and
assign a thread to each portion of overlapping data, wherein the thread is to decode the portion or copy results from another thread decoding another portion.
